(19) United States
(12) Patent Application Publication
(10) Pub. No.: US 2025/0015088 A1
(43) Pub. Date: Jan. 9, 2025

(54) DISPLAY APPARATUS AND ELECTRONIC DEVICE

(71) Applicant: Semiconductor Energy Laboratory Co., Ltd., Atsugi-shi, Kanagawa-ken (JP)

(72) Inventors: Tomoaki ATSUMI, Hadano (JP); Koji KUSUNOKI, Isehara (JP); Hideaki SHISHIDO, Atsugi (JP); Susumu KAWASHIMA, Atsugi (JP)

(21) Appl. No.: 18/711,187

(22) PCT Filed: Nov. 17, 2022
(86) PCT No.: PCT/IB2022/061058

§ 371 Date: May 17, 2024

(30) Foreign Application Priority Data
Nov. 30, 2021 (JP) 2021-193895

(51) Int. Cl. H01L 27/12

(52) U.S. Cl. CPC H01L 27/1225; H01L 27/1218; H01L 27/124

(57) ABSTRACT

A display apparatus with high luminance and a long lifetime is provided. The display apparatus includes a first layer and a second layer positioned above the first layer. The first layer includes a substrate and a plurality of driver circuit regions, and the second layer includes a plurality of display regions. The substrate is a glass substrate. Each of the plurality of driver circuit regions includes a driver circuit, and the driver circuit includes a transistor including silicon in a channel formation region. Each of the plurality of display regions includes a pixel, and the pixel includes a light-emitting diode and a transistor including a metal oxide in a channel formation region. Specifically, the light-emitting diode is preferably a micro light-emitting diode. The driver circuit included in one of the plurality of driver circuit regions has a function of driving the display pixel included in one of the plurality of display regions.

### TECHNICAL FIELD

One embodiment of the present invention relates to a display apparatus and an electronic device.

Note that one embodiment of the present invention is not limited to the above technical field. The technical field of the invention disclosed in this specification and the like relates to an object, a driving method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting device, a power storage device, an imaging device, a memory device, a signal processing device, a processor, an electronic device, a system, a driving method thereof, a manufacturing method thereof, and a testing method thereof.

### BACKGROUND ART

Display apparatuses included in electronic devices for XR (Extended Reality or Cross Reality) such as VR (Virtual Reality) or AR (Augmented Reality), mobile phones such as smartphones, tablet information terminals, laptop PCs (Personal Computers), and the like have undergone various improvements in recent years. For example, display apparatuses have been developed aiming for higher pixel density, higher color reproducibility (NTSC ratio), a smaller driver circuit, lower power consumption, and the like.

In order to increase the area of the display portion of the display apparatus, for example, the bezel region around the display portion can be reduced. A driver circuit or the like is provided in the bezel region of the display portion of the display apparatus in some cases; thus, the driver circuit is provided in a region other than the bezel region, in which case the bezel region can be reduced or eliminated. For example, Patent Document 1 discloses a structure in which a display portion of a display apparatus is divided and one of a plurality of display portions and a driver circuit corresponding to the display portion overlap with each other, as a structure for making a smaller bezel region.

### REFERENCE

### [Patent Document]

[Patent Document 1] PCT International Publication No. 2021/191721

### SUMMARY OF THE INVENTION

### Problems to be Solved by the Invention

As described above, in a display apparatus with a display portion divided, a driver circuit corresponding to one display region is provided so as to overlap with the display region in a plan view in some cases. In that case, the display apparatus can be manufactured by providing the driver circuit over a semiconductor substrate and providing display pixels over the driver circuit, for example.

The diagonal size of such a display apparatus is limited by the size of a semiconductor substrate. In the case where a wafer including silicon as a material (hereinafter, referred to as a silicon wafer) is used for a semiconductor substrate, for example, a silicon wafer having a diameter exceeding 20 inches is needed to manufacture a display apparatus having a diagonal size exceeding 20 inches. Since the diameter of a silicon wafer used for the current semiconductor manufacturing line is approximately 300 mm (approximately 12 inches), a silicon wafer with a diameter exceeding 300 mm is difficult to prepare.

Furthermore, when the display apparatus has high color reproducibility, an image displayed on the display apparatus can be clear, which improves sense of reality. For example, when a display pixel including a light-emitting device containing an organic EL material (referred to as an OLED (Organic Light Emitting Diode) in some cases) is employed for a pixel of the display apparatus, the color reproducibility can be higher than a display apparatus using a liquid crystal display apparatus as a display element. Meanwhile, the light-emitting device containing an organic EL material is likely to deteriorate due to factors such as ultraviolet light, atmospheric components, or a usage environment, for example; thus, the lifetime of the display apparatus including the electronic device containing an organic EL material is short in some cases.

An object of one embodiment of the present invention is to provide a display apparatus with high definition and a large diagonal size. Another object of one embodiment of the present invention is to provide a display apparatus with high luminance and a long lifetime. Another object of one embodiment of the present invention is to provide an electronic device including the above-described display apparatus. Another object of one embodiment of the present invention is to provide a novel display apparatus or a novel electronic device.

Note that the objects of one embodiment of the present invention are not limited to the objects listed above. The objects listed above do not preclude the existence of other objects. Note that the other objects are objects that are not described in this section and will be described below. The objects that are not described in this section can be derived from the description of the specification, the drawings, and the like and can be extracted as appropriate from the description by those skilled in the art. Note that one embodiment of the present invention is to achieve at least one of the objects listed above and the other objects. Note that one embodiment of the present invention does not necessarily achieve all of the objects listed above and the other objects.

### Means for Solving the Problems

(1)

One embodiment of the present invention is a display apparatus including a first layer and a second layer positioned above the first layer. The first layer includes a substrate and a plurality of driver circuit regions positioned over the substrate, and the second layer includes a plurality of display regions. Each of the plurality of driver circuit regions includes a driver circuit. Each of the plurality of display regions includes a pixel, and the pixel includes a light-emitting diode. In addition, the driver circuit included in one of the plurality of driver circuit regions has a function of driving the display pixel included in one of the plurality of display regions. The display apparatus has a function displaying images on at least two of the plurality of display regions at different frame frequencies.

(2)

Another embodiment of the present invention in the above (1) may have a structure in which each of the plurality of the display region in one embodiment of the present invention includes a sensor portion. In particular, the sensor portion is preferably positioned above the light-emitting diode.

(3)

Another embodiment of the present invention in the above (2) may have a structure in which the frame frequency of a displayed image on the display region where the sensor portion sensing a touch is included is made lower than the frame frequency of a displayed image on the display region where the sensor portion not sensing a touch is included.

(4)

Another embodiment of the present invention in the above (1) to (3) may have a structure in which the driver circuit includes a transistor containing silicon in a channel formation region and the pixel includes a transistor containing a metal oxide in a channel formation region.

(5)

Another embodiment of the present invention in the above (4) may have a structure in which the substrate is a glass substrate and silicon is low-temperature polysilicon.

(6)

Another embodiment of the present invention in any one of the above (1) to (5) may have a structure in which the one of the plurality of driver circuit regions is positioned to have a region overlapping with the one of the plurality of display regions in a plan view.

(7)

Another embodiment of the present invention in any one of the above (1) to (6) has a structure in which a wiring is extended in a direction perpendicular to or a direction substantially perpendicular to the substrate between the first layer and the second layer, and the wiring is electrically connected to the pixel and the driver circuit.

(8)

Another embodiment of the present invention is an electronic device including the display apparatus according to any one of the above (1) to (7) and a housing.

### Effect of the Invention

One embodiment of the present invention can provide a display apparatus with high definition and a large diagonal size. Another embodiment of the present invention can provide a display apparatus with high luminance and a long lifetime. Another embodiment of the present invention can provide an electronic device including the above-described display apparatus. Another embodiment of the present invention can provide a novel display apparatus or a novel electronic device.

Note that the effects of one embodiment of the present invention are not limited to the effects listed above. The effects listed above do not preclude the presence of other effects. Note that the other effects are effects that are not described in this section and will be described below. The effects that are not described in this section can be derived from the description of the specification, the drawings, and the like and can be extracted as appropriate from the description by those skilled in the art. Note that one embodiment of the present invention has at least one of the effects listed above and the other effects. Accordingly, depending on the case, one embodiment of the present invention does not have the effects listed above.

### BRIEF DESCRIPTION OF THE DRAWINGS

FIG. 1A and FIG. 1B are schematic cross-sectional views illustrating structure examples of a display apparatus.

FIG. 2A is a schematic plan view illustrating an example of a display portion of a display apparatus, and FIG. 2B is a schematic plan view illustrating an example of a driver circuit region of the display apparatus.

FIG. 3 is a block diagram illustrating a structure example of a display apparatus.

FIG. 4 is a schematic plan view illustrating a structure example of a display apparatus.

FIG. 5 is a block diagram illustrating a structure example of a display apparatus.

FIG. 6A and FIG. 6B are diagrams illustrating an example in which a display portion of a display apparatus is divided into a plurality of regions.

FIG. 7A is a diagram illustrating an example in which a plane of a display portion of a display apparatus is divided into a plurality of regions, and FIG. 7B is a diagram illustrating an example of the plane of the display portion of the display apparatus.

FIG. 8 is a diagram illustrating an example in which a display portion of a display apparatus is divided into a plurality of regions.

FIG. 9 is a schematic cross-sectional view illustrating a structure example of a display apparatus.

FIG. 10A and FIG. 10B are cross-sectional views each illustrating an example of a transistor.

FIG. 11A to FIG. 11D are schematic cross-sectional views each illustrating a structure example of an LED package.

FIG. 12A and FIG. 12B are schematic plan views each illustrating a structure example of an LED package.

FIG. 13A is a schematic cross-sectional view illustrating a structure example of a display apparatus, and FIG. 13B is a schematic cross-sectional view illustrating a structure example of a substrate provided in the display apparatus a light-emitting diode over the substrate.

FIG. 14 is a schematic cross-sectional view illustrating a structure example of a display apparatus.

FIG. 15 is a schematic cross-sectional view illustrating a structure example of a display apparatus.

FIG. 16 is a schematic cross-sectional view illustrating a structure example of a display apparatus.

FIG. 17A is a circuit diagram illustrating a structure example of a pixel circuit included in a display apparatus, and FIG. 17B is a schematic perspective view illustrating the structure example of the pixel circuit included in the display apparatus.

FIG. 18A to FIG. 18G are plan views illustrating examples of a pixel.

FIG. 19A to FIG. 19F are plan views illustrating examples of a pixel.

FIG. 20A to FIG. 20H are plan views illustrating examples of a pixel.

FIG. 21A to FIG. 21D are plan views illustrating examples of a pixel.

FIG. 22A to FIG. 22G are plan views illustrating examples of a pixel.

FIG. 23A and FIG. 23B are diagrams illustrating a structure example of a display module.

FIG. 24A to FIG. 24F are diagrams illustrating structure examples of an electronic device.

FIG. 25A to FIG. 25D are diagrams illustrating structure examples of electronic devices.

FIG. 26A to FIG. 26C are diagrams illustrating structure examples of an electronic device.

FIG. 27A to FIG. 27H are diagrams illustrating structure examples of electronic devices.

FIG. 28 is a diagram illustrating a structure example of a system.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. For example, an integrated circuit, a chip including an integrated circuit, an electronic component including a chip in a package and the like are each an example of the semiconductor device. Moreover, for example, a memory device, a display apparatus, a light-emitting apparatus, a lighting device, an electronic device, and the like themselves are semiconductor devices and include semiconductor devices in some cases.

In the case where there is description “X and Y are connected” in this specification and the like, a case where X and Y are electrically connected, a case where X and Y are functionally connected, and a case where X and Y are directly connected are regarded as being disclosed in this specification and the like. Accordingly, without being limited to a predetermined connection relation, for example, a connection relation shown in drawings or described with texts, a connection relation other than one shown in drawings or described with texts is regarded as being disclosed in the drawings or description with the texts. Each of X and Y denotes an object (e.g., a device, an element, a circuit, a wiring, an electrode, a terminal, a conductive film, a layer, or the like).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conducting state (on state) or a non-conducting state (off state) to control whether current flows or not.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit which is called a step-up circuit or a step-down circuit, or a level shifter circuit for changing the potential level of a signal); a voltage source; a current source; a switching circuit; an amplifier circuit (e.g., a circuit that can increase signal amplitude, the amount of current, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

It can be expressed as, for example, “X, Y, a source (called one of a first terminal and a second terminal in some cases) of a transistor, and a drain (called the other of the first terminal and the second terminal in some cases) of the transistor are electrically connected to each other, and X, the source of the transistor, the drain of the transistor, and Y are electrically connected to each other in this order”. Alternatively, it can be expressed as “a source of a transistor is electrically connected to X; a drain of the transistor is electrically connected to Y; and X, the source of the transistor, the drain of the transistor, and Y are electrically connected to each other in this order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression similar to the above examples, a source and a drain of a transistor can be distinguished from each other to specify the technical scope. Note that these expressions are examples and the expression is not limited to these expressions. Here, each of X and Y denotes an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both functions of a wiring and an electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” includes a wiring having a resistance value, a transistor in which current flows between a source and a drain, a diode, and a coil. Thus, the term “resistor” can be sometimes replaced with the terms “resistance”, “load”, “region having a resistance value”, or the like. Conversely, the term “resistor”, “load”, or “region having a resistance value” can be sometimes replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. As another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with the term “pair of electrodes”, “pair of conductive regions”, “pair of regions”, or “pair of terminals”. In addition, the terms “one of a pair of terminals” or “the other of the pair of terminals” is referred to as a first terminal or a second terminal in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the conducting state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of off-state current can be reduced, and the withstand voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

In this specification and the like, circuit elements such as a “light-emitting device” and a “light-receiving device” sometimes have polarities called an “anode” and a “cathode”. In the case of a “light-emitting device”, the “light-emitting device” can sometimes emit light when a forward bias is applied (a positive potential with respect to a “cathode” is applied to an “anode”). In the case of a “light-receiving device”, current is sometimes generated between an “anode” and a “cathode” when a zero bias or a reverse bias is applied (a negative potential with respect to a “cathode” is applied to an “anode”) and the “light-receiving device” is irradiated with light. As described above, an “anode” and a “cathode” are sometimes regarded as input/output terminals of the circuit elements such as a “light-emitting device” and a “light-receiving device”. In this specification and the like, an “anode” and a “cathode” of the circuit element such as a “light-emitting device” or a “light-receiving device” are sometimes called terminals (a first terminal, a second terminal, and the like). For example, one of an “anode” and a “cathode” is called a first terminal and the other of the “anode” and the “cathode” is called a second terminal in some cases.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and their gates are electrically connected to each other. Similarly, for another example, the case where a single switch is illustrated in a circuit diagram may include a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred as a node.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and, for example, a potential supplied to a wiring, a potential applied to a circuit or the like, and a potential output from a circuit or the like change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

“Current” means a charge transfer phenomenon (electrical conduction); for example, the description “electrical conduction of positively charged particles occurs” can be rephrased as “electrical conduction of negatively charged particles occurs in the opposite direction”. Therefore, unless otherwise specified, “current” in this specification and the like refers to a charge transfer phenomenon (electrical conduction) accompanied by carrier movement. Examples of a carrier here include an electron, a hole, an anion, a cation, and a complex ion, and the type of carrier differs between current flow systems (e.g., a semiconductor, a metal, an electrolyte solution, or a vacuum). The “direction of current” in a wiring or the like refers to the direction in which a carrier with a positive charge moves, and the amount of current is expressed as a positive value. In other words, the direction in which a carrier with a negative charge moves is opposite to the direction of current, and the amount of current is expressed as a negative value. Thus, in the case where the polarity of current (or the direction of current) is not specified in this specification and the like, the description “current flows from element A to element B” can be rephrased as a description “current flows from element B to element A”. The description “current is input to element A” can be rephrased as a description “current is output from element A”.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the SCOPE OF CLAIMS. For another example, a “first” component in one embodiment in this specification and the like can be omitted in other embodiments or the SCOPE OF CLAIMS.

In this specification and the like, the terms for describing positioning, such as “over” and “under”, are sometimes used for convenience to describe the positional relation between components with reference to drawings. The positional relation between components is changed as appropriate in accordance with the direction in which the components are described. Thus, the positional relation is not limited to the terms described in the specification and the like, and can be described with another term as appropriate depending on the situation. For example, the expression “an insulator positioned over (on) the top surface of a conductor” can be replaced with the expression “an insulator positioned under (on) a bottom surface of a conductor” when the direction of a drawing showing these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relation are sometimes described using terms such as “row” and “column”. The positional relation between components is changed as appropriate in accordance with the direction in which the components are described. Thus, the positional relation is not limited to the terms described in the specification and the like, and can be described with another term as appropriate depending on the situation. For example, the term “row direction” can be replaced with the term “column direction” when the direction of the diagram is rotated by 90°.

In this specification and the like, wirings electrically connect components arranged in a matrix can be extended in a row direction or a column direction. For example, in this specification and the like, in the case of description a “wiring A is extended in a row direction,” the wiring A can also be extended in a column direction in some cases. Similarly, in the case where the “wiring A is extended in the column direction,” the wiring A can also be extended in the row direction in some cases. That is, the direction in which the wirings that electrically connect components arranged in a matrix are extended is not limited to the direction described in this specification and the like, and can be the row direction or the column direction in some cases.

In this specification and the like, the terms “film” and “layer” can be interchanged with each other depending on the situation. For example, the term “conductive layer” can be changed into the term “conductive film” in some cases. For another example, the term “insulating film” can be changed into the term “insulating layer” in some cases. Alternatively, the terms “film” and “layer” are not used and can be interchanged with another term depending on the case or the situation. For example, the term “conductive layer” or “conductive film” can be changed into the term “conductor” in some cases. For another example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where a plurality of “electrodes”, “wirings” or “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. As another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Conversely, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also collectively referred to as a metal oxide in some cases. A metal oxide containing nitrogen may be called a metal oxynitride.

In this specification and the like, an impurity in a semiconductor refers to, for example, an element other than a main component of a semiconductor layer. For example, an element with a concentration of lower than 0.1 atomic % is an impurity. When an impurity is contained, for example, at least one of an increase in the density of defect states in a semiconductor, a decrease in carrier mobility, and a decrease in crystallinity occurs in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen. In addition, in the case where the semiconductor is a silicon layer, examples of an impurity that changes characteristics of the semiconductor include Group 1 elements, Group 2 elements, Group 13 elements, and Group 15 elements (except oxygen and hydrogen).

In this specification and the like, a switch has a function of being in a conducting state (on state) or a non-conducting state (off state) to control whether current flows or not. Alternatively, a switch has a function of selecting and changing a current path. Thus, a switch may have two terminals or three or more terminals through which current flows, in addition to a control terminal. For example, an electrical switch or a mechanical switch can be used. That is, a switch can be any element capable of controlling a current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conducting state” of the transistor refers to a state where a source electrode and a drain electrode of the transistor can be regarded as being electrically short-circuited or a state where current can flow between the source electrode and the drain electrode. Furthermore, a “non-conducting state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch using a MEMS (micro electro mechanical systems) technology. Such a switch includes an electrode that can be moved mechanically and controls conduction and non-conduction with movement of the electrode.

In this specification, “parallel” indicates a state where two straight lines are placed at an angle greater than or equal to −10′ and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 950 is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Therefore, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification, a plan view is sometimes used to explain a structure in each embodiment. A plan view is, for example, a diagram showing a plane of a structure seen in a direction perpendicular to a horizontal plane or a diagram showing a plane (section) of a structure cut in a horizontal direction (any of the planes is sometimes referred to as a plan view). Hidden lines (e.g., dashed lines) shown in a plan view can indicate the positional relation between a plurality of components included in a structure or the overlapping relation between the plurality of components. In this specification and the like, the term “plan view” can be replaced with the term “projection view”, “top view”, or “bottom view”. A plane (section) of a structure cut in a direction other than the horizontal direction may be referred to as a plan view depending on circumstances.

In this specification, a cross-sectional view is sometimes used to explain a structure in each embodiment. A cross-sectional view is, for example, a diagram showing a plane of a structure seen in a direction perpendicular to a horizontal plane or a diagram showing a plane (section) of a structure cut in a direction perpendicular to a horizontal plane (any of the planes is referred to as a cross-sectional view in some cases). In this specification and the like, the term “cross-sectional view” can be replaced with the term “front view” or “side view”. A plane (section) of a structure cut not in a direction perpendicular to a horizontal plane but in a direction other than the perpendicular direction may be referred to as a cross-sectional view depending on circumstances.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

In the drawings in this specification, the size, the layer thickness, or the region is exaggerated for clarity in some cases. Therefore, they are not limited to the illustrated scale. The drawings are schematic views showing ideal examples, and embodiments of the present invention are not limited to shapes, values, or the like shown in the drawings. For example, variations in signal, voltage, or current due to noise, variations in signal, voltage, or current due to difference in timing, or the like can be included.

### Embodiment 1

In this embodiment, a display apparatus of one embodiment of the present invention will be described.

### <Structure Example of Display Apparatus>

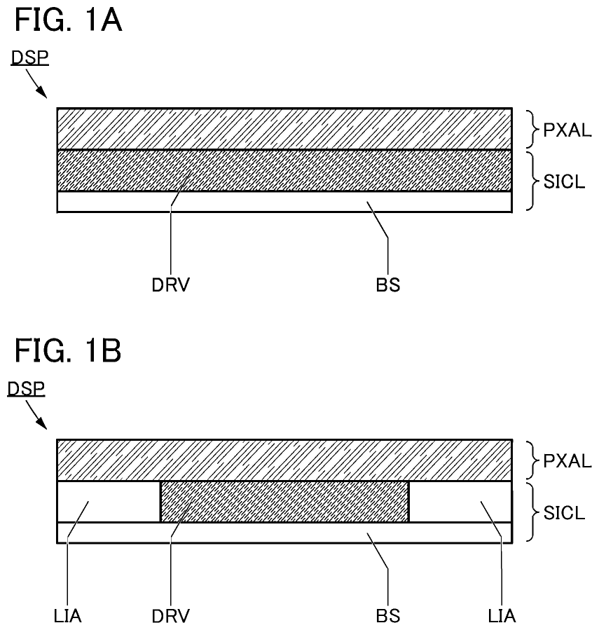

FIG. 1A is a schematic cross-sectional view of the display apparatus of one embodiment of the present invention. A display apparatus DSP illustrated in FIG. 1A includes a pixel layer PXAL and a circuit layer SICL as an example.

The pixel layer PXAL is provided over the circuit layer SICL. Note that the pixel layer PXAL overlaps with a region including a driver circuit region DRV described later.

The circuit layer SICL includes a substrate BS and the driver circuit region DRV.

As the substrate BS, for example, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, paper or a base material film including a fibrous material can be used. Examples of the glass substrate include barium borosilicate glass, aluminoborosilicate glass, and soda lime glass. Examples of the flexible substrate, the attachment film, the base material film, and the like, include plastics typified by polyethylene terephthalate (PET), polyethylene naphthalate (PEN), polyether sulfone (PES), and polytetrafluoroethylene (PTFE). Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the manufacturing process of the display apparatus DSP includes heat treatment, a highly heat-resistant material is preferably selected for the substrate BS.

Note that in this embodiment, the substrate BS is described as a substrate including a material with high resistance to heat, such as a glass substrate.

The driver circuit region DRV is provided over the substrate BS.

The driver circuit region DRV includes, for example, a driver circuit for driving a pixel included in the pixel layer PXAL to be described later. Note that a specific structure example of the driver circuit region DRV will be described later.

The pixel layer PXAL includes, for example, a plurality of pixels. The plurality of pixels may be arranged in a matrix in the pixel layer PXAL.

Each of the plurality of pixels can express one color or a plurality of colors. In particular, the plurality of colors can be, for example, three colors of red (R), green (G), and blue (B). Alternatively, the plurality of colors may be one or more of, for example, red (R), green (G), blue (B), cyan (C), magenta (M), yellow (Y), and white (W). Note that in the case where each of pixels expressing different colors is called a subpixel and white is expressed by a plurality of subpixels expressing different colors, the plurality of subpixels are collectively called a pixel in some cases. In this specification and the like, a subpixel is referred to as a pixel for convenience in some cases.

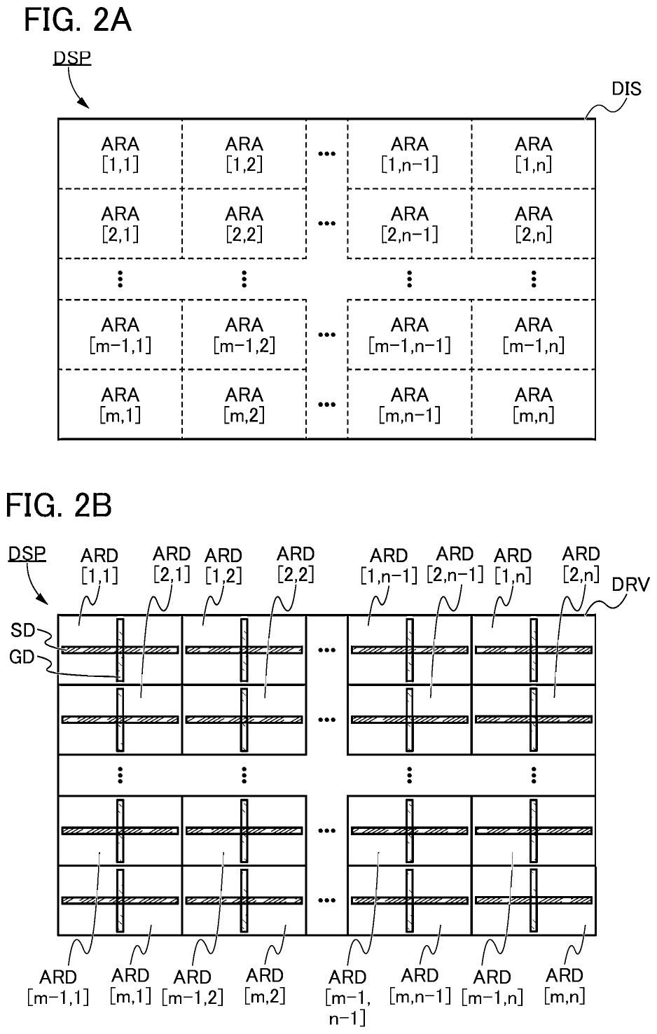

FIG. 2A is an example of a plan view of the display apparatus DSP and illustrates only a display portion DIS. Note that the display portion DIS can be a plan view of the pixel layer PXAL.

In the display apparatus DSP in FIG. 2A, the display portion DIS is divided into regions in m rows and n columns (m is an integer greater than or equal to 1, and n is an integer greater than or equal to 1) as an example. Thus, the display portion DIS includes a display region ARA[1,1] to a display region ARA[m,n]. Note that FIG. 2A selectively illustrates the display region ARA[1,1], the display region ARA[2,1], the display region ARA[m−1,1], the display region ARA[m,1], the display region ARA[1,2], the display region ARA[2,2], the display region ARA[m−1,2], the display region ARA[m,2], the display region ARA[1,n−1], the display region ARA[2,n−1], the display region ARA[m−1,n−1], the display region ARA[m,n−1], the display region ARA[1,n], the display region ARA[2,n], the display region ARA[m−1,n], and the display region ARA[m,n], as an example.

For example, in the case where the display portion DIS is divided into 32 regions, m=4 and n=8 may be substituted into FIG. 2A. In the case where the display apparatus DSP has a screen resolution of 8K4K, the number of pixels is 7680×4320. In the case where the colors of subpixels of the display portion DIS are three colors, red (R), green (G), and blue (B), the total number of subpixels is 7680×4320×3. Here, in the case where a pixel array of the display portion DIS with a screen resolution of 8K4K is divided into 32 regions, the number of pixels per region is 960×1080, and when the colors of the subpixels of the display apparatus DSP are three colors, red (R), green (G), and blue (B), the number of subpixels per region is 960×1080×3.

Here, in the case where the display portion DIS of the display apparatus DSP in FIG. 2A is divided into regions in m rows and n columns, the driver circuit region DRV included in the circuit layer SICL is considered.

FIG. 2B is an example of a plan view of the display apparatus DSP, and illustrates only the driver circuit region DRV included in the circuit layer SICL.

Since the display portion DIS of the display apparatus DSP in FIG. 2A is divided into regions in m rows and n columns, each of the display region ARA[1,1] to the display region ARA[m,n] which are divided from each other needs a corresponding driver circuit. Specifically, the driver circuit region DRV may also be divided into regions in m rows and n columns and a driver circuit may be provided in each of the divided regions.

The driver circuit region DRV in the display apparatus DSP in FIG. 2B includes regions divided into m rows and n columns. Thus, the driver circuit region DRV includes a circuit region ARD[1,1] to a circuit region ARD[m,n]. Note that FIG. 2B selectively illustrates the circuit region ARD[1,1], the circuit region ARD[2,1], the circuit region ARD[m−1,1], the circuit region ARD[m,1], the circuit region ARD[1,2], the circuit region ARD[2,2], the circuit region ARD[m−1,2], the circuit region ARD[m,2], the circuit region ARD[1,n−1], the circuit region ARD[2,n−1], the circuit region ARD[m−1,n−1], the circuit region ARD[m,n−1], the circuit region ARD[1,n], the circuit region ARD[2,n], the circuit region ARD[m−1,n], and the circuit region ARD[m,n], as an example.

Each of the circuit region ARD[1,1] to the circuit region ARD[m,n] includes a driver circuit SD and a driver circuit GD. For example, the driver circuit SD and the driver circuit GD included in the circuit region ARD[i,j] (not illustrated in FIG. 2B) positioned in the i-th row and the j-th column (i is an integer greater than or equal to 1 and less than or equal to m, and j is an integer greater than or equal to 1 and less than or equal to n) can drive a plurality of pixels included in the display region ARA[i,j] positioned in the i-th row and the j-th column (not illustrated in FIG. 2A) in the display portion DIS.

The driver circuit SD serves as, for example, a source driver circuit that transmits image signals to a plurality of pixels included in the corresponding circuit region ARD. The driver circuit SD may include a digital-analog conversion circuit that converts digital data of an image signal to analog data.

The driver circuit GD serves as, for example, a gate driver circuit that selects a plurality of pixels, which are destinations to which image signals are transmitted, in the corresponding circuit region ARD.

In FIG. 2A and FIG. 2B, the display region ARA[i,j] and the circuit region ARD[i,j] are positioned in a region where the display region ARA[i,j] and the circuit region ARD[i,j] overlap with each other in the plan view. When the display region ARA[i,j] and the circuit region ARD[i,j] overlap with each other, a wiring electrically connecting the display region ARA[i,j] and the circuit region ARD[i,j] can be shortened, so that the parasitic resistance of the wiring can be reduced. Furthermore, shortening the wiring can reduce parasitic capacitance of the wiring, and thus the time constant of the wiring can be decreased. When the time constant of the wiring is decreased, the time for writing an image to be displayed on the display region ARA[i,j] can be shortened, and the frame frequency can be consequently increased.

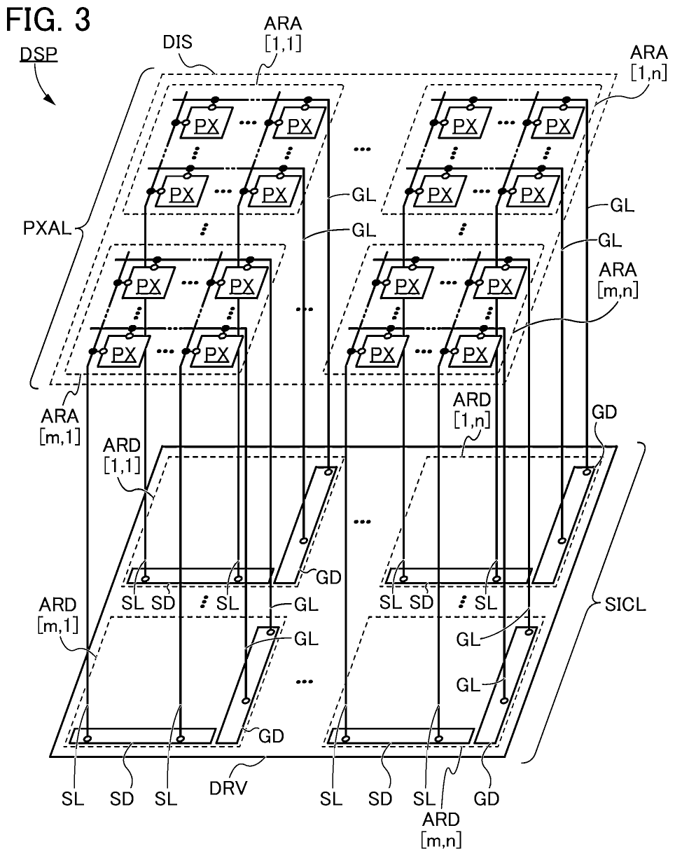

FIG. 3 is a perspective view of the display apparatus DSP illustrated in FIG. 2A and FIG. 2B. FIG. 3 selectively illustrates the display region ARA[1,1], the display region ARA[m,1], the display region ARA[1,n], and the display region ARA[m,n] as the display region ARA, and selectively illustrates the circuit region ARD[1,1], the circuit region ARD[m,1], the circuit region ARD[1,n], and the circuit region ARD[m,n] as the circuit region ARD.

In the display apparatus DSP in FIG. 3, each of a plurality of display regions ARA includes a plurality of pixels PX, for example. In the display region ARA, the plurality of pixels PX are arranged in a matrix.

In each of the plurality of display regions ARA, a plurality of wirings GL are extended in the row direction and a plurality of wirings SL are extended in the column direction.

Each of the plurality of pixels PX arranged in a matrix in the display region ARA is electrically connected to the wiring GL in the corresponding row. Similarly, each of the plurality of pixels PX is electrically connected to the wiring SL in the corresponding column.

In the display apparatus DSP in FIG. 3, each of a plurality of circuit regions ARD includes the driver circuit SD and the driver circuit GD as in the display apparatus DSP illustrated in FIG. 2B.

As described with reference to FIG. 2A and FIG. 2B, the driver circuit SD and the driver circuit GD included in the circuit region ARD[i,j] have a function of driving a plurality of pixels included in the display region ARA[i,j]. Thus, the driver circuit SD included in the circuit region ARD[i,j] is electrically connected to the plurality of wirings SL extending in the display region ARA[i,j]. The driver circuit GD included in the circuit region ARD[i,j] is electrically connected to the plurality of wirings GL extended to the display region ARA[i,j].

In order to electrically connect the display region ARA[i,j] and the circuit region ARD[i,j], the plurality of wirings SL and the plurality of wirings GL are provided between the display portion DIS and the driver circuit region DRV.

When the display region ARA[i,j] and the circuit region ARD[i,j] are arranged so as to overlap with each other, the wiring electrically connecting the display region ARA[i,j] and the circuit region ARD[i,j] to each other can be extended in the direction perpendicular or substantially perpendicular to the substrate BS, for example. When the wiring is extended in the perpendicular direction or substantially perpendicular direction, the length of the wiring can be shortened; thus, the parasitic resistance of the wiring can be reduced as described above. In addition, the parasitic capacitance of the wiring can be reduced. Accordingly, a voltage for supplying current to the wiring can be reduced, leading to reduced power consumption.

Note that the display apparatus DSP illustrated in FIG. 1A, FIG. 2A, FIG. 2B, and FIG. 3 has a structure in which the display region ARA[i,j] and the circuit region ARD[i,j] overlap with each other in the display portion DIS; however, the display apparatus of one embodiment of the present invention is not limited to the structure. In a structure of the display apparatus of one embodiment of the present invention, the display region ARA[i,j] and the circuit region ARD[i,j] do not necessarily overlap with each other.

For example, as illustrated in FIG. 1B, the display apparatus DSP may have a structure in which not only the driver circuit region DRV but also a region LIA is provided over the substrate BS.

A wiring is provided in the region LIA, as an example. At this time, the display apparatus DSP may have a structure in which a circuit included in the driver circuit region DRV and a circuit included in the pixel layer PXAL are electrically connected to each other through the wiring included in the region LIA.

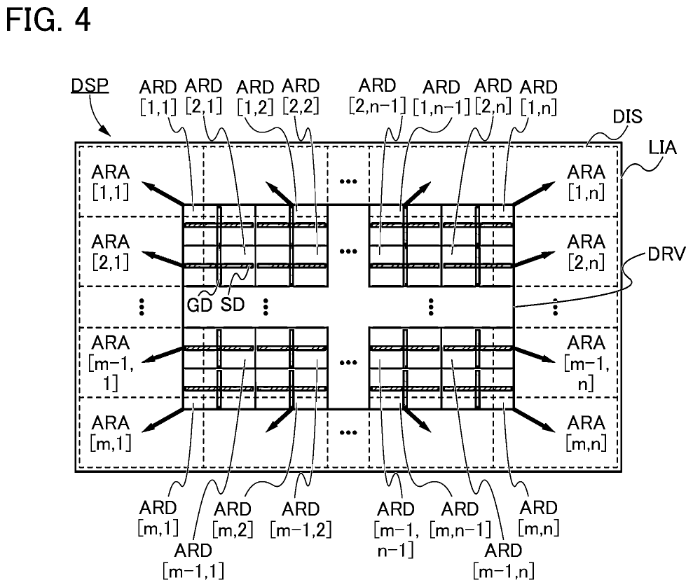

FIG. 4 is an example of a plan view of the display apparatus DSP illustrated in FIG. 1B, and illustrates the driver circuit region DRV denoted by a solid line and the display portion DIS denoted by a dotted line. The display apparatus DSP in FIG. 4 has a structure in which the driver circuit region DRV is surrounded by the region LIA, as an example. Thus, as illustrated in FIG. 4, the driver circuit region DRV is provided to overlap with the inside of the display portion DIS in the plan view.

In the display apparatus DSP illustrated in FIG. 4, the display portion DIS is divided into the display region ARA[1,1] to the display region ARA[m,n] and the driver circuit region DRV is also divided into the circuit region ARD[1,1] to the circuit region ARD[m,n] as in FIG. 2A.

In FIG. 4, a correspondence between the display region ARA and the circuit region ARD including a driver circuit that drives a pixel included in the display region ARA is shown by a thick arrow. Specifically, a driver circuit included in the circuit region ARD[1,1] drives a pixel included in the display region ARA[1,1], and a driver circuit included in the circuit region ARD[2,1] drives a pixel included in the display region ARA[2,1]. A driver circuit included in the circuit region ARD[m−1,1] drives a pixel included in the display region ARA[m−1,1], and a driver circuit included in the circuit region ARD[m,1] drives a pixel included in the display region ARA[m,1]. A driver circuit included in the circuit region ARD[1,n] drives a pixel included in the display region ARA[1,n], and a driver circuit included in the circuit region ARD[2,n] drives a pixel included in the display region ARA[2,n]. A driver circuit included in the circuit region ARD[m−1,n] drives a pixel included in the display region ARA[m−1,n], and a driver circuit included in the circuit region ARD[m,n] drives a pixel included in the display region ARA[m,n]. That is, although not illustrated in FIG. 4, a driver circuit included in the circuit region ARD[i,j] positioned in the i-th row and the j-th column drives a pixel included in the display region ARA[i,j].

In FIG. 1B, when the driver circuit included in the circuit region ARD in the circuit layer SICL and the pixel included in the display region ARA in the pixel layer PXAL are electrically connected through a wiring, the display apparatus DSP can have a structure in which the display region ARA[i,j] and the circuit region ARD[i,j] do not necessarily overlap with each other. Accordingly, the positional relation between the driver circuit region DRV and the display portion DIS is not limited to the plan view of the display apparatus DSP in FIG. 4, and the position of the driver circuit region DRV can be freely determined.

Note that in FIG. 2B and FIG. 4, the driver circuit SD and the driver circuit GD are arranged so as to form a cross in each of the circuit region ARD[1,1] to the circuit region ARD[m,n]; however, the arrangement of the driver circuit SD and the driver circuit GD is not limited to the structure of the display apparatus of one embodiment of the present invention. For example, the arrangement of the driver circuit SD and the driver circuit GD may form an L shape in one circuit region ARD in the driver circuit region DRV as illustrated in FIG. 3. Alternatively, one of the driver circuit SD and the driver circuit GD may be placed in upper and lower parts in a plan view and the other of the driver circuit SD and the driver circuit GD may be placed in right and left parts in the plan view.

As illustrated in FIG. 2A to FIG. 4, the display portion DIS of the display apparatus DSP is divided into the display region ARA[1,1] to the display region ARA[m,n], and the driver circuit SD and the driver circuit GD are provided in the circuit region ARD corresponding to each display regions ARA, whereby each of the display region ARA[1,1] to the display region ARA[m,n] can be independently driven. For example, for the display region ARA in which image data is often rewritten, the driver circuit SD and the driver circuit GD provided in the corresponding the circuit region ARD can be driven with a high frame frequency; and for the display region ARA in which image data is not often rewritten, the driver circuit SD and the driver circuit GD provided in the corresponding the circuit region ARD can be driven with a low frame frequency. Specifically, the driver circuit SD and the driver circuit GD corresponding to the display region ARA in which image data is often rewritten to display moving images or the like may be driven with a high frame frequency of higher than or equal to 60 Hz, higher than or equal to 120 Hz, higher than or equal to 165 Hz, or higher than or equal to 240 Hz. For example, the driver circuit SD and the driver circuit GD corresponding to the display region ARA in which image data is not often rewritten to display a still image or the like may be driven with a low frame frequency of lower than or equal to 5 Hz, lower than or equal to 1 Hz, lower than or equal to 0.5 Hz, or lower than or equal to 0.1 Hz. In this manner, the display portion DIS of the display apparatus DSP is divided into the display region ARA[1,1] to the display region ARA[m,n], whereby the rewrite frequency (frame frequency) can be changed depending on an image displayed on the display region ARA. That is, in the display portion DIS of the display apparatus DSP, two selected from the display region ARA[1,1] to the display region ARA[m,n] can display images with different frame frequencies.

When any of a glass substrate, a metal substrate, and a base material film is used as the substrate BS, the diagonal size of the display apparatus DSP can be easily increased as compared with the case of using a semiconductor substrate including silicon or the like as a material. In particular, a substrate having a substrate size such as the second generation (approximately 370 mm×470 mm), the third generation (approximately 550 mm×650 mm), the fourth generation (approximately 680 mm×880 mm), or a substrate size exceeding the fourth generation is selected as the glass substrate, in which case the display apparatus DSP having a diagonal size larger than the diameter (approximately 12 inches) of a silicon wafer mainly used in the current semiconductor process can be manufactured.

### <Structure Example Pf Control Circuit>

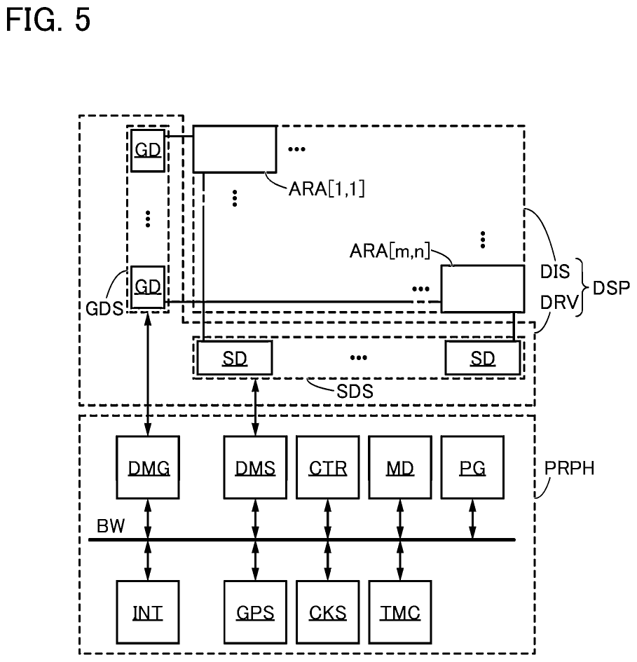

Next, an example of the display apparatus DSP and a control circuit provided outside the display apparatus DSP will be described. FIG. 5 is a block diagram illustrating an example of the display apparatus DSP and a control circuit PRPH.

The display apparatus DSP illustrated in FIG. 5 includes the display portion DIS and the driver circuit region DRV. The driver circuit region DRV includes a circuit GDS including a plurality of driver circuits GD and a circuit SDS including a plurality of driver circuits SD. The control circuit PRPH includes a distribution circuit DMG, a distribution circuit DMS, a control unit CTR, a memory device MD, a voltage generation circuit PG, a timing controller TMC, a clock signal generation circuit CKS, an image processing portion GPS, and an interface INT.

Note that in the display apparatus DSP, the driver circuit region DRV including the plurality of driver circuits GD overlaps with the pixel layer PXAL including the plurality of display regions ARA as illustrated in FIG. 2A to FIG. 4; however, FIG. 5 illustrates the plurality of driver circuits GD arranged in a column, for convenience. Similarly, the driver circuit region DRV including the plurality of driver circuits SD overlaps with the pixel layer PXAL including the plurality of display regions ARA as illustrated in FIG. 2A to FIG. 4; however, FIG. 5 illustrates the plurality of driver circuits SD arranged in a row, for convenience.

The control circuit PRPH is electrically connected to the outside of the display apparatus DSP illustrated in FIG. 1A to FIG. 4, for example.

The distribution circuit DMG, the distribution circuit DMS, the control unit CTR, the memory device MD, the voltage generation circuit PG, the timing controller TMC, the clock signal generation circuit CKS, the image processing portion GPS, and the interface INT transmit and receive signals mutually through a bus wiring BW.

The interface INT has, for example, a function of a circuit for taking image information output from an external device for displaying an image on the display apparatus DSP into the circuit in the control circuit PRPH. Examples of the external device include a recording media player and a nonvolatile memory device such as an HDD (Hard Disk Drive) and an SSD (Solid State Drive). The interface INT may be a circuit that outputs a signal from a circuit inside the control circuit PRPH to a device outside the display apparatus DSP.

In the case where image information is input from the external device to the interface INT by wireless communication, the interface INT can include, for example, an antenna receiving the image information, a mixer, an amplifier circuit, and an analog-digital conversion circuit.

The control unit CTR has functions of processing control signals transmitted from the external device through the interface INT and controlling circuits included in the control circuit PRPH.

The memory device MD has a function of temporarily holding data and an image signal. In that case, the memory device MD serves as a frame memory (referred to as a frame buffer in some cases), for example. The memory device MD may have a function of temporarily holding at least one piece of information transmitted from the external device through the interface INT and information processed in the control unit CTR. In that case, at least one of an SRAM (Static Random Access Memory) and a DRAM (Dynamic Random Access Memory) can be used as the memory device MD, for example.

The voltage generation circuit PG has a function of generating power supply voltages supplied to a pixel circuit included in the display portion DIS and a circuit included in the control circuit PRPH. Note that the voltage generation circuit PG may have a function of selecting a circuit to which a voltage is to be supplied. For example, the voltage generation circuit PG stops supply of voltage to the circuit GDS, the circuit SDS, the image processing portion GPS, the timing controller TMC, and the clock signal generation circuit CKS in a period in which a still image is displayed on the display portion DIS, enabling a reduction in the total power consumption of the display apparatus DSP.

The timing controller TMC has a function of generating timing signals used in the plurality of driver circuits GD included in the circuit GDS and the plurality of driver circuits SD included in the circuit SDS. For the generation of the timing signal, a clock signal generated by the clock signal generation circuit CKS can be used.

The image processing portion GPS has a function of performing processing for drawing an image on the display portion DIS. For example, the image processing portion GPS may include a GPU (Graphics Processing Unit). Specifically, the image processing portion GPS is configured to perform pipeline processing in parallel and can thus perform high-speed processing of image data to be displayed on the display portion DIS. The image processing portion GPS can also have a function of a decoder for decoding an encoded image.

In FIG. 5, the image processing portion GPS has a function of receiving image data to be displayed on each of the display region ARA[1,1] to the display region ARA[m,n] and generating an image signal from the image data, for example.

The image processing portion GPS may have a function of correcting the color tone of an image displayed on the display region ARA[1,1] to the display region ARA[m,n]. In that case, the image processing portion GPS is preferably provided with one or both of a dimming circuit and a toning circuit. In the case where the display pixel circuit included in the display portion DIS includes an organic EL element, the image processing portion GPS may be provided with an EL correction circuit.

The above-described image correction may be performed using artificial intelligence. For example, a current flowing in a display device included in a pixel (or a voltage applied to the display device) may be monitored and obtained, an image displayed on the display portion DIS may be obtained with an image sensor or the like, the current (or voltage) and the image may be used as input data in an arithmetic operation of the artificial intelligence (e.g., an artificial neural network), and the output result may be used to determine whether the image is needed to be corrected.

Such an arithmetic operation of artificial intelligence can be applied not only to image correction but also to upconversion processing of image data. Accordingly, upconversion of low screen resolution image data can be performed in accordance with the screen resolution of the display portion DIS, which enables a high-display-quality image to be displayed on the display portion DIS. Such an arithmetic operation of artificial intelligence can be applied to downconversion processing of image data.

Note that the above-described arithmetic operation of artificial intelligence is performed by the GPU included in the image processing portion GPS, for example. That is, the GPU can be used to perform arithmetic operations for various kinds of correction (e.g., color irregularity correction or upconversion).

Note that in this specification and the like, such a GPU performing an arithmetic operation of artificial intelligence is referred to as an AI accelerator. That is, the GPU may be replaced with an AI accelerator in the description in this specification and the like.

The clock signal generation circuit CKS has a function of generating a clock signal for displaying a desired image on each of the display region ARA[1,1] to the display region ARA[m,n], for example.

In the case where the image rewriting frequency (frame frequency) is different among the display region ARA[1,1] to the display region ARA[m,n], the clock signal generation circuit CKS preferably has a function of generating a clock signal with the frame frequency corresponding to each of the display region ARA[1,1] to the display region ARA[m,n]. That is, the clock signal generation circuit CKS preferably has a function of generating clock signals with different frequencies at the same time.

The distribution circuit DMG has a function of transmitting a signal received from the bus wiring BW to the driver circuit GD for driving pixels included in any one of the display region ARA[1,1] to the display region ARA[m,n], in accordance with the content of the signal.

The distribution circuit DMS has a function of transmitting a signal received from the bus wiring BW to the driver circuit SD for driving pixels included in any one of the display region ARA[1,1] to the display region ARA[m,n], in accordance with the content of the signal.

FIG. 5 illustrates a state where the distribution circuit DMG transmits a signal directly to the circuit GDS; however, the signal transmitted from the distribution circuit DMG may be input to the circuit GDS through the interface INT. Similarly, the distribution circuit DMS transmits a signal directly to the circuit SDS in FIG. 5; however, the signal transmitted from the distribution circuit DMS may be input to the circuit SDS through the interface INT.

Although not illustrated in FIG. 5, a level shifter may be included in the control circuit PRPH. The level shifter has a function of converting signals input to circuits into appropriate levels, for example.

Note that the structure of the control circuit PRPH illustrated in FIG. 5 is an example, and the circuit structure included in the control circuit PRPH may be changed depending on circumstances. For example, in the case where the control circuit PRPH receives driving voltages of circuits from the outside, the control circuit PRPH does not need to generate the driving voltages. In that case, the control circuit PRPH may have a structure without including the voltage generation circuit PG.

For another example, some or all of the circuits included in the control circuit PRPH may be included in the circuit layer SICL of the display apparatus DSP. Specifically, in the case of the display apparatus DSP in FIG. 1A, some or all of the circuits included in the control circuit PRPH may be included in the driver circuit region DRV. In the case of the display apparatus DSP in FIG. 1B, some or all of the circuits included in the control circuit PRPH may be included in the driver circuit region DRV or the region LIA.

Note that this embodiment can be combined with any of the other embodiments in this specification as appropriate.

### Embodiment 2

In this embodiment, an example in which images are displayed so that display quality of the images is different for each divided display ARA in the above-described display apparatus DSP will be described.

Note that the display quality here is determined by one or both of the level of the screen resolution (the level of definition (pixel density)) and the level of frame frequency, for example. For example, when the screen resolution (definition) of the display apparatus DSP is increased, the display apparatus DSP can exhibit an image on the display apparatus DSP as a higher resolution image; however, the amount of data of the displayed image is increased. On the other hand, when the screen resolution (definition) of the display apparatus DSP is decreased, the display apparatus DSP exhibit a rough image on the display apparatus DSP; however, the amount of data of the displayed image is decreased. For example, when the frame frequency of the display apparatus DSP is increased, the display apparatus DSP can express a movement of an image on the display apparatus DSP smoothly; however, the amount of data of the displayed image is increased. On the other hand, when the frame frequency of the display apparatus DSP is decreased, the display apparatus DSP expresses a movement of an image on the display apparatus DSP roughly; however, the amount of data of the displayed image can be decreased.

In addition, an example of change of the screen resolution here is described. In the case where the screen resolution of the display portion DIS in the display apparatus DSP is 8K4K, the number of pixels PX included in the display portion DIS is 7680×4320. Here, in the case where the screen resolution of the display portion DIS of the display apparatus DSP is changed to 4K2K (3840×2160), the matrix of the pixels PX of the display portion DIS are divided into regions in two rows and two columns and four pixels PX included in the regions are regarded as one pixel; the display apparatus DSP can be driven as a display apparatus with the screen resolution of 4K2K when the same image signal is transmitted to the four pixels PX included in the same region. Accordingly, when the screen resolution of the display portion DIS is changed from 8K4K to 4K2K, the definition of the display portion DIS can be regarded as being decreased to substantially ½. In addition, in the case where the screen resolution of the display portion DIS of the display apparatus DSP is changed to FHD (1920×1080), the matrix of the pixels PX of the display portion DIS are divided into regions in four rows and four columns and 16 pixels PX included in the regions are regarded as one pixel; the display apparatus DSP with 8K4K can be driven as a display apparatus with an FHD screen resolution when the same image signal is transmitted to four pixels included in the same region. Accordingly, when the screen resolution of the display portion DIS is changed from 8K4K to FHD, the resolution of the display portion DIS can be regarded as being decreased to substantially one fourth. In the case where the screen resolution of the display portion DIS of the display apparatus DSP is changed to HD (1280×720), the matrix of the pixels PX of the display portion DIS are divided into regions in six rows and six columns and 36 pixels PX in the regions are regarded as one pixel; the display apparatus DSP with 8K4K can be driven as a display apparatus with an HD screen resolution when the same image signal is transmitted to 36 pixels PX included in the same region. Accordingly, when the screen resolution of the display portion DIS is changed from 8K4K to HD, the resolution of the display portion DIS can be regarded as being decreased to substantially one sixth.

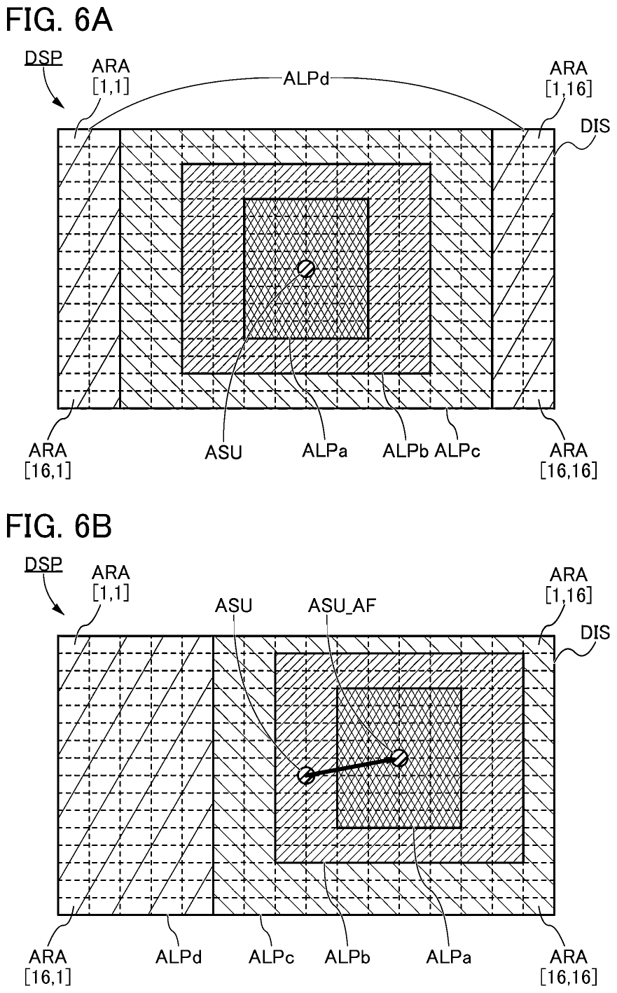

FIG. 6A illustrates an example in which the display portion DIS of the display apparatus DSP is divided into display regions in 16 rows and 16 columns (i.e., p=16 and q=16 in FIG. 2A).

The display apparatus DSP is provided with a function of sensing the user's gaze. For example, an imaging device is provided in the display apparatus DSP. The imaging device captures an image of the user's eye and the movement of the eyeball is calculated from the captured image of the user's eye. Examples of calculating the movement of the eyeball include is a corneal reflection method (PCCR method).

When the display apparatus DSP has a function of sensing the user's gaze, the display apparatus DSP can determine which portion of a pixel array ALP the user is looking at. For example, in FIG. 6A, a region ASU is determined as the region the user is looking at (referred to as a region of a user's gaze destination in some cases) by eye tracking function of the display apparatus DSP.

Since the region ASU is at the user's gaze destination, the user can see the region ASU clearly. On the other hand, it is difficult for user to see clearly a region apart from the region ASU (i.e., the region which is included in the visual field of the user but where the user is not gazing, or region where the user is not gazing). In other words, the user does not consciously pay attention to an image displayed on the display region ARA apart from the region ASU; therefore, high display quality of the display region ARA is not particularly needed.

Here, the display apparatus DSP set regions based on the region ASU detected by eye tracking function as illustrated in FIG. 6A; a region ALPa is set around the region ASU; a region ALPb is set so as to surround the region ALPa; a region ALPc is set so as to surround the region ALPb; and a region ALPd is set so as to surround the region ALPc. Then, the screen resolution (definition) is set in each of the display regions ARA included in the region ALPa to the region ALPd. Here, the screen resolution (definition) of the display region ARA included in the region ALPa is Rₐ, the screen resolution (definition) of the display region ARA included in the region ALPb is R_{b}, the screen resolution (definition) of the display region ARA included in the region ALPc is R_{c}, and the screen resolution (definition) of the display region ARA included in the region ALPd is R_{d}. In particular, it is preferable that Rₐ be higher than R_{b}, R_{b} be higher than R_{c}, and R_{c} be higher than R_{d}.

As described above, when the screen resolution (definition) of the display region ARA around the region ASU that is the user's gaze destination is increased and the screen resolution (definition) of the display region ARA apart from the region ASU is decreased, the amount of image data transmitted to the display portion DIS of the display apparatus DSP can be reduced. Accordingly, the performance of an interface for transmitting image data to the display apparatus DSP is not necessarily improved; therefore, the power consumption and cost can be reduced. Similarly, since the amount of image data transmitted to the display region ARA is reduced, power consumption can be reduced in a circuit included in the circuit region ARD which drives the pixel PX included in the display region ARA with the low screen resolution (definition).

It is difficult for the user to see the display region ARA apart from the region ASU clearly. Therefore, even when the screen resolution (definition) of the display region ARA apart from the region ASU is decreased and when the display quality of the image displayed on the whole of the pixel array ALP is decreased, the influence of the decreases is small in the case where the user sees the image displayed on the pixel array ALP.

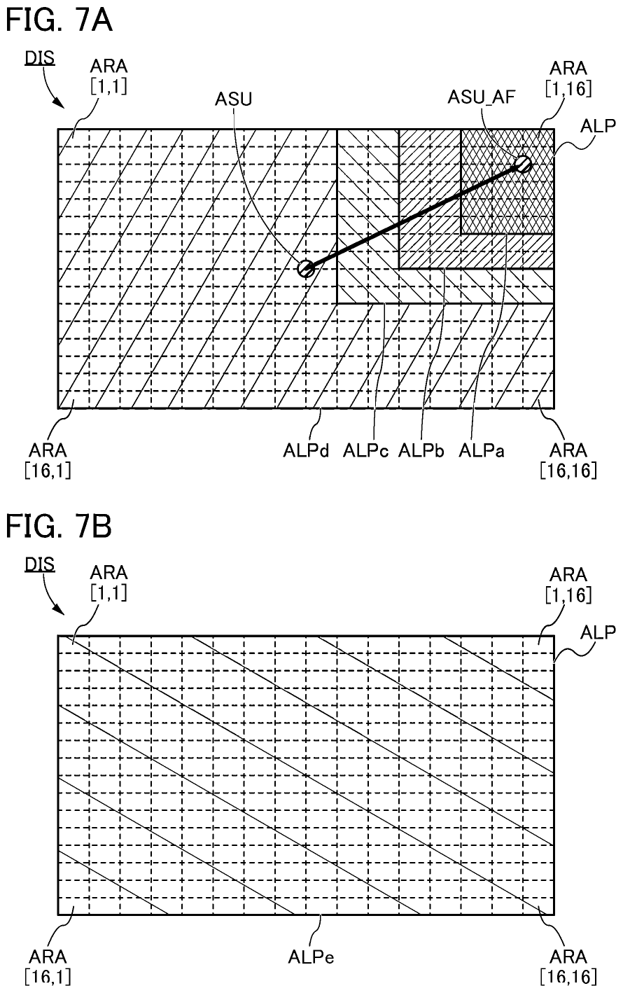

In the case where the position of the region ASU is changed as the user's gaze moves, the positions and the ranges of the region ALPa, the region ALPb, the region ALPc, and the region ALPd may also be changed. For example, as illustrated in FIG. 6B or FIG. 7A, when a region to be the user's gaze destination changes from the region ASU to a region ASU_AF, the positions of the region ALPa, the region ALPb, the region ALPc, and the region ALPd is changed. Note that in the modification example in FIG. 6B, the ranges (sizes) of the region ALPa and the region ALPb are not changed, the range of the region ALPc is reduced, and the range of the region ALPd is enlarged. FIG. 7A shows a modification example in which the region to be the user's gaze destination is changed from the region ASU to the region ASU_AF which is in the vicinity of an end portion of the pixel array ALP, and each of the ranges of the region ALPa, the region ALPb, and the region ALPc is reduced and the range of the region ALPd is enlarged.

In the case where the eye tracking function of the display apparatus DSP does not sense the user's gaze, the display apparatus DSP may set the whole of the pixel array ALP to a region ALPe as illustrated in FIG. 7B. Note that the case where the user's gaze is not sensed include the case where the user's eyelids are closed, the case where the user is asleep, and the like. The screen resolution (definition) of the display region ARA included in the region ALPe may be lower than that of the region ALPd, for example. Alternatively, the display apparatus DSP may perform an operation of not transmitting an image signal to the pixel PX in the display region ARA included in the region ALPe. In other words, the display apparatus DSP may perform an operation of transmitting an image signal of black display to the pixel PX in the display region ARA included in the region ALPe.

In the display apparatus DSP in FIG. 6A and FIG. 6B, the display portion DIS is divided into four: the region ALPa, the region ALPb, the region ALPc, and the region ALPd, and sets the region ALPa, the region ALPb, the region ALPc, and the region ALPd with different screen resolution (definition) from each other; however, the display apparatus of one embodiment of the present invention is not limited thereto. For example, the display portion DIS of the display apparatus DSP may be divided into two, three or five or more regions and may have different screen resolution (definition) among the regions.

FIG. 6A to FIG. 7B show examples that the screen resolution (definition) is changed among the region ALPa, the region ALPb, the region ALPc, and the region ALPd which are in the display portion DIS of the display apparatus DSP; however, not the screen resolution (definition) but the frame frequency may be changed among the region ALPa, the region ALPb, the region ALPc, and the region ALPd. For example, the frame frequency of the display region ARA included in the region ALPa can be higher than the frame frequency of the display region ARA included in the region ALPb, the frame frequency of the display region ARA included in the region ALPb can be higher than the frame frequency of the display region ARA included in the region ALPc, and the frame frequency of the display region ARA included in the region ALPc can be higher than the frame frequency of the display region ARA included in the region ALPd; therefore, the amount of the image data transmitted to the display region ARA in the vicinity of the region ASU can be increased, whereby an image with high display quality can be seen by the user. As described above, by setting the frame frequency of each region in the display portion DIS, the amount of image data transmitted to the display region ARA apart from the region ASU can be reduced; therefore, the load on the driver circuit for driving pixels included in the display region ARA can be reduced.

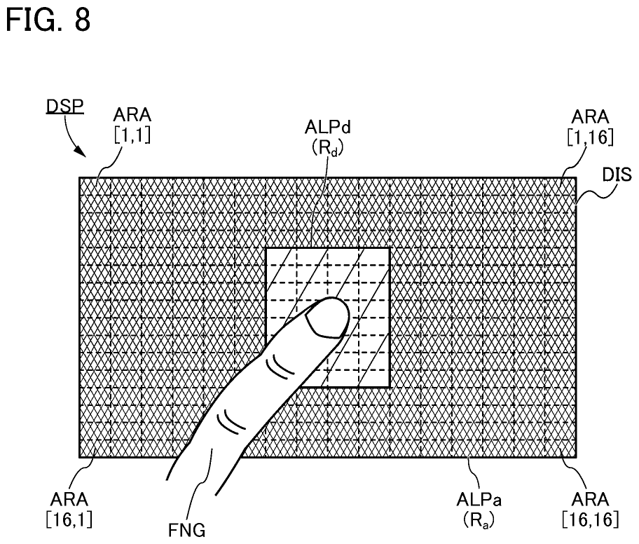

Although in the description of the display apparatus DSP with reference to FIG. 6A to FIG. 7B, the example in which the display quality of the image in the vicinity of the region the user see is increased by eye tracking function is described, one embodiment of the present invention is not limited thereto. For example, one embodiment of the present invention may have a structure in which the display quality of each region of the display portion DIS of the display apparatus DSP is changed not by eye tracking function for sensing the gaze but by the touch sensor function for sensing a finger of the user. For example, FIG. 8 illustrates an example in which a user's finger FNG touched the display portion DIS of the display apparatus DSP. When the image on the display portion DIS is scrolled by motion such as sliding the user's finger FNG with touching the display portion DIS, the user is gazing not at the display region ARA around the user's finger FNG but at the display region ARA apart from the user's finger FNG in many cases. Therefore, as shown in FIG. 8, the image resolution of the display regions ARA in the region ALPd including the region touched by the finger FNG and its vicinity thereof of the display portion DIS can be decreased, and the image resolution of the display regions ARA in the region ALPa, other than the display regions ARA in the region ALPd, of the display portion DIS can be increased. Alternatively, the frame frequency of the display region ARA in the region ALPd including the region touched by the finger FNG and its vicinity thereof can be decreased, and the frame frequency of the display regions ARA in the region ALPa, other than the display regions ARA in the region ALPd, of the display portion DIS can be increased.

Although the example in which the display quality of the region ALPa is increased and the display quality of the region ALPd is decreased is described with reference to FIG. 8, the display quality of the display region ARA in the region ALPd including the touched region by the finger FNG and its vicinity can be increased, and the display quality of the display regions ARA in the region ALPa, other than the display regions ARA in the region ALPd, of the display portion DIS can be decreased.

The structure described in this embodiment can be used in an appropriate combination with any of the structures described in the other embodiments.

### Embodiment 3

In this embodiment, a display apparatus that can be provided for the electronic device of one embodiment of the present invention will be described. Note that the display apparatus described in this embodiment can be used for the display apparatus DSP described in the above embodiment.

### <Structure Example of Display Apparatus>

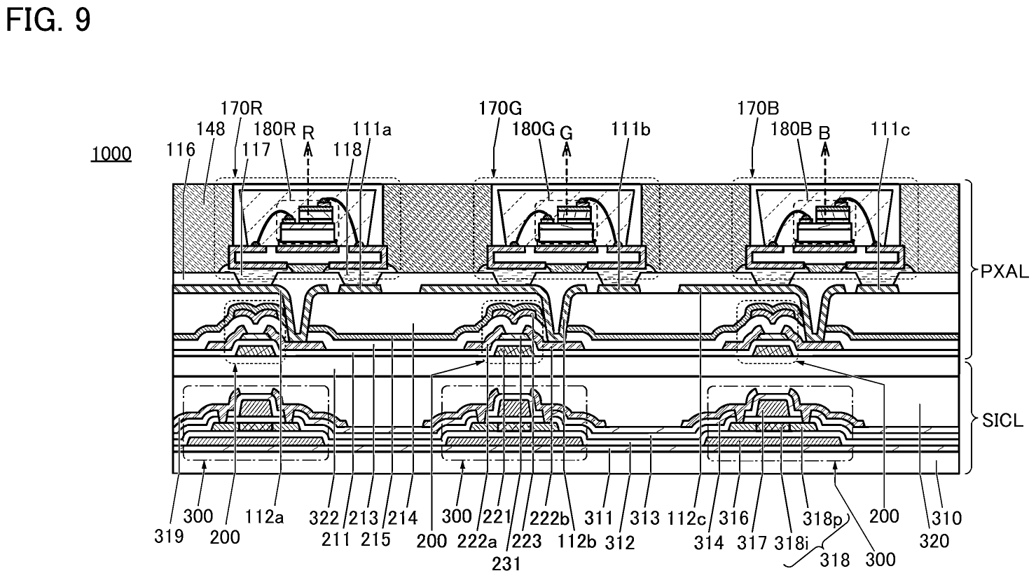

FIG. 9 is a cross-sectional view illustrating an example of a display apparatus of one embodiment of the present invention. A display apparatus 1000 illustrated in FIG. 9 has a structure in which a pixel circuit and a driver circuit are provided over a substrate 310, for example. Note that the display apparatus DSP described in the above embodiment can have a structure of the display apparatus 1000 in FIG. 9.

Specifically, for example, the circuit layer SICL and the pixel layer PXAL shown in the display apparatus DSP in FIG. 1 can have structures in the display apparatus 1000 in FIG. 9. The display apparatus 1000 in FIG. 9 has a structure in which a circuit element and a light-emitting diode are formed over the substrate 310, for example. Specifically, a transistor 300 is formed over the substrate 310. In addition, a transistor 200, an LED package 170R, an LED package 170G, and an LED package 170B are provided over the transistor 300. Note that a wiring electrically connecting the transistor 300 and the transistor 200 is provided between the transistors (not illustrated). The pixel layer PXAL includes the transistor 200, the LED package 170R, the LED package 170G, and the LED package 170B, for example. Note that in this specification and the like, the LED package 170R, the LED package 170G, and the LED package 170B are collectively referred to as an LED package 170.

The substrate 310 corresponds to, for example, the substrate BS described in Embodiment 1. Thus, the substrate 310 is preferably a substrate usable as the substrate BS as described in Embodiment 1.

In particular, the substrate 310 preferably blocks visible light (has a non-transmitting property with respect to visible light). When the substrate 310 blocks visible light, entry of light from the outside into the transistor 200 and the transistor 300 formed over the substrate 310 can be inhibited. Note that one embodiment of the present invention is not limited thereto, and the substrate 310 may have a property of transmitting visible light.

The substrate 310 may include one or both of a reflective layer reflecting light from an LED chip 180R, an LED chip 180G, and an LED chip 180B (light-emitting diodes) which are respectively included in the LED package 170R, the LED package 170G, and the LED package 170B and a light-blocking layer which blocks the light.

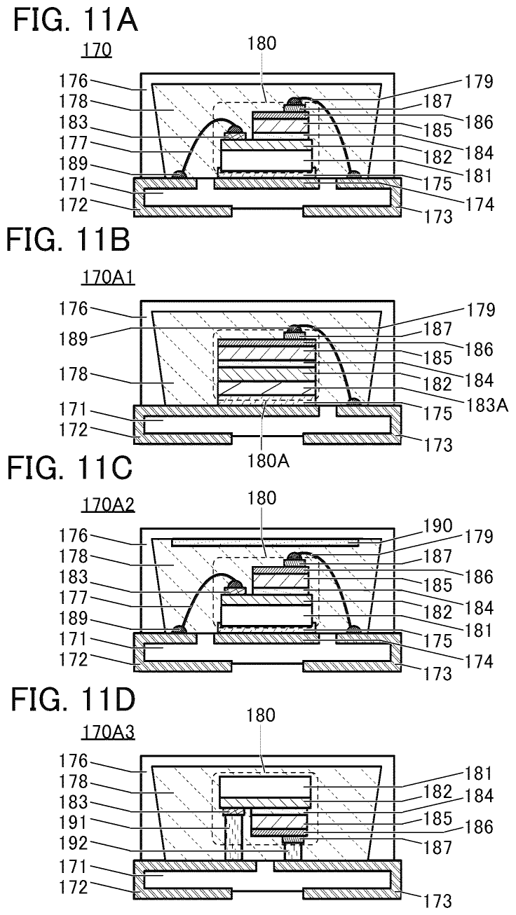

An LED chip is a light-emitting diode in which an electrode serving as a cathode, an electrode serving as an anode, a p-type semiconductor, an n-type semiconductor, and a light-emitting layer are provided over a substrate. Specifically, in this specification and the like, a light-emitting diode whose LED chip area is less than or equal to 10000 μm² is referred to as a micro light-emitting diode, a light-emitting diode whose LED chip area is greater than 10000 μm² and less than or equal to 1 mm² is referred to as a mini light-emitting diode, and a light-emitting diode whose LED chip area is greater than 1 mm² is referred to as a macro light-emitting diode in some cases. Note that the area of an LED chip here can be, for example, the area of the upper surface or the bottom surface of a substrate 181 in FIG. 11A, FIG. 11C, and FIG. 11D described later. Alternatively, the area of an LED chip can be, for example, the area of the upper surface or the bottom surface of an electrode 183A in FIG. 11B described later.

For example, a light-emitting diode whose LED chip area is less than or equal to 100 m² can be referred to as a micro light-emitting diode (micro LED chip). As a light-emitting diode usable for an LED package with an area of 1 mm², a micro LED chip or a mini LED chip can be used in some cases, for example.

Any of a micro light-emitting diode, a mini light-emitting diode, and a macro light-emitting diode can be used for the LED package of the display apparatus of one embodiment of the present invention. In particular, the display apparatus of one embodiment of the present invention preferably includes a micro light-emitting diode or a mini light-emitting diode, and more preferably includes a micro light-emitting diode.

In particular, the area of a LED chip of the light-emitting diode is preferably less than or equal to 1 mm², further preferably less than or equal to 10000 μm², still further preferably less than or equal to 3000 μm², even further preferably less than or equal to 700 μm².

The area of a light-emitting region of the light-emitting diode is preferably less than or equal to 1 mm², further preferably less than or equal to 10000 μm², still further preferably less than or equal to 3000 μm², even further preferably less than or equal to 700 μm². Here, the area of the light-emitting region of the light-emitting diode is the area of the top surface or the bottom surface of a light-emitting layer 184 in FIG. 11A to FIG. 11D described later.

In this embodiment, in particular, an example where a micro light-emitting diode is used as a light-emitting diode is described. A micro light-emitting diode having a double heterojunction is described in this embodiment. Note that there is no particular limitation on the light-emitting diode, and for example, a micro light-emitting diode having a quantum well junction or a nanocolumn light-emitting diode may be used.

The transistor included in the display apparatus preferably contains a metal oxide in its channel formation region. The transistor using a metal oxide can have low power consumption. Thus, a combination with a micro LED can achieve a display apparatus with significantly reduced power consumption.

As described in Embodiment 1, the diagonal size of the display apparatus DSP can be determined by the size of the substrate used as the substrate BS (the substrate 310). In particular, when a substrate used as the substrate BS (the substrate 310) is a glass substrate, a metal substrate, or a base film that easily has a large area, the display apparatus DSP with a large diagonal size can be fabricated. In this specification and the like, a large-area substrate refers to a substrate of the second generation substrate size or larger, for example.

Note that in this embodiment, the substrate 310 is described as a substrate containing a material with high resistance to heat, such as a glass substrate.

In the case where the area of the substrate BS (the substrate 310) is increased, the transistor 300 and the transistor 200 are preferably formed by a process that enables the transistors to be formed over the substrate BS (the substrate 310) having a large area. Examples of the transistor that can be formed over a large-area substrate include a transistor containing low-temperature polysilicon in a channel formation region (hereinafter, referred to as an LTPS transistor) and an OS transistor.

The transistor 300 is provided over the substrate 310. The transistor 300 includes an insulator 311, an insulator 312, an insulator 313, an insulator 314, a conductor 316, a conductor 317, a low-resistance region 318p, a semiconductor region 318i, and a conductor 319. Here, a plurality of layers obtained by processing the same conductive film are shown with the same hatching pattern. In this specification and the like, the low-resistance region 318p and the semiconductor region 318i are collectively referred to as a semiconductor layer 318. In particular, when, for example, low-temperature polysilicon is used as a semiconductor material contained in the semiconductor layer 318, the transistor 300 can be an LTPS transistor. The LTPS transistor has high field-effect mobility and excellent frequency characteristics.

With the use of an LTPS transistor as the transistor 300, a circuit provided in the circuit layer SICL (e.g., the driver circuit GD and the driver circuit SD illustrated in FIG. 2B to FIG. 5) can be formed over the same substrate as the display portion. This allows simplification of an external circuit mounted on the display apparatus and a reduction in component cost and mounting cost.

In FIG. 9, the conductor 317 functions as a first gate (sometimes referred to as one of a gate and a back gate) of the transistor 300. The conductor 316 functions as a second gate (sometimes referred to as the other of the gate and the back gate) of the transistor 300. One of the pair of low-resistance regions 368p in the semiconductor layer 318 functions as one of a source and a drain of the transistor 300, and the other of the pair of low-resistance regions 368p in the semiconductor layer 318 functions as the other of the source and the drain of the transistor 300. The insulator 313 functions as a first gate insulating film in the transistor 300, and the insulator 312 functions a second gate insulating film in the transistor 300.

In FIG. 9, the insulator 311 is formed over the substrate 310. The conductor 316 is formed in a region over part of the insulator 311. The insulator 312 is formed to cover the insulator 311 and the conductor 316. The semiconductor layer 318 is formed in a region overlapping with the conductor 316 and the insulator 312 and being over part of the insulator 312. The insulator 313 is formed to cover the insulator 312 and the semiconductor layer 318. The conductor 317 is formed in a region overlapping with the conductor 316, the insulator 312, the semiconductor layer 318, and the insulator 313 and being over part of the insulator 313. The insulator 314 is covered so as to cover the insulator 313 and the conductor 317. An opening portion is formed in the insulator 313 and the insulator 314 in a region overlapping with the low-resistance region 318p, and the conductor 319 is formed over the insulator 314 to fill the opening portion.

For the insulator 311, the insulator 312, the insulator 313, and the insulator 314, one or more selected from silicon oxide, silicon oxynitride, silicon nitride oxide, silicon nitride, aluminum oxide, aluminum oxynitride, aluminum nitride oxide, or aluminum nitride may be used.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

In particular, a barrier insulating film that inhibits diffusion of impurities (e.g., a certain metal ion, a certain metal atom, an oxygen atom, an oxygen molecule, a hydrogen atom, a hydrogen molecule, and a water molecule) from a region below the insulator 311 (e.g., the substrate 310) is preferably used as the insulator 311.

Similarly, for the insulator 314, it is preferable to use a barrier insulating film that can prevent diffusion of impurities (e.g., a certain metal ion, a certain metal atom, an oxygen atom, an oxygen molecule, a hydrogen atom, a hydrogen molecule, and a water molecule) from a region above the insulator 314 (e.g., a region where the transistor 200, the LED package 170R, the LED package 170G, and the LED package 170B are provided).

Accordingly, for the insulator 311 and the insulator 314, it is preferable to use an insulating material that has a function of inhibiting diffusion of impurities such as a certain metal ion, a certain metal atom, an oxygen atom, an oxygen molecule, a hydrogen atom, a hydrogen molecule, and a water molecule (through which the above impurities are less likely to pass). Furthermore, depending on the situation, for the insulator 311 and the insulator 314, it is preferable to use an insulating material that has a function of inhibiting diffusion of impurities such as a nitrogen atom, a nitrogen molecule, a nitrogen oxide molecule (e.g., N₂O, NO, or NO₂), and a copper atom (through which the above oxygen is less likely to pass).

For the film having a barrier property against hydrogen, silicon nitride deposited by a CVD (Chemical Vapor Deposition) method can be used, for example.

The amount of released hydrogen can be analyzed by thermal desorption spectroscopy (TDS), for example. The amount of hydrogen released from the insulator 311 or the insulator 314 that is converted into hydrogen atoms per area of the insulator 311 or the insulator 314 is less than or equal to 10×10¹⁵ atoms/cm², preferably less than or equal to 5×10¹⁵ atoms/cm² in the TDS analysis in a film-surface temperature range of 50° C. to 500° C., for example.

The semiconductor layer 318 contains silicon, as described above. In particular, the silicon is preferably low-temperature polysilicon. That is, the transistor 300 is preferably an LTPS transistor.

Since a p-type semiconductor is difficult to form with use of a metal oxide in terms of mobility and reliability, a circuit formed with OS transistors becomes a single-polarity circuit with n-channel transistors in many cases. Meanwhile, since the LTPS transistor can be easily fabricated to be either an n-channel transistor or a p-channel transistor, a CMOS circuit can be formed using the LTPS transistors. As described in Embodiment 1, the circuit layer SICL includes a driver circuit; thus, the driver circuit is preferably configured with a CMOS circuit rather than the single-polarity circuit in terms of driving speed and power consumption.

The low-resistance region 318p is a region containing an impurity element. For example, in the case where the transistor 300 is an n-channel transistor, phosphorus or arsenic is added to the low-resistance region 318p. In contrast, in the case where the transistor 300 is a p-channel transistor, boron or aluminum is added to the low-resistance region 318p. In addition, in order to control the threshold voltage of the transistor 300, the above-described impurity may be added to the semiconductor region 318i.

Note that the transistor 300 may be either a p-channel transistor or an n-channel transistor. Alternatively, a plurality of the transistors 300 may be provided in the circuit layer SICL and both a p-channel transistor and an n-channel transistor may be used.

For the conductor 316 and the conductor 317, a metal such as aluminum, titanium, chromium, nickel, copper, yttrium, zirconium, molybdenum, silver, tantalum, or tungsten can be used, for example. Alternatively, an alloy containing any of the above metals as its main component can be used for the conductor 316 and the conductor 317 as a single-layer structure or a stacked-layer structure. Alternatively, for the conductor 316 and the conductor 317, a light-transmitting conductive material such as indium oxide, indium tin oxide (ITO), indium oxide containing tungsten, indium zinc oxide containing tungsten, indium oxide containing titanium, ITO containing titanium, indium zinc oxide, zinc oxide (ZnO), ZnO containing gallium, or indium tin oxide containing silicon can be used. Alternatively, a semiconductor such as an oxide semiconductor or polycrystalline silicon whose resistance is lowered by making an impurity element contained therein, for example, or a silicide such as nickel silicide may be used for the conductor 316 and the conductor 317. Alternatively, for the conductor 316 and the conductor 317, a film containing graphene can be used. The film containing graphene can be formed, for example, by reducing a film containing graphene oxide. In addition, for the conductor 316 and the conductor 317, a semiconductor such as an oxide semiconductor made to contain an impurity element may be used. Alternatively, the conductor 316 and the conductor 317 may be formed using a conductive paste of silver, carbon, copper, or the like or a conductive polymer such as polythiophene. A conductive paste is preferable because it is inexpensive. A conductive polymer is preferable because it is easily applied.

The conductor 319 serves as a wiring electrically connected to the low-resistance region 318p of the transistor 300. That is, the conductor 319 serves as a source or a drain of the transistor 300. Note that for the conductor 319, any of the materials usable for the conductor 316 and the conductor 317 can be used.

Note that the transistor 300 illustrated in FIG. 9 is an example and the structure is not limited thereto; an appropriate transistor may be used in accordance with a circuit structure, a driving method, or the like.

An insulator 320 and an insulator 322 are formed in this order over the insulator 314.

For each of the insulator 320 and the insulator 322, a material usable for any one of the insulator 311 to the insulator 314 can be used, for example.

A plurality of transistors 200 are formed over the insulator 322. The plurality of transistors 200 can be fabricated using the same material in the same step, for example.

An insulator 211, an insulator 213, an insulator 215, and an insulator 214 are provided in this order over the insulator 322. Part of the insulator 211 functions as a gate insulating layer of each transistor. Part of the insulator 213 functions as a gate insulating layer of each transistor. The insulator 215 is provided to cover the transistors. The insulator 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This allows the insulating layer to function as a barrier layer. Such a structure can effectively inhibit diffusion of impurities into the transistors from the outside and increase the reliability of a display apparatus.

An inorganic insulating film is preferably used as each of the insulator 211, the insulator 213, and the insulator 215. As the inorganic insulating film, a silicon nitride film, a silicon oxynitride film, a silicon oxide film, a silicon nitride oxide film, an aluminum oxide film, or an aluminum nitride film can be used. As the inorganic insulating film, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film may be used. The inorganic insulating film may have a stacked-layer structure including two or more of the above insulating films.

An organic insulating layer is suitable as the insulator 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulator 214 may have a stacked-layer structure of an organic insulating layer and an inorganic insulating layer. The outermost layer of the insulator 214 preferably has a function of an etching protective layer. Accordingly, a depressed portion can be prevented from being formed in the insulator 214 at the time of processing a conductor 111a to a conductor 111c and a conductor 112a to a conductor 112c described later. Alternatively, a depressed portion may be inhibited in the insulator 214 at the time of processing the conductor 111a to the conductor 111c and the conductor 112a to the conductor 112c.

Each of the plurality of transistors 200 includes a conductor 221 functioning as a gate, the insulator 211 functioning as a gate insulating layer, a conductor 222a and a conductor 222b functioning as a source and a drain, a semiconductor layer 231, the insulator 213 functioning as a gate insulating layer, and a conductor 223 functioning as a gate. Here, as in the transistor 300, a plurality of layers obtained by processing the same conductive film are shown with the same hatching pattern. The insulator 211 is positioned between the conductor 221 and the semiconductor layer 231. The insulator 213 is positioned between the conductor 223 and the semiconductor layer 231.

For the conductor 221, the conductor 222a, the conductor 222b, and the conductor 223, any of the materials usable for the conductor 316 can be used, for example.

There is no particular limitation on the structure of the transistors included in the display apparatus of this embodiment. For example, a planar transistor, a staggered transistor, an inverted staggered transistor, or the like can be used. A top-gate or a bottom-gate transistor structure may be employed. Alternatively, gates may be provided above and below the semiconductor layer where a channel is formed.

The structure in which the semiconductor layer where a channel is formed is provided between two gates is used for the plurality of transistors 200. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used because degradation of the transistor characteristics can be inhibited.

The semiconductor layer of the transistor preferably includes a metal oxide (also referred to as an oxide semiconductor). That is, a transistor using a metal oxide in its channel formation region (hereinafter an OS transistor) is preferably used for the display apparatus of this embodiment.

As the oxide semiconductor having crystallinity, a CAAC (c-axis aligned crystalline)-OS, an nc (nanocrystalline)-OS, and the like are given.

An OS transistor has much higher field-effect mobility than a transistor using amorphous silicon. In addition, an OS transistor has an extremely low leakage current between a source and a drain in an off state (also referred to as off-state current), and charge accumulated in a capacitor that is connected in series to the transistor can be retained for a long period. Furthermore, the power consumption of the display apparatus can be reduced with the OS transistor.

The off-state current value per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current value per micrometer of channel width of a Si transistor at room temperature is higher than or equal to 1 fA (1×10⁻¹⁵ A) and lower than or equal to 1 pA (1×10⁻¹² A). Thus, the off-state current of an OS transistor is lower than that of a Si transistor by approximately ten orders of magnitude.

In the case where the luminance of a light-emitting diode included in the pixel circuit (the light-emitting diode included in the LED package 170) is increased, the amount of current fed through the light-emitting diode needs to be increased. For that purpose, the source-drain voltage of the driving transistor included in the pixel circuit needs to be increased. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting diode can be increased, so that the emission luminance of the light-emitting diode can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, current flowing between the source and the drain can be set minutely by a change in gate-source voltage; hence, the amount of current flowing through the light-emitting diode can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made flow through an OS transistor than through a Si transistor. Thus, by using an OS transistor as the driving transistor, a stable current can be fed through light-emitting diodes even when the current-voltage characteristics of the light-emitting diodes vary, for example. In other words, when the OS transistor operates in the saturation region, the source-drain current hardly changes with an increase in the source-drain voltage; hence, the emission luminance of the light-emitting diode can be stable.

As described above, by using an OS transistor as the driving transistor included in the pixel circuit, it is possible to “reduce black-level degradation”, “increase the emission luminance”, “increase the number of gray levels”, and “suppress variations in light-emitting devices”, for example.

A semiconductor layer provided in the OS transistor preferably contains at least indium or zinc, and further preferably contains indium and zinc, for example. The semiconductor layer preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO).

In the case where the semiconductor layer is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=1:3:2 or a composition in the neighborhood thereof, In:M:Zn=1:3:4 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

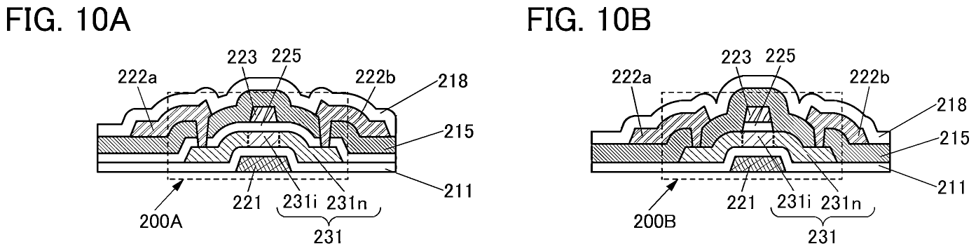

The structure of the OS transistor is not limited to the structure illustrated in FIG. 9. For example, the structures illustrated in FIG. 10A and FIG. 10B may be employed.

A transistor 200A and a transistor 200B each include the conductor 221 functioning as a gate, the insulator 211 functioning as a gate insulating layer, the semiconductor layer 231 including a channel formation region 231i and a pair of low-resistance regions 231n, the conductor 222a connected to one of the pair of low-resistance regions 231n, the conductor 222b connected to the other of the pair of low-resistance regions 231n, an insulator 225 functioning as a gate insulating layer, the conductor 223 functioning as a gate, and the insulator 215 covering the conductor 223. The insulator 211 is positioned between the conductor 221 and the channel formation region 231i. The insulator 225 is positioned at least between the conductor 223 and the channel formation region 231i. Furthermore, an insulator 218 covering the transistor may be provided.

FIG. 10A illustrates an example of the transistor 200A in which the insulator 225 covers the top surface and the side surface of the semiconductor layer 231. The conductor 222a and the conductor 222b are connected to the low-resistance regions 231n through openings provided in the insulator 225 and the insulator 215. One of the conductor 222a and the conductor 222b functions as a source, and the other functions as a drain.

Meanwhile, in the transistor 200B illustrated in FIG. 10B, the insulator 225 overlaps with the channel formation region 231i of the semiconductor layer 231 and does not overlap with the low-resistance regions 231n. The structure illustrated in FIG. 10B can be formed by processing the insulator 225 with the conductor 223 as a mask, for example. In FIG. 10B, the insulator 215 is provided to cover the insulator 225 and the conductor 223, and the conductor 222a and the conductor 222b are connected to the low-resistance regions 231n through the openings in the insulator 215.

As illustrated in FIG. 9, opening portions are provided in regions where the insulator 214 is overlapping with parts of a plurality of conductors 222b. In each of the opening portions, the conductor 111a, the conductor 111b, the conductor 111c, the conductor 112a, the conductor 112b, or the conductor 112c is provided over part of the insulator 214, on a side surface of the opening portions, and over the conductor 222b that corresponds to a bottom surface of the opening portion.

The conductor 111a, the conductor 111b, and the conductor 111c function as a common electrode of the LED chip 180R, the LED chip 180G, and the LED chip 180B (light-emitting diodes) included in the LED package 170R, the LED package 170G, and the LED package 170B, respectively. The conductor 112a, the conductor 112b, and the conductor 112c functions as pixel electrodes of the LED chip 180R, the LED chip 180G, and the LED chip 180B (light-emitting diodes) included in the LED package 170R, the LED package 170G, and the LED package 170B, respectively.

For the conductor 111a to the conductor 111c and the conductor 112a to the conductor 112c, aluminum, titanium, chromium, nickel, copper, yttrium, zirconium, molybdenum, silver, tantalum, or tungsten can be used, for example. For the conductor 111a to the conductor 111c and the conductor 112a to the conductor 112c, an alloy containing any metal selected from the above-described materials as its main component can be used, for example. In addition, the conductor 111a to the conductor 111c and the conductor 112a to the conductor 112c may each have a single-layer structure containing any of the above-described materials or alloys, or a stacked-layer structure in which two or more single-layers are stacked, for example. Specifically, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, a three-layer structure in which an aluminum film or a copper film is stacked over a molybdenum film or a molybdenum nitride film and a molybdenum film or a molybdenum nitride film is formed thereover, and the like can be given. Note that an oxide such as indium oxide, tin oxide, or zinc oxide may be used. Copper containing manganese is preferably used because it increases controllability of a shape by etching.

A protective layer 116 is provided over the insulator 214, the conductor 111a to the conductor 111c, and the conductor 112a to the conductor 112c. The protective layer 116 is formed to fill an opening portion of the insulator 214 whose bottom surface is regarded as the conductor 222b. In particular, the protective layer 116 is preferably provided to cover end portions of the conductor 111a to the conductor 111c and the conductor 112a to the conductor 112c.

A resin such as an acrylic resin, a polyimide resin, an epoxy resin, or a silicone resin is suitably used for the protective layer 116. Providing the protective layer 116 can inhibit a conductor 117 and a conductor 118 to be described later from being in contact with each other, that is, from being short-circuited. Note that depending on circumstances, the protective layer 116 is not necessarily provided over the insulator 214, the conductor 111a to the conductor 111c, and the conductor 112a to the conductor 112c.

Opening portions are formed in the protective layer 116 in regions partly overlapping with the conductor 111a to the conductor 111c and regions partly overlapping with the conductor 112a to the conductor 112c. The conductor 117 and the conductor 118 are provided over the protective layer 116. Specifically, the conductor 117 is provided to fill the opening portions of the protective layer 116 in the regions partly overlapping with the conductor 112a to the conductor 112c, and the conductor 118 is provided to fill the opening portions of the protective layer 116 in the regions partly overlapping with the conductor 111a to the conductor 111c.

For example, a conductive paste including a material such as silver, carbon, or copper or a bump including a material such as gold or solder can be suitably used for the conductor 117 and the conductor 118. For each of the conductor 112a to the conductor 112c (the conductor 111a to the conductor 111c) and an electrode 172 (an electrode 173) to be described later, which are electrically connected to the conductor 117 (the conductor 118), a conductive material having low contact resistance with the conductor 117 (the conductor 118) is preferably used. For example, in the case where a silver paste is used for the conductor 117 (the conductor 118), aluminum, titanium, copper, or an alloy containing silver, palladium and copper (Ag—Pd—Cu (APC)) is used as the conductive material usable for the conductor 112a to the conductor 112c (the conductor 111a to the conductor 111c) and the electrode 172 (the electrode 173) to be described later, whereby the contact resistance with the conductor 117 (the conductor 118) can be low.

The LED package 170R, the LED package 170G, and the LED package 170B are provided over the conductor 117 and the conductor 118. Note that FIG. 11A illustrates specific structure examples of the LED package 170R, the LED package 170G, and the LED package 170B included in the display apparatus 1000 in FIG. 9.

The LED package 170 in FIG. 11A includes a substrate 171, the electrode 172, the electrode 173, a heat sink 174, an adhesive layer 175, a case 176, a wire 177, a wire 179, a sealing layer 178, a ball 189, and an LED chip 180.

The LED chip 180 includes the substrate 181, a semiconductor layer 182, an electrode 183, the light-emitting layer 184, a semiconductor layer 185, an electrode 186, and an electrode 187. Note that in this specification and the like, the term “LED chip” can be replaced with the term “light-emitting diode” in the description in some cases.

As the substrate 171, a glass epoxy resin substrate, a polyimide substrate, a ceramic substrate, an alumina substrate, or an aluminum nitride substrate can be used, for example.

The electrode 172 and the electrode 173 are formed on the top surface, side surfaces, and the bottom surface of the substrate 171. Specifically, the electrode 172 formed on the top surface, the side surface, and the bottom surface of the substrate 171 serves as one wiring. Similarly, the electrode 173 formed on the top surface, the side surface, and the bottom surface of the substrate 171 serves as another wiring. Note that electrical continuity is not established between the electrode 172 and the electrode 173.

The substrate 171 is provided with the heat sink 174. The heat sink 174 has a function of releasing heat generated in the LED chip 180, for example.

Note that the electrode 172, the electrode 173, and the heat sink 174 can be formed with the same material. For example, for each of the electrode 172, the electrode 173, and the heat sink 174, one element selected from nickel, copper, silver, platinum, and gold, or an alloy material containing any of the elements at 50% or higher can be used.

The electrode 172, the electrode 173, and the heat sink 174 can be formed in the same step.

The LED chip 180 is attached above the substrate 171 with the adhesive layer 175. Specifically, the substrate 181 of the LED chip 180 is provided to overlap with the heat sink 174 on the substrate 171, with the adhesive layer 175 therebetween. There is no particular limitation on a material of the adhesive layer 175. For example, the use of an adhesive with conductivity as a material of the adhesive layer 175 can increase the heat dissipation property of the LED chip 180.

The substrate 181 can be a single crystal substrate such as a sapphire substrate, a silicon carbide substrate, a silicon substrate, or a gallium nitride substrate, for example.

In the LED chip 180, the semiconductor layer 182 is formed over the substrate 181. The electrode 183 is formed over part of the semiconductor layer 182, and the light-emitting layer 184 is formed over other part of the semiconductor layer 182. The semiconductor layer 185 is formed over the light-emitting layer 184, the electrode 186 is formed over the semiconductor layer 185, and the electrode 187 is formed over part of the electrode 186.

In the LED chip 180, the light-emitting layer 184 is sandwiched between the semiconductor layer 182 and the semiconductor layer 185. In the light-emitting layer 184, electrons and holes are combined to emit light. One of the semiconductor layer 182 and the semiconductor layer 185 is an n-type semiconductor layer, and the other of the semiconductor layer 182 and the semiconductor layer 185 is a p-type semiconductor layer.

In the display apparatus 1000 in FIG. 9, a light-emitting diode included in the LED chip 180 of each of the LED package 170R, the LED package 170G, and the LED package 170B has a stacked-layer structure of a pair of semiconductor layers and a light-emitting layer between the pair of semiconductor layers, and emits red light, green light, or blue light. Thus, the colors of light emitted from the light-emitting diodes of the LED chips 180 can be freely determined separately in the LED package 170R, the LED package 170G, and the LED package 170B. For example, a compound of gallium and phosphorus, a compound of gallium and arsenic, a compound of gallium, aluminum, and arsenic, a compound of aluminum, gallium, indium, and phosphorus, gallium nitride, a compound of indium and gallium nitride, or a compound of selenium and zinc can be used for the stacked-layer structure.

The colors of light emitted from the light-emitting diodes included in the LED chips 180 of the LED packages 170 can be cyan, magenta, yellow, or white in addition to red, green, and blue.

The electrode 183 is electrically connected to the electrode 172 through the wire 177. That is, the electrode 183 serves as a pixel electrode of the light-emitting diode. The electrode 187 is electrically connected to the electrode 173 through the wire 179. That is, the electrode 187 serves as a common electrode of the light-emitting diode.

A wire bonding method can be used as a method of bonding the electrode 183 and the wire 177, a method of bonding the electrode 172 and the wire 177, a method of bonding the electrode 187 and the wire 179, and a method of bonding the electrode 173 and the wire 179, for example. A thermocompression bonding method and an ultrasonic bonding method are kinds of the wire bonding method. In a step of bonding the wire 177 and the wire 179 by the wire bonding method, the ball 189 made of the same material as the wire 179 is formed over the electrode 172, the electrode 173, the electrode 183, and the electrode 187.

For example, a material usable for the conductor 111a to the conductor 111c and the conductor 112a to the conductor 112c is preferably used for each of the electrode 183, the electrode 186, and the electrode 187. In particular, the light-emitting layer 184 of the LED chip 180 emits light to the upper side of the LED package 170; therefore, a light-transmitting conductive material is preferably used for the electrode 186. The light-transmitting conductive material is preferably a light-transmitting conductive material which can be used for the conductor 11a to the conductor 111c and the conductor 112a to the conductor 112c, for example. For the same reason, the electrode 187 preferably uses a light-transmitting conductive material.

As the wire 177 and the wire 179, a thin metal wire of gold, an alloy containing gold, copper, or an alloy containing copper can be used, for example.

A resin can be used as the material of the case 176. The case 176 does not necessarily cover the top surface of the LED chip 180 as long as the case 176 covers the side surface of the sealing layer 178. That is, for example, the sealing layer 178 may be exposed from the top surface of the LED chip 180. The inner side surface of the case 176, specifically, the periphery of the LED chip 180 (peripheries of the substrate 181, the semiconductor layer 182, the electrode 183, the light-emitting layer 184, the semiconductor layer 185, the electrode 186, and the electrode 187) is preferably provided with a reflector made of ceramics or the like. Part of light emitted by the light-emitting layer 184 of the LED chip 180 is reflected by the reflector, so that a larger amount of light can be extracted from the LED package 170.

The inside of the case 176 is filled with the sealing layer 178. For the sealing layer 178, a resin having a property of transmitting visible light is preferably used. Specifically, for the sealing layer 178, for example, an ultraviolet curable resin such as an epoxy resin or a silicone resin or a visible light curable resin can be used.

Next, a structure example of an LED package which can be used as the LED package 170R, the LED package 170G, and the LED package 170B of the display apparatus 1000 and is different from the LED package 170 in FIG. 11A is described.

An LED package 170A1 illustrated in FIG. 11B is different from the LED package 170 in FIG. 11A in that an LED chip 180A is provided over the substrate 171. Note that a pixel electrode of the LED chip 180A is bonded to the electrode 172 not with the wire 177 but with the adhesive layer 175.

The LED package 170A1 in FIG. 11B includes the substrate 171, the electrode 172, the electrode 173, the adhesive layer 175, the case 176, the wire 177, the wire 179, the sealing layer 178, the ball 189, and the LED chip 180A.

In the LED package 170A1 in FIG. 11B, the LED chip 180A includes the electrode 183A and a light-emitting diode provided over the electrode 183A. The light-emitting diode includes the semiconductor layer 182, the light-emitting layer 184, the semiconductor layer 185, the electrode 186, and the electrode 187.

As the electrode 183A, a conductive substrate can be used, for example. As a kind of the conductive substrate, a metal substrate is given, for example.

The semiconductor layer 182, the light-emitting layer 184, the semiconductor layer 185, the electrode 186, and the electrode 187 are formed in this order over the electrode 183A.

For the semiconductor layer 182, the light-emitting layer 184, the semiconductor layer 185, the electrode 186, and the electrode 187, description of the LED package 170 in FIG. 11A is referred to.

In the LED package 170A1 in FIG. 11B, the electrode 172 and the electrode 173 are formed on the top surface, the side surfaces, and the bottom surface of the substrate 171. In particular, the electrode 172 is also provided in a region of the substrate 171 where the LED chip 180A is provided. The electrode 172 formed on the top surface, the side surface, and the bottom surface of the substrate 171 serves as one wiring. Similarly, the electrode 173 formed on the top surface, the side surface, and the bottom surface of the substrate 171 serves as another wiring. Note that electrical continuity is not established between the electrode 172 and the electrode 173.

The LED chip 180A is attached above the substrate 171 with the adhesive layer 175. Specifically, the electrode 183A of the LED chip 180A is provided to overlap with a region of the electrode 172 provided on the substrate 171, with the adhesive layer 175 positioned therebetween. Note that the adhesive layer 175 is an adhesive having conductivity.

As described above, in the case where the LED chip 180A in which the light-emitting diode is formed over the conductive substrate is employed, the pixel electrode of the LED chip 180A and the electrode 172 of the substrate 171 are attached not with the wire 177 but with the adhesive layer 175, whereby an LED package 170A2 can be formed.

Next, a structure example of an LED package which can be used as the LED package 170R, the LED package 170G, and the LED package 170B of the display apparatus 1000 and is different from the LED package 170 in FIG. 11A and the LED package 170A1 in FIG. 11B is described.

The LED package 170A2 illustrated in FIG. 11C is different from the LED package in FIG. 11A in that a color conversion layer 190 is provided inside the case 176.

Note that although a structure in which the color conversion layer 190 is provided above the sealing layer 178 is illustrated in FIG. 11C, the position of the color conversion layer 190 is not limited thereto. For example, the color conversion layer 190 may be separated inside the sealing layer 178.

As the color conversion layer 190, a phosphor or a quantum dot (QD) is preferably used. In particular, a quantum dot has an emission spectrum with a narrow peak, so that emission with high color purity can be obtained. The use of a quantum dot for the color conversion layer 190 can improve the display quality of the display apparatus 1000.

The color conversion layer 190 has a function of converting light emitted by the light-emitting layer 184 included in the LED chip 180 of the LED package 170A2 into light of another color.

For example, as the color conversion layer 190, a color conversion layer converting blue light into green light or a color conversion layer converting blue light into red light can be used. For example, in the case where a blue light-emitting diode is provided in a red subpixel, blue light emitted by the blue light-emitting diode passes through the color conversion layer 190, thereby being converted into red light and emitted to the upside of the case 176, that is, the outside of the display apparatus 1000. For example, in the case where a blue light-emitting diode is provided in a green subpixel, blue light emitted by the blue light-emitting diode passes through the color conversion layer 190, thereby being converted into green light and emitted to the upside of the case 176, that is, the outside of the display apparatus 1000.

The color conversion layer 190 can be formed by a droplet discharge method (e.g., an ink-jet method), a coating method, an imprinting method, or a variety of printing methods (screen printing or offset printing). Alternatively, for the color conversion layer 190, a color conversion film such as a quantum dot film can be used.

As the phosphor, an organic resin layer having a surface on which a phosphor is printed or which is coated with a phosphor or an organic resin layer mixed with a phosphor can be used.

There is no limitation on a material of quantum dots, and examples include a Group 14 element, a Group 15 element, a Group 16 element, a compound of a plurality of Group 14 elements, a compound of an element belonging to any of Group 4 to Group 14 and a Group 16 element, a compound of a Group 2 element and a Group 16 element, a compound of a Group 13 element and a Group 15 element, a compound of a Group 13 element and a Group 17 element, a compound of a Group 14 element and a Group 15 element, a compound of a Group 11 element and a Group 17 element, iron oxides, titanium oxides, spinel chalcogenides, and semiconductor clusters.

Specific examples include cadmium selenide; cadmium sulfide; cadmium telluride; zinc selenide; zinc oxide; zinc sulfide; zinc telluride; mercury sulfide; mercury selenide; mercury telluride; indium arsenide; indium phosphide; gallium arsenide; gallium phosphide; indium nitride; gallium nitride; indium antimonide; gallium antimonide; aluminum phosphide; aluminum arsenide; aluminum antimonide; lead selenide; lead telluride; lead sulfide; indium selenide; indium telluride; indium sulfide; gallium selenide; arsenic sulfide; arsenic selenide; arsenic telluride; antimony sulfide; antimony selenide; antimony telluride; bismuth sulfide; bismuth selenide; bismuth telluride; silicon; silicon carbide; germanium; tin; selenium; tellurium; boron; carbon; phosphorus; boron nitride; boron phosphide; boron arsenide; aluminum nitride; aluminum sulfide; barium sulfide; barium selenide; barium telluride; calcium sulfide; calcium selenide; calcium telluride; beryllium sulfide; beryllium selenide; beryllium telluride; magnesium sulfide; magnesium selenide; germanium sulfide; germanium selenide; germanium telluride; tin sulfide; tin selenide; tin telluride; lead oxide; copper fluoride; copper chloride; copper bromide; copper iodide; copper oxide; copper selenide; nickel oxide; cobalt oxide; cobalt sulfide; iron oxide; iron sulfide; manganese oxide; molybdenum sulfide; vanadium oxide; tungsten oxide; tantalum oxide; titanium oxide; zirconium oxide; silicon nitride; germanium nitride; aluminum oxide; barium titanate; a compound of selenium, zinc, and cadmium; a compound of indium, arsenic, and phosphorus; a compound of cadmium, selenium, and sulfur; a compound of cadmium, selenium, and tellurium; a compound of indium, gallium, and arsenic; a compound of indium, gallium, and selenium; a compound of indium, selenium, and sulfur; a compound of copper, indium, and sulfur; and a combinations thereof. What is called an alloyed quantum dot, whose composition is represented by a given ratio, may be used.

Examples of the quantum dot include a core-type quantum dot, a core-shell quantum dot, and a core-multishell quantum dot. Quantum dots have a high proportion of surface atoms and thus have high reactivity and easily cohere together. For this reason, it is preferable that a protective agent be attached to, or a protective group be provided at the surfaces of quantum dots. The attachment of the protective agent or the provision of the protective group can prevent cohesion and increase solubility in a solvent. It can also reduce reactivity and improve electrical stability.

Since band gaps of quantum dots are increased as their size (diameter) is decreased, the size is adjusted as appropriate so that light with a desired wavelength can be obtained. Light emission from the quantum dots is shifted to a blue color side, i.e., a high energy side, as the crystal size is decreased; thus, emission wavelengths of the quantum dots can be adjusted over a wavelength range in the spectrum of an ultraviolet region, a visible light region, and an infrared region by changing the size of quantum dots. The size (diameter) of quantum dots is, for example, greater than or equal to 0.5 nm and less than or equal to 20 nm, preferably greater than or equal to 1 nm and less than or equal to 10 nm. The emission spectra are narrowed as the size distribution of quantum dots gets smaller, and thus light can be obtained with high color purity. The shape of quantum dots is not particularly limited and may be a spherical shape, a rod shape, a circular shape, or other shapes. A quantum rod, which is a rod-shaped quantum dot, has a function of emitting directional light.

Alternatively, a stacked-layer structure of the color conversion layer 190 and a coloring layer may be provided inside or above the LED package 170A2. Thus, light that has been converted by the color conversion layer 190 passes through the coloring layer, whereby the purity of light can be increased. A coloring layer of the same color as light emitted by the light-emitting layer 184 may be provided in a position overlapping with the LED chip 180 (the substrate 181, the semiconductor layer 182, the electrode 183, the light-emitting layer 184, the semiconductor layer 185, the electrode 186, and the electrode 187). Providing a coloring layer of the same color can increase the purity of light emitted by the light-emitting layer 184. Furthermore, in the case where a coloring layer is not provided in the LED package 170A2, the manufacturing process can be simplified.

The coloring layer is a colored layer that transmits light in a specific wavelength range. For example, a color filter for transmitting light in a red, green, blue, or yellow wavelength range can be used. Examples of a material that can be used for the coloring layer include a metal material, a resin material, and a resin material containing a pigment or dye.

As described above, the color conversion layer provided above the LED chip 180 enables the LED package 170A2 to emit light with a high color purity.

Next, a structure example of an LED package which can be used as the LED package 170R, the LED package 170G, and the LED package 170B of the display apparatus 1000 and is different from the LED package 170 in FIG. 11A, the LED package 170A1 in FIG. 11B, and the LED package 170A2 in FIG. 11C is described.

An LED package 170A3 illustrated in FIG. 11D is different from the LED package 170 in FIG. 11A in that the substrate 181 of the LED chip 180 provided over the substrate 171 is positioned in an upper portion, and the electrode 183 and the electrode 187 are positioned in an upper portion.

With this structure, light emitted by the light-emitting layer 184 is emitted to the upside of the LED package 170A3; thus, the substrate 181 preferably has a light-transmitting property.

In the LED package 170A3 in FIG. 11D, since the electrode 183 and the electrode 187 in the LED chip 180 face the substrate 171 side, bonding between the electrode 183 and the electrode 172 and bonding between the electrode 187 and the electrode 173 are performed not with a wire but with a conductor serving as a bump. Specifically, the electrode 183 and the electrode 172 are bonded by a conductor 191, and the electrode 187 and the electrode 173 are bonded by a conductor 192.

For each of the conductor 191 and the conductor 192, a material usable for the conductor 117 or the conductor 118 can be used.

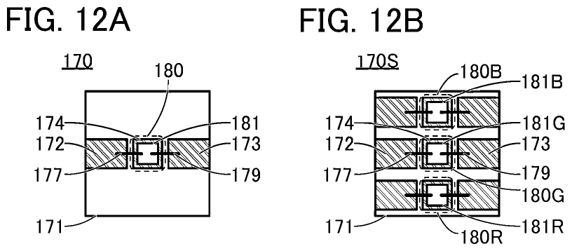

Next, the number of LED chips 180 that can be provided in the LED package 170 is described. FIG. 12A is an example of a plan view of the LED package 170 in FIG. 11A. FIG. 12A illustrates the substrate 181 which is a component of the LED chip 180. Although the LED package 170 including one LED chip 180 over the substrate 171 is described above as an example as illustrated in FIG. 12A, one embodiment of the present invention is not limited to this structure. For example, the LED package 170 may include not one LED chip but a plurality of LED chips over the substrate 171.

FIG. 12B illustrates a structure of an LED package 170S in which three LED chips, the LED chip 180R, the LED chip 180G, and the LED chip 180B, are provided over the substrate 171. FIG. 12B illustrates a substrate 181R which is a component of the LED chip 180R, a substrate 181G which is a component of the LED chip 180G, and a substrate 181B which is a component of the LED chip 180B. Light-emitting layers of light-emitting diodes included in the LED chip 180R, the LED chip 180G, and the LED chip 180B provided in the LED package 170S may emit light of different colors. For example, the substrate 181R is provided with a light-emitting diode emitting red light, the substrate 181G is provided with a light-emitting diode emitting green light, and the substrate 181B is provided with a light-emitting diode emitting blue light, whereby the LED package 170S can emit light of three colors, red, green, and blue.

The light-emitting diodes (the LED chip 180R, the LED chip 180G, and the LED chip 180B) in the LED package 170, the LED package 170A1, the LED package 170A2, the LED package 170A3, and the LED package 170S, which are described above, may be driven by transistors with the same structure, or may be driven by transistors with different structures. For example, in the display apparatus 1000 in FIG. 9, a transistor that drives the LED chip 180R included in the LED package 170R, a transistor that drives the LED chip 180G included in the LED package 170G, and a transistor that drives the LED chip 180B included in the LED package 170B may differ from each other in at least one of the transistor size, the channel length, the channel width, and the structure. Specifically, depending on the amount of current required for light emission with desired luminance, one or both of the channel length and the channel width of the transistor may be changed for each color.

In the display apparatus 1000 in FIG. 9, the top surface of the protective layer 116, the top surface and side surface of the conductor 117, the top surface and side surface of the conductor 118, and the side surfaces of the LED package 170R, the LED package 170G, and the LED package 170B may be covered with a resin layer 148. Use of a black resin for the resin layer 148 can enhance the display contrast of the display apparatus 1000. One or more selected from the top surface of the resin layer 148 and the top surfaces of the LED package 170R, the LED package 170G, and the LED package 170B may be provided with a surface protective layer, an impact absorption layer, or both. Since each of the LED package 170R, the LED package 170G, and the LED package 170B has a structure in which light is emitted upward, a layer provided on each of the top surfaces of the LED package 170R, the LED package 170G, and the LED package 170B preferably has a visible-light-transmitting property.

All the conductor 112a to the conductor 112c, the conductor 117, and the electrode 172 in the LED package 170R, the LED package 170G, and the LED package 170B are referred to as pixel electrodes in some cases. Furthermore, parts of the conductor 112a to the conductor 112c, the conductor 117, and the electrode 172 are referred to as pixel electrodes in some cases.

Note that the display apparatus of one embodiment of the present invention is not limited to the structure of the display apparatus 1000 illustrated in FIG. 9. The display apparatus of one embodiment of the present invention may have the structure of the display apparatus 1000 in FIG. 9 with a modification made within the scope of achieving an object of the present invention.

For example, the display apparatus of one embodiment of the present invention may have not a structure in which a plurality of LED packages 170 are mounted above the substrate 310 but a structure in which a substrate provided with a plurality of light-emitting diodes are attached above the substrate 310.

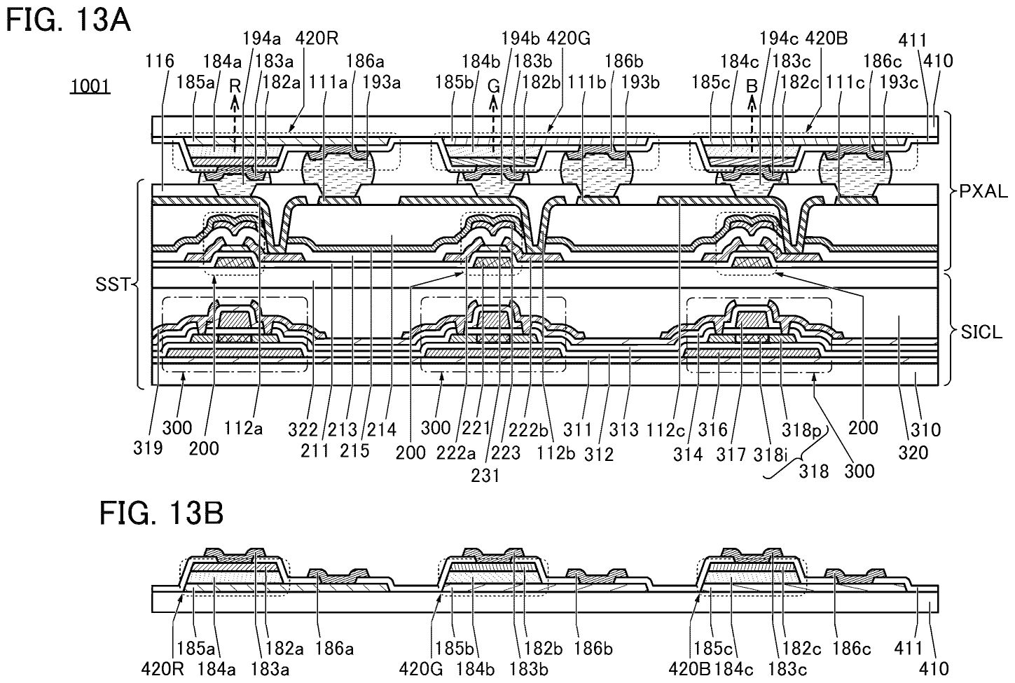

FIG. 13A illustrates a display apparatus 1001 formed by attaching a substrate 410 where a plurality of light-emitting diodes are formed to the structure in which the components up to the protective layer 116 of the display apparatus 1000 in FIG. 9 have been formed (hereinafter this structure is referred to as a stack SST). FIG. 13B illustrates a plurality of light-emitting diodes and the substrate 410 provided with the plurality of light-emitting diodes.

A light-emitting diode 420R, a light-emitting diode 420G, and a light-emitting diode 420B are illustrated as the plurality of light-emitting diodes in FIG. 13A and FIG. 13B. The light-emitting diode 420R, the light-emitting diode 420G, and the light-emitting diode 420B are collectively referred to as a light-emitting diode 420 in some cases.

The light-emitting diode 420R includes an electrode 183a, a semiconductor layer 182a, a light-emitting layer 184a, a semiconductor layer 185a, and an electrode 186a, for example. The light-emitting diode 420G includes an electrode 183b, a semiconductor layer 182b, a light-emitting layer 184b, a semiconductor layer 185b, and an electrode 186b, for example. The light-emitting diode 420B includes an electrode 183c, a semiconductor layer 182c, a light-emitting layer 184c, a semiconductor layer 185c, and an electrode 186c, for example.

The semiconductor layer 185a to the semiconductor layer 185c are formed over the substrate 410 in FIG. 13B. The light-emitting layer 184a to the light-emitting layer 184c are formed over some regions of the semiconductor layer 185a to the semiconductor layer 185c, respectively. The semiconductor layer 182a is formed over the light-emitting layer 184a, the semiconductor layer 182b is formed over the light-emitting layer 184b, and the semiconductor layer 182c is formed over the light-emitting layer 184c. A protective layer 411 is formed to cover the top surface of the substrate 410, the top surfaces and side surfaces of the semiconductor layer 185a to the semiconductor layer 185c, the side surfaces of the light-emitting layer 184a to the light-emitting layer 184c, and the top surfaces and side surfaces of the semiconductor layer 182a to the semiconductor layer 182c.

Note that an opening portion is formed in the protective layer 411 in a region overlapping with part of the semiconductor layer 182a, and the electrode 183a is formed to cover part of the protective layer 411 and the top surface of the semiconductor layer 182a which corresponds to the bottom surface of the opening portion. Similarly, an opening portion is formed in the protective layer 411 in a region overlapping with part of the semiconductor layer 182b, and the electrode 183b is formed to cover part of the protective layer 411 and the top surface of the semiconductor layer 182b which corresponds to the bottom surface of the opening portion. Similarly, an opening portion is formed in the protective layer 411 in a region overlapping with part of the semiconductor layer 182c, and the electrode 183c is formed to cover part of the protective layer 411 and the top surface of the semiconductor layer 182c which corresponds to the bottom surface of the opening portion.

An opening portion is formed in the protective layer 411 in a region overlapping with part of the semiconductor layer 185a and not overlapping with the semiconductor layer 182a or the light-emitting layer 184a, and the electrode 186a is formed to cover part of the protective layer 411 and the semiconductor layer 185a which corresponds to the bottom surface of the opening portion. Similarly, an opening portion is formed in the protective layer 411 in a region overlapping with part of the semiconductor layer 185b and not overlapping with the semiconductor layer 182b or the light-emitting layer 184b, and the electrode 186b is formed to cover part of the protective layer 411 and the semiconductor layer 185b which corresponds to the bottom surface of the opening portion. Similarly, an opening portion is formed in the protective layer 411 in a region overlapping with part of the semiconductor layer 185c and not overlapping with the semiconductor layer 182c or the light-emitting layer 184c, and the electrode 186c is formed to cover part of the protective layer 411 and the semiconductor layer 185c which corresponds to the bottom surface of the opening portion.

The display apparatus 1001 has a top-emission structure. Light from the light-emitting diode 420R, the light-emitting diode 420G, and the light-emitting diode 420B are emitted to the substrate 410 side. For this reason, a material having a high visible-light-transmitting property is preferably used for the substrate 410. For example, a substrate having a high visible-light-transmitting property may be selected as the substrate 410 among substrates usable as the substrate BS.

As illustrated in FIG. 13A and FIG. 13B, the light-emitting layer 184a is sandwiched between the semiconductor layer 182a and the semiconductor layer 185a. In the light-emitting layer 184a, electrons and holes are combined to emit light. One of the semiconductor layer 182a and the semiconductor layer 185a is an n-type semiconductor layer, and the other of the semiconductor layer 182a and the semiconductor layer 185a is a p-type semiconductor layer. Similarly, the light-emitting layer 184b is sandwiched between the semiconductor layer 182b and the semiconductor layer 185b. In the light-emitting layer 184b, electrons and holes are combined to emit light. One of the semiconductor layer 182b and the semiconductor layer 185b is an n-type semiconductor layer, and the other of the semiconductor layer 182b and the semiconductor layer 185b is a p-type semiconductor layer. Similarly, the light-emitting layer 184c is sandwiched between the semiconductor layer 182c and the semiconductor layer 185c. In the light-emitting layer 184c, electrons and holes are combined to emit light. One of the semiconductor layer 182c and the semiconductor layer 185c is an n-type semiconductor layer, and the other of the semiconductor layer 182c and the semiconductor layer 185c is a p-type semiconductor layer.

Each of the light-emitting diode 420R, the light-emitting diode 420G, and the light-emitting diode 420B provided in the display apparatus 1001 in FIG. 13A has a stacked-layer structure including a pair of semiconductor layers and a light-emitting layer sandwiched between the pair of semiconductor layers, and the stacked-layer structure is formed to emit red light, green light, or blue light. Thus, colors of light emitted can be freely determined separately in the light-emitting diode 420R, the light-emitting diode 420G, and the light-emitting diode 420B. For example, the light-emitting diode 420R can be a light-emitting diode that emits red light, the light-emitting diode 420G can be a light-emitting diode that emits green light, and the light-emitting diode 420B can be a light-emitting diode that emits blue light. As the stacked-layer structure, the stacked-layer structure applicable to the light-emitting diode included in the LED package 170 in FIG. 9.

The color of light, other than red, green, and blue, emitted by the light-emitting diode 420 can be cyan, magenta, yellow, or white.

For the protective layer 411, an inorganic insulating film that can be used as an insulator 105 or an organic insulating film can be used, for example. Alternatively, for the protective layer 411, a material usable for the sealing layer 178 of the LED package 170 in FIG. 11A can be used, for example.

The substrate 410 is attached to the stack SST with use of a conductor 193a to a conductor 193c and a conductor 194a to a conductor 194c each serving as a bump. Specifically, the conductor 112a included in the stack SST and the electrode 183a of the light-emitting diode 420R are bonded through the conductor 194a; the conductor 111a included in the stack SST and the electrode 186a of the light-emitting diode 420R are bonded through the conductor 193a; the conductor 112b included in the stack SST and the electrode 183b of the light-emitting diode 420G are bonded through the conductor 194b; the conductor 111b included in the stack SST and the electrode 186b of the light-emitting diode 420G are bonded through the conductor 193b; the conductor 112c included in the stack SST and the electrode 183c of the light-emitting diode 420B are bonded through the conductor 194c; and the conductor 111c included in the stack SST and the electrode 186c of the light-emitting diode 420B are bonded through the conductor 193c.

For the conductor 193a to the conductor 193c and the conductor 194a to the conductor 194c, a material usable for the conductor 117 or the conductor 118 can be used.

The color conversion layer 190 used in the LED package 170A2 in FIG. 11C can be used for the display apparatus 1001. Specifically, the color conversion layer 190 is provided between the substrate 410 and at least one of the semiconductor layer 185a to the semiconductor layer 185c on the path of light emitted by the light-emitting diode 420R, the light-emitting diode 420G, or the light-emitting diode 420B, whereby the color conversion layer 190 can convert the color of light emitted by the light-emitting layer into a different color.

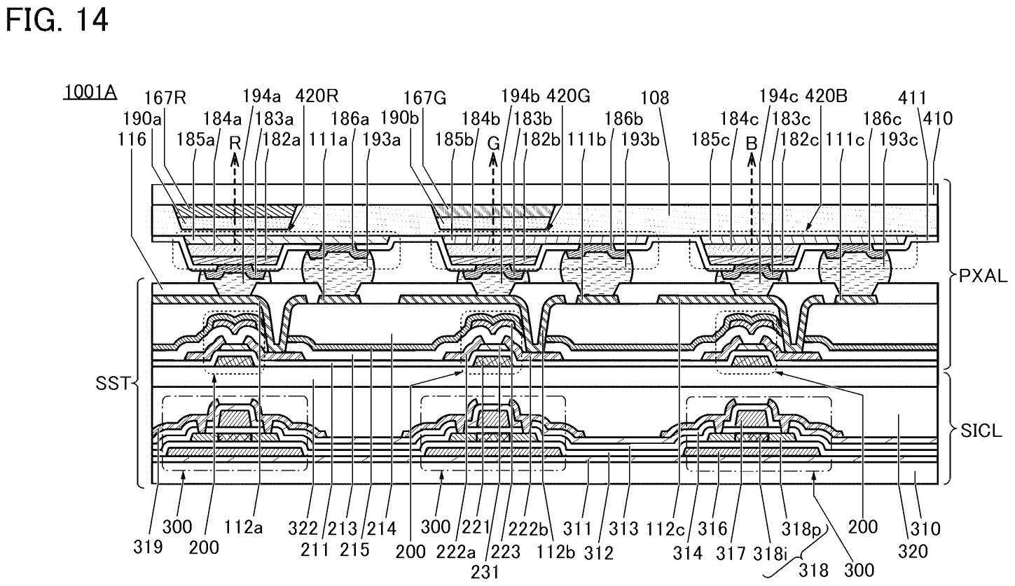

Here, for example, the case where each of the light-emitting diode 420R, the light-emitting diode 420G, and the light-emitting diode 420B is a light-emitting diode emitting blue light is considered. A display apparatus 1001A illustrated in FIG. 14 has a structure changed from that of the display apparatus 1001 in FIG. 13A, and is provided with a coloring layer 167R, a color conversion layer 190a, a coloring layer 167G, a color conversion layer 190b, and an adhesive layer 108 on the substrate 410

Specifically, the coloring layer 167R and the color conversion layer 190a are sequentially formed on the substrate 410 in a region overlapping with the light-emitting diode 420R. The coloring layer 167G and the color conversion layer 190b are sequentially formed on the substrate 410 in a region overlapping with the light-emitting diode 420G. The adhesive layer 108 is provided to cover the substrate 410, the coloring layer 167R, the color conversion layer 190a, the coloring layer 167G, and the color conversion layer 190b.

The light-emitting diode 420R, the light-emitting diode 420G, and the light-emitting diode 420B described with reference to the display apparatus 1001 in FIG. 13A are provided on the adhesive layer 108.

Specifically, the semiconductor layer 185a to the semiconductor layer 185c are provided in some regions over the adhesive layer 108. The light-emitting layer 184a and the semiconductor layer 185a are provided in this order over a region of the semiconductor layer 185a overlapping with the coloring layer 167R and the color conversion layer 190a, and the light-emitting layer 184b and the semiconductor layer 185b are provided in this order over a region of the semiconductor layer 185b overlapping with the coloring layer 167G and the color conversion layer 190b. The light-emitting layer 184c and the semiconductor layer 185c are provided in this order in a region over part of the semiconductor layer 185c in this order. The protective layer 411 is formed to cover the top surface of the adhesive layer 108, the top surfaces and side surfaces of the semiconductor layer 185a to the semiconductor layer 185c, the side surfaces of the light-emitting layer 184a to the light-emitting layer 184c, and the top surfaces and side surfaces of the semiconductor layer 182a to the semiconductor layer 182c.

As in the display apparatus 1001 in FIG. 13A, an opening portion is formed in the protective layer 411 in a region overlapping with part of the semiconductor layer 182a, and the electrode 183a is formed to cover part of the protective layer 411 and the top surface of the semiconductor layer 182a which corresponds to the bottom surface of the opening portion. Similarly, an opening portion is formed in the protective layer 411 in a region overlapping with part of the semiconductor layer 182b, and the electrode 183b is formed to cover part of the protective layer 411 and the top surface of the semiconductor layer 182b which corresponds to the bottom surface of the opening portion. Similarly, an opening portion is formed in the protective layer 411 in a region overlapping with part of the semiconductor layer 182c, and the electrode 183c is formed to cover part of the protective layer 411 and the top surface of the semiconductor layer 182c which corresponds to the bottom surface of the opening portion.

As the display apparatus 1001 in FIG. 13A, an opening portion is formed in the protective layer 411 in a region overlapping with part of the semiconductor layer 185a and not overlapping with the semiconductor layer 182a or the light-emitting layer 184a, and the electrode 186a is formed to cover part of the protective layer 411 and the semiconductor layer 185a which corresponds to the bottom surface of the opening portion. Similarly, an opening portion is formed in the protective layer 411 in a region overlapping with part of the semiconductor layer 185b and not overlapping with the semiconductor layer 182b or the light-emitting layer 184b, and the electrode 186b is formed to cover part of the protective layer 411 and the semiconductor layer 185b which corresponds to the bottom surface of the opening portion. Similarly, an opening portion is formed in the protective layer 411 in a region overlapping with part of the semiconductor layer 185c and not overlapping with the semiconductor layer 182c or the light-emitting layer 184c, and the electrode 186c is formed to cover part of the protective layer 411 and the semiconductor layer 185c which corresponds to the bottom surface of the opening portion.

Here, the color conversion layer 190a has a function of converting blue light into red light, and the color conversion layer 190b has a function of converting blue light into green light. The coloring layer 167R is a colored layer that transmits light in a red wavelength range, and the coloring layer 167G is a colored layer that transmits light in a green wavelength range. Thus, blue light emitted from the light-emitting diode 420R is converted into red light by the color conversion layer 190a, and red light whose color purity is increased by the coloring layer 167R is emitted to the outside of the display apparatus 1001A. Similarly, blue light emitted from the light-emitting diode 420G is converted into green light by the color conversion layer 190b, and green light whose color purity is increased by the coloring layer 167G is emitted to the outside of the display apparatus 1001A.

As illustrated in FIG. 13A and FIG. 14, one embodiment of the present invention can be a display apparatus in which a substrate provided with a transistor and a substrate provided with a light-emitting diode are bonded to each other with a bump or the like.

A variety of optical members can be provided on surfaces of the resin layer 148, the LED package 170R, the LED package 170G, and the LED package 170B, for example, in the display apparatus 1000. Examples of the optical members include a polarizing plate, a retardation plate, a light diffusion layer (e.g., a diffusion film), an anti-reflective layer, and a light-condensing film. The surfaces of the resin layer 148, the LED package 170R, the LED package 170G, and the LED package 170B, for example, in the display apparatus 1000 may be provided with a surface protective layer such as an antistatic film suppressing the attachment of a foreign substance, a water repellent film suppressing the attachment of stain, a hard coat film suppressing generation of a scratch in use, or an impact absorption layer. For example, it is preferable to provide, as the surface protective layer, a glass layer or a silica layer (SiOₓ layer) because the surface contamination or damage can be inhibited from being generated. For the surface protective layer, DLC (diamond-like carbon), aluminum oxide (AlOₓ), a polyester-based material, a polycarbonate-based material, or the like may be used. For the surface protective layer, a material having a high transmittance with respect to visible light is preferably used. For the surface protective layer, a material with high hardness is preferably used.

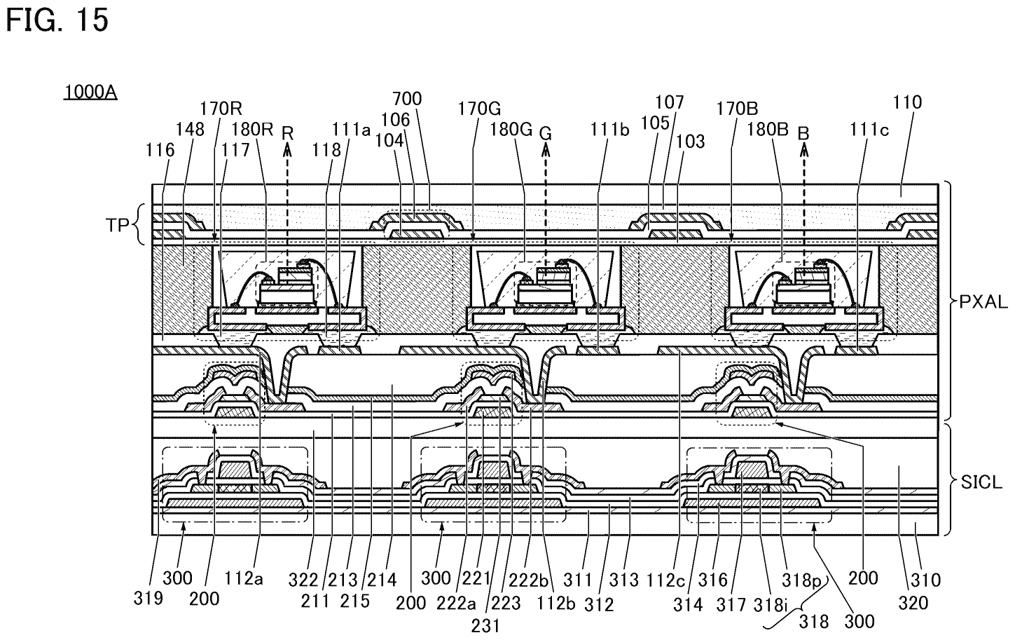

Like a display apparatus 1000A illustrated in FIG. 15, the display apparatus 1000 in FIG. 9 may be provided with a panel having a touch sensor function (referred to as a touch panel in some cases), for example. In the display apparatus 1000A in FIG. 15, a plurality of sensor portions 700 are provided over the resin layer 148 and the LED package 170. Specifically, the display apparatus 1000A has a structure in which an insulator 103, a conductor 104, the insulator 105, and a conductor 106 are formed in this order over the resin layer 148 and the LED package 170, for example. In the display apparatus 1000A, the insulator 105 and the conductor 106 are bonded to a substrate 110 with an adhesive layer 107 therebetween. That is, a sensor portion 700 includes the conductor 104, the insulator 105, and the conductor 106.

In the display apparatus 1000A in FIG. 15, a layer including the plurality of sensor portions 700 is illustrated as a touch sensor layer TP.

The insulator 103 preferably contains an inorganic insulating material. Examples of an oxide or a nitride which can be used for the insulator 103 include silicon oxide, silicon oxynitride, silicon nitride oxide, silicon nitride, aluminum oxide, aluminum oxynitride, and hafnium oxide.

The conductor 104 and the conductor 106 serve as electrodes of a touch sensor. In the case of using a mutual capacitive touch sensor, a pulse potential may be supplied to one of the conductor 104 and the conductor 106, and an analog-digital (A-D) converter circuit or a sensing circuit such as a sense amplifier may be connected to the other of the conductor 104 and the conductor 106, for example. In that case, capacitance is formed between the conductor 104 and the conductor 106. When a finger or the like approaches the conductor 104 and the conductor 106, the capacitance changes (specifically, the capacitance is reduced). This change in the capacitance appears, when a pulse potential is supplied to one of the conductor 104 and the conductor 106, as a change in the amplitude of a signal that occurs in the other of the conductor 104 and the conductor 106. Accordingly, the touch and approach of the finger or the like can be sensed.

For each of the conductor 104 and the conductor 106, any of the materials usable for the conductor 316 or the conductor 317 can be used, for example.

In the case where the conductor 104 and the conductor 106 use a material which is less likely to transmit visible light (which has a low visible light transmittance, which has a high visible light absorbance, and which has a high visible light reflectance), the conductor 104 and the conductor 106 are preferably provided in a region between the adjacent LED packages 170 so as not to block visible light from the LED package 170. Note that in the case where the conductor 104 and the conductor 106 have a light-transmitting property, a region where the conductor 104 and the conductor 106 are provided is not limited to the above.

For the insulator 105, an inorganic insulating film or an organic insulating film can be used, for example. For the insulator 105, a resin such as an acrylic resin or an epoxy resin can be used, for example. Alternatively, for the insulator 105, an inorganic insulating material such as silicon oxide, silicon oxynitride, silicon nitride oxide, silicon nitride, or aluminum oxide can be used, for example. Note that the insulator 105 may have either a single-layer structure or a stacked-layer structure.

For the adhesive layer 107, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. An adhesive sheet and the like may be used.

Note that although the display apparatus 1000A in FIG. 15 has a structure in which a mutual capacitive touch sensor is used, one embodiment of the present invention is not limited thereto. For example, in one embodiment of the present invention, a light-receiving device (referred to as a photodiode or a photoelectric conversion element in some cases) that generates a current by receiving light may be used instead of the sensor portion 700 in the display apparatus 1000A. Thus, when a finger touches the substrate 110, for example, the light-receiving device can receive light reflected by the finger and sense contact and approach of the finger to the display portion of the display apparatus 1000A. The light-receiving device may have a function of generating current by receiving visible light or may have a function of generating current by receiving infrared light (also referred to as IR in some cases), in which case the light-emitting device (including a light-emitting diode) that emits light (visible light or infrared rays) to be received may be provided in the display apparatus 1000A.

The display apparatus 1000A has a top-emission structure. Light emitted from the LED package 170 is emitted toward the substrate 110 side. Thus, for the substrate 110, a material having a high visible-light-transmitting property is preferably used. For example, a substrate having a high visible-light-transmitting property may be selected as the substrate 110 from substrates usable as the substrate BS.

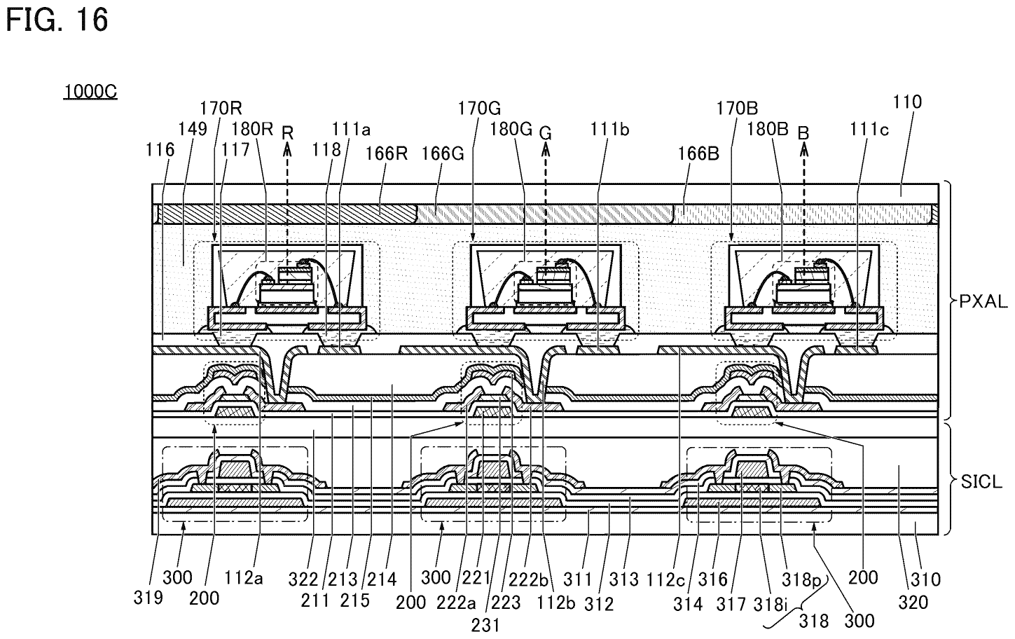

The display apparatus 1000 in FIG. 9 may include, for example, a coloring layer (a color filter) or the like. In a display apparatus 1000C in FIG. 16, for example, the top surface of the protective layer 116, the top surface and side surfaces of the conductor 117, the top surface and side surfaces of the conductor 118, the top surface and side surfaces of the LED package 170R, the top surface and side surfaces of the LED package 170G, and the top surface and side surfaces of the LED package 170B are covered with a resin layer 149. The display apparatus 1000C has a structure including a coloring layer 166R, a coloring layer 166G, and a coloring layer 166B between the resin layer 149 and the substrate 110, for example. Note that the coloring layer 166R, the coloring layer 166G, and the coloring layer 166B may be formed on the substrate 110 side or on the resin layer 149 side, for example. In the case where the LED package 170R emits red (R) light, the LED package 170G emits green (G) light, and the LED package 170B emits blue (B) light, the coloring layer 166R is preferably red, the coloring layer 166G is preferably green, and the coloring layer 166B is preferably blue.

As described above, when a light-emitting diode is used in the pixel PX of the display apparatus DSP described in Embodiment 1 and Embodiment 2, a display apparatus with a high luminance and a longer lifetime than OLED can be fabricated.

Note that the display apparatus of one embodiment of the present invention is not limited to the structure of the display apparatus 1000 illustrated in FIG. 9. The structure of the display apparatus of one embodiment of the present invention may be changed as appropriate within the scope of achieving an object, or the structures described in this specification and the like may be combined as appropriate.

For example, the display apparatus may have not a layer structure in which two transistors are stacked but a layer structure in which three or more transistors are stacked.

### <Structure Example of Pixel Circuit>

Here, structure examples of a pixel circuit that can be included in the pixel layer PXAL are described.

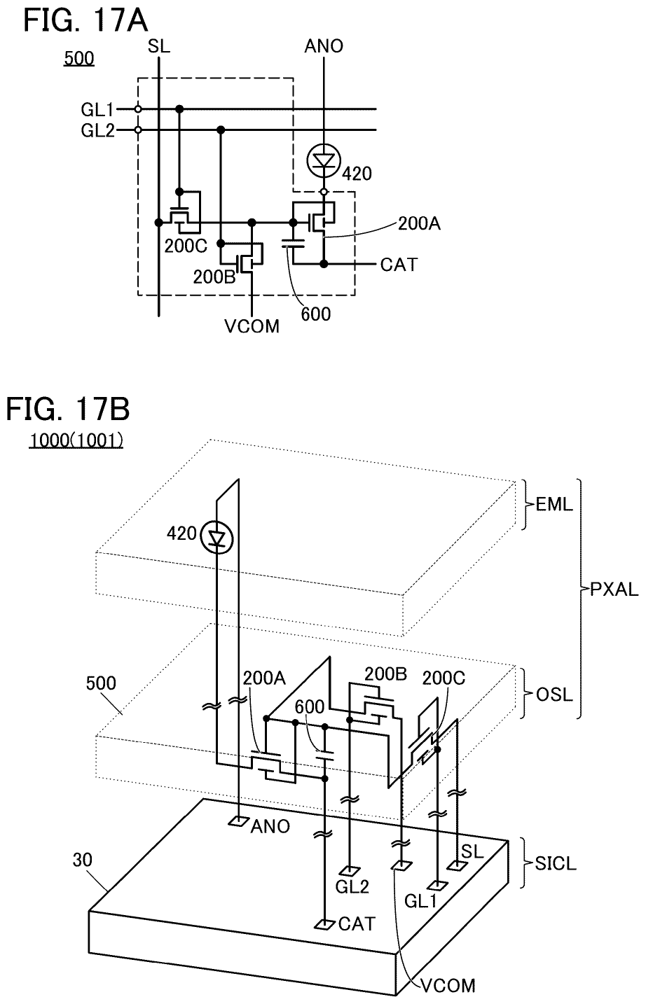

FIG. 17A and FIG. 17B illustrate a structure example of a pixel circuit that can be included in the pixel layer PXAL and the light-emitting diode 420 connected to the pixel circuit. FIG. 17A is a diagram illustrating connection of circuit elements included in a pixel circuit 500 included in the pixel layer PXAL, and FIG. 17B is a diagram schematically illustrating the vertical relation of the circuit layer SICL including a driver circuit 30 and the like, a layer OSL including a plurality of transistors of the pixel circuit, and a layer EML including the light-emitting diode 420. Note that the pixel layer PXAL of the display apparatus 1000 (the display apparatus 1001) illustrated in FIG. 17B includes the layer OSL and the layer EML, for example. The transistor 200A, the transistor 200B, and a transistor 200C included in the layer OSL illustrated in FIG. 17B each correspond to the transistor 200 in FIG. 9 and FIG. 13. The light-emitting diode 420 included in the layer EML illustrated in FIG. 17B corresponds to the light-emitting diode included in any one of the LED package 170R, the LED package 170G, and the LED package 170B in FIG. 9, or any one of the light-emitting diode 420R, the light-emitting diode 420G, and the light-emitting diode 420B in FIG. 13.

The pixel circuit 500 illustrated as an example in FIG. 17A and FIG. 17B includes the transistor 200A, the transistor 200B, the transistor 200C, and a capacitor 600. The transistor 200A, the transistor 200B, and the transistor 200C can be, for example, transistors usable as the transistor 200 described above as examples. That is, the transistor 200A, the transistor 200B, and the transistor 200C can be OS transistors. In particular, in the case where the transistor 200A, the transistor 200B, and the transistor 200C are OS transistors, each of the transistor 200A, the transistor 200B, and the transistor 200C preferably includes a back gate electrode, in which case the transistors can have a structure in which the back gate electrode is supplied with the same signals as those supplied to the gate electrode as shown in FIG. 17A and FIG. 17B. Each of the transistor 200A, the transistor 200B, and the transistor 200C can have a structure in which different signals are supplied to the back gate electrode and the gate electrode. Although each of the transistor 200A, the transistor 200B, and the transistor 200C illustrated in FIG. 17A and FIG. 17B includes a back gate electrode, each of the transistor 200A, the transistor 200B, and the transistor 200C does not necessarily include a back gate electrode.

The transistor 200B includes a first terminal electrically connected to the gate electrode of the transistor 200A, a gate electrode electrically connected to a wiring GL2, and a second terminal electrically connected to a wiring VCOM. The wiring VCOM is a wiring for supplying a constant potential to the gate electrode of the transistor 200A. Note that the constant potential can be, for example, a potential for turning off the transistor 200A. The transistor 200B includes a gate electrode having a function of controlling the conduction state or the non-conduction state on the basis of the potential of the wiring GL2 functioning as a gate line.

The transistor 200A includes the gate electrode electrically connected to the first terminal of the transistor 200B, a first terminal electrically connected to the cathode electrode of the light-emitting diode 420, and a second terminal electrically connected to a wiring CAT. The transistor 200A also includes a gate electrode having a function of controlling the conduction state or non-conduction state on the basis of the potential of a wiring GL1 functioning as a gate line. The wiring CAT functions as a wiring that outputs a current flowing from the light-emitting diode 420 through the transistor 200A.

The transistor 200C includes a first terminal electrically connected to the wiring SL functioning as a source wiring, a second terminal electrically connected to the gate electrode of the transistor 200A and the first terminal of the transistor 200B, and a gate electrode electrically connected to the wiring GL1. The transistor 200A has a function of controlling the conduction state or non-conduction state on the basis of the potential of the wiring GL1 functioning as a gate line.

The capacitor 600 includes a conductive film electrically connected to the gate electrode of the transistor 200A and a conductive film electrically connected to a second terminal of the transistor 200A.

The light-emitting diode 420 includes a cathode electrode electrically connected to the first terminal of the transistor 200A and an anode electrode electrically connected to a wiring ANO. The wiring ANO is a wiring for supplying a potential for supplying current to the light-emitting diode 420.

Accordingly, the intensity of light emitted from the light-emitting diode 420 can be controlled in accordance with an image signal supplied to the gate electrode of the transistor 200A.

Note that the pixel circuit in FIG. 17A and FIG. 17B is a circuit that is driven by PAM (Pulse Amplitude Modulation) control; however, one embodiment of the present invention is not limited thereto. For example, the pixel circuit including the light-emitting diode of the display apparatus of one embodiment of the present invention may be driven by PWM (Pulse Width Modulation) control.

The pixel circuit in FIG. 17A and FIG. 17B can output a current value that can be used for setting of a pixel parameter from the wiring CAT, for example. Specifically, the wiring CAT may function as a monitor line for outputting current flowing through the transistor 200A or current flowing through the light-emitting diode 420 to the outside. For example, a current output to the wiring CAT can be converted into voltage by a source follower circuit or the like, which can be output to the outside. Alternatively, for example, a voltage output to the wiring CAT can be converted into a digital signal by an A-D converter or the like, which can be and output to the AI accelerator included in the external control circuit PRPH, which is described in the above embodiment.

Note that in the structure illustrated as an example in FIG. 17B, the wirings electrically connecting the pixel circuit 500 and the driver circuit 30 can be shortened, so that wiring resistance of the wirings can be reduced. Thus, data writing can be performed at high speed, leading to high-speed driving of the display apparatus 1000 (the display apparatus 1001). Therefore, even when the number of pixel circuits 500 included in the display apparatus 1000 (the display apparatus 1001) is large, a sufficient frame period can be feasible and thus the pixel density of the display apparatus 1000 (the display apparatus 1001) can be increased. In addition, the increased pixel density of the display apparatus 1000 (the display apparatus 1001) can increase the resolution of an image displayed by the display apparatus 1000 (the display apparatus 1001). For example, the pixel density of the display apparatus 1000 (the display apparatus 1001) can be greater than or equal to 500 ppi, preferably greater than or equal to 1000 ppi. Thus, the display apparatus 1000 can be, for example, a display apparatus for AR or VR and can be suitably used in an electronic device with a short distance between a display portion and the user, such as a head-mounted display (TIMID).

### <Pixel Layout>

Here, a pixel layout is described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and pentile arrangement.

Examples of the top surface shape of the subpixel include polygons such as a triangle, a tetragon (including a rectangle and a square), and a pentagon; polygons with rounded corners; an ellipse; and a circle. Here, the top surface shape of the subpixel corresponds to the top surface shape of a light-emitting region of the light-emitting diode.

Note that a subpixel 80a, a subpixel 80b, and a subpixel 80c described below each include a light-emitting diode. The light-emitting diode includes a pixel electrode, an n-type semiconductor layer, a p-type semiconductor layer, a light-emitting layer, and a common electrode, for example. Note that the description of the LED package 170 in FIG. 11A, the LED package 170A1 in FIG. 11B, the LED package 170A2 in FIG. 11C, the LED package 170A3 in FIG. 11D, and the light-emitting diode 420R, the light-emitting diode 420G, and the light-emitting diode 420B in FIG. 13A and FIG. 13B is referred to for the structure of the light-emitting diode.

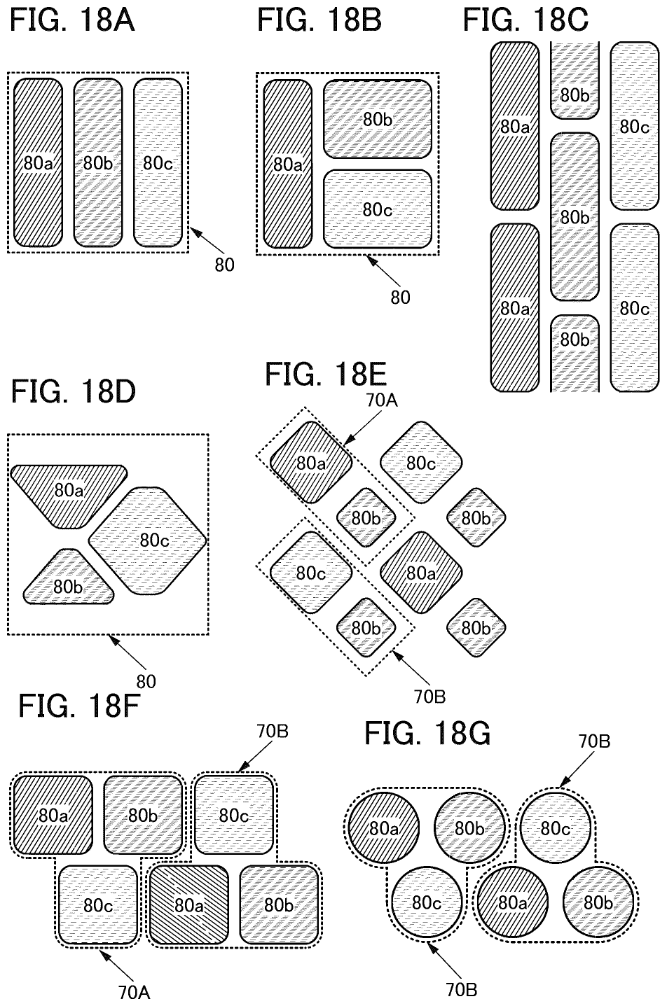

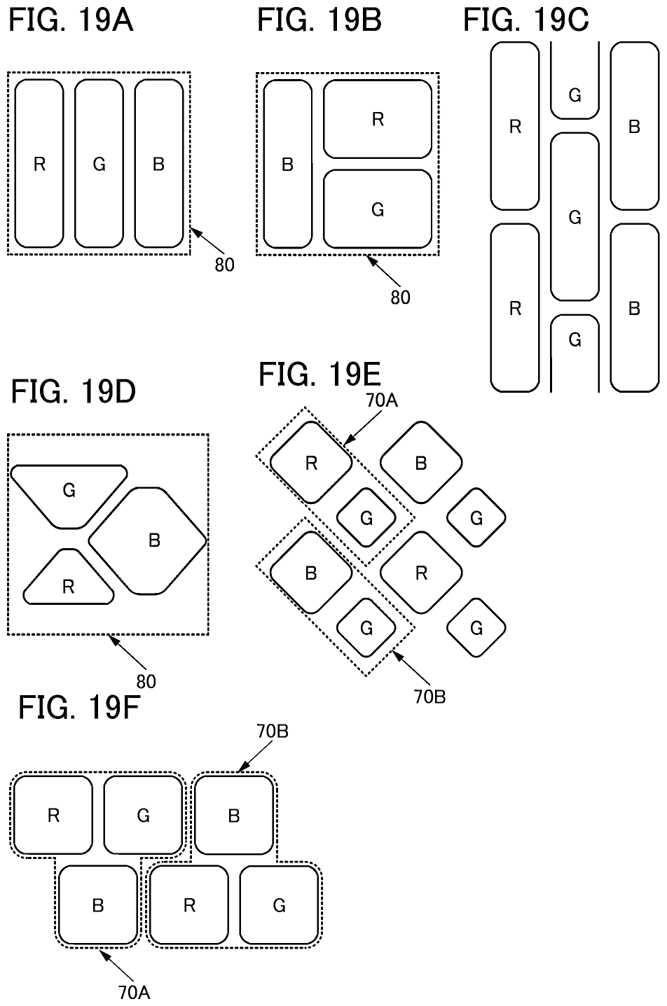

A pixel 80 illustrated in FIG. 18A employs stripe arrangement. The pixel 80 illustrated in FIG. 18A is composed of three subpixels: the subpixel 80a, the subpixel 80b, and the subpixel 80c. For example, as illustrated in FIG. 19A, the subpixel 80a may be a red subpixel R, the subpixel 80b may be a green subpixel G, and the subpixel 80c may be a blue subpixel B.

The pixel 80 illustrated in FIG. 18B employs S-stripe arrangement. The pixel 80 illustrated in FIG. 18B is composed of three subpixels: the subpixel 80a, the subpixel 80b, and the subpixel 80c. For example, as illustrated in FIG. 19B, the subpixel 80a may be the blue subpixel B, the subpixel 80b may be the red subpixel R, and the subpixel 80c may be the green subpixel G.

FIG. 18C illustrates an example where subpixels of different colors are arranged in a zigzag manner. Specifically, the positions of the top sides of two subpixels arranged in the column direction (e.g., the subpixel 80a and the subpixel 80b or the subpixel 80b and the subpixel 80c) are not aligned in the plan view. For example, as illustrated in FIG. 19C, the subpixel 80a may be the red subpixel R, the subpixel 80b may be the green subpixel G, and the subpixel 80c may be the blue subpixel B.

The pixel 80 illustrated in FIG. 18D includes the subpixel 80a whose top surface has a rough trapezoidal shape with rounded corners, the subpixel 80b whose top surface has a rough triangle shape with rounded corners, and the subpixel 80c whose top surface has a rough tetragonal or rough hexagonal shape with rounded corners. The subpixel 80a has a larger light-emitting area than the subpixel 80b. In this manner, the shapes and sizes of the subpixels can be determined independently. For example, as illustrated in FIG. 19D, the subpixel 80a may be the green subpixel G, the subpixel 80b may be the red subpixel R, and the subpixel 80c may be the blue subpixel B.

A pixel 70A and a pixel 70B illustrated in FIG. 18E employ pentile arrangement. FIG. 18E illustrates an example where the pixels 70A including the subpixel 80a and the subpixel 80b and the pixels 70B including the subpixel 80b and the subpixel 80c are alternately arranged. For example, as illustrated in FIG. 19E, the subpixel 80a may be the red subpixel R, the subpixel 80b may be the green subpixel G, and the subpixel 80c may be the blue subpixel B.

The pixel 70A and the pixel 70B illustrated in FIG. 18F and FIG. 18G employ delta arrangement. The pixel 70A includes two subpixels (the subpixel 80a and the subpixel 80b) in the upper row (first row) and one subpixel (the subpixel 80c) in the lower row (second row). The pixel 70B includes one subpixel (the subpixel 80c) in the upper row (first row) and two subpixels (the subpixel 80a and the subpixel 80b) in the lower row (second row). For example, as illustrated in FIG. 19F, the subpixel 80a may be the red subpixel R, the subpixel 80b may be the green subpixel G, and the subpixel 80c may be the blue subpixel B.

FIG. 18F illustrates an example where the top surface of each subpixel has a rough tetragonal shape with rounded corners, and FIG. 18G illustrates an example where the top surface of each subpixel has a circular shape.

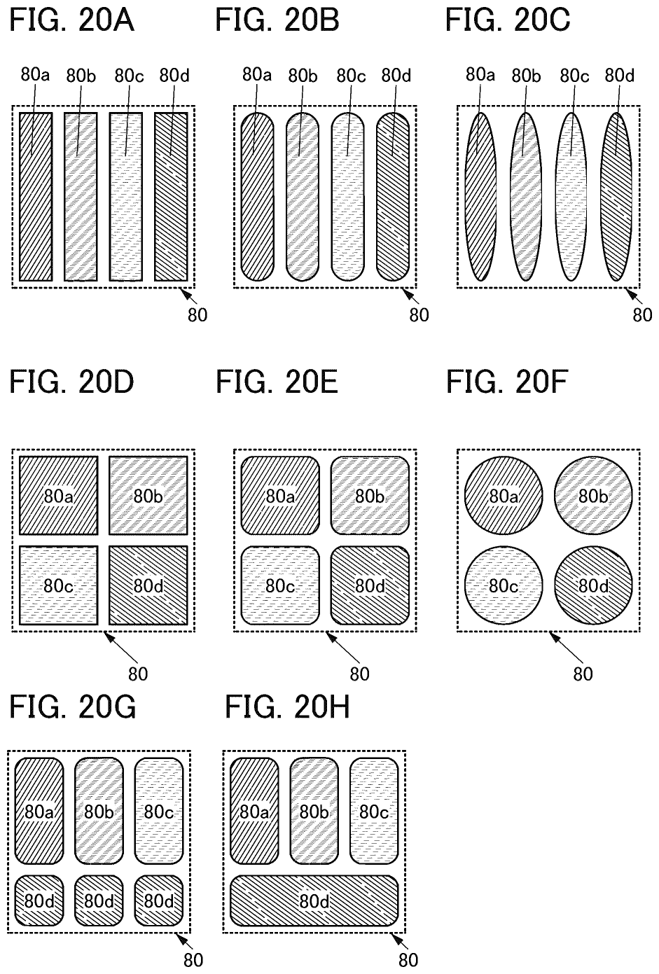

The pixels 80 illustrated in FIG. 20A to FIG. 20C employ stripe arrangement.

FIG. 20A illustrates an example where each subpixel has a rectangular top surface shape, FIG. 20B illustrates an example where each subpixel has a top surface shape formed by combining two half circles and a rectangle, and FIG. 20C illustrates an example where each subpixel has an elliptical top surface shape.

The pixels 80 illustrated in FIG. 20D to FIG. 20F employ matrix arrangement.

FIG. 20D illustrates an example where each subpixel has a square top surface shape, FIG. 20E illustrates an example where each subpixel has a substantially square top surface shape with rounded corners, and FIG. 20F illustrates an example where each subpixel has a circular top surface shape.

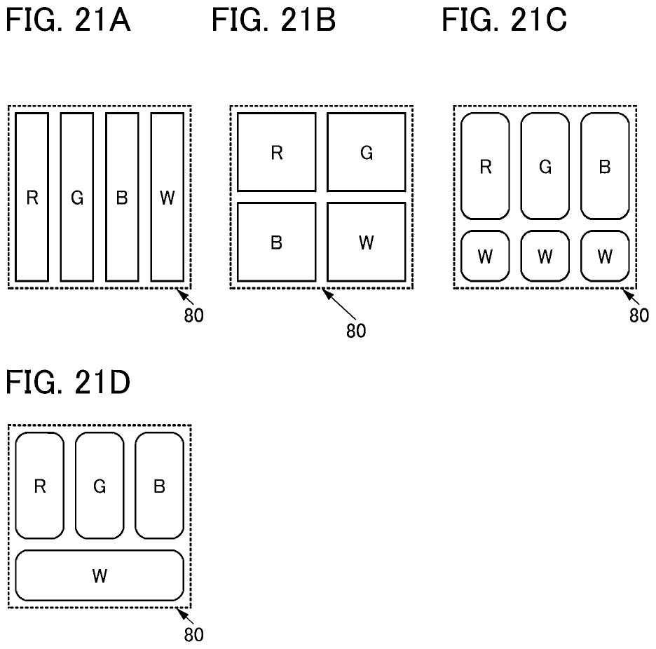

The pixels 80 illustrated in FIG. 20A to FIG. 20F are each composed of four subpixels: the subpixel 80a, the subpixel 80b, the subpixel 80c, and a subpixel 80d. The subpixel 80a, the subpixel 80b, the subpixel 80c, and the subpixel 80d emit light of different colors. For example, the subpixel 80a, the subpixel 80b, the subpixel 80c, and the subpixel 80d can be red, green, blue, and white subpixels, respectively. For example, the subpixel 80a, the subpixel 80b, the subpixel 80c, and the subpixel 80d can be subpixels for red (R), green (G), blue (B), and white (W), respectively, as illustrated in FIG. 21A and FIG. 21B. Alternatively, the subpixel 80a, the subpixel 80b, the subpixel 80c, and the subpixel 80d can be red, green, blue, and infrared-light subpixels, respectively.

Note that for the structure of the subpixel 80d, the description of the subpixel 80a, the subpixel 80b, and the subpixel 80c is referred to, for example.

FIG. 20G illustrates an example where one pixel 80 is composed of two rows and three columns. The pixel 80 includes three subpixels (the subpixel 80a, the subpixel 80b, and the subpixel 80c) in the upper row (first row) and three subpixels 80d in the lower row (second row). In other words, the pixel 80 includes the subpixel 80a and the subpixel 80d in the left column (first column), the subpixel 80b and the subpixel 80d in the center column (second column), and the subpixel 80c and the subpixel 80d in the right column (third column).

FIG. 20H illustrates an example where one pixel 80 is composed of two rows and three columns. The pixel 80 includes three subpixels (the subpixel 80a, the subpixel 80b, and the subpixel 80c) in the upper row (first row) and one subpixel (the subpixel 80d) in the lower row (second row). In other words, the pixel 80 includes the subpixel 80a in the left column (first column), the subpixel 80b in the center column (second column), the subpixel 80c in the right column (third column), and the subpixel 80d across these three columns.

In the pixel 80 illustrated in each of FIG. 20G and FIG. 20H, for example, the subpixel 80a can be the red subpixel R, the subpixel 80b can be the green subpixel G, the subpixel 80c can be the blue subpixel B, and the subpixel 80d can be a white subpixel W, as illustrated in FIG. 21C and FIG. 21D.

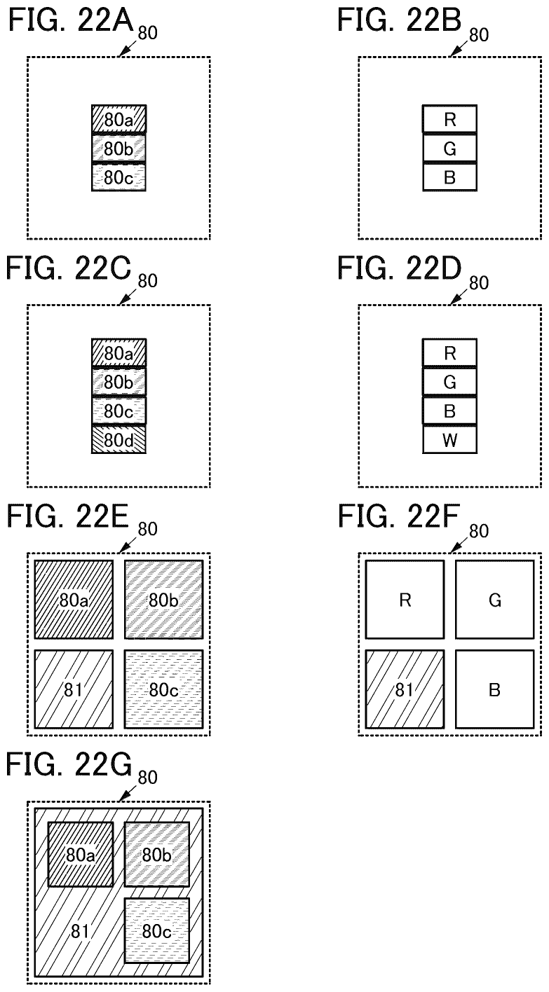

In the pixel 80 illustrated in FIG. 22A, subpixels each have a rectangular top surface and are arranged such that long sides of the subpixels are adjacent to one another. Note that the subpixels may be arranged to be in contact with each other or may be arranged not to be in contact with each other.

The pixel 80 illustrated in FIG. 22A includes three subpixels: the subpixel 80a, the subpixel 80b, and the subpixel 80c. As an example, the subpixel 80a, the subpixel 80b, and the subpixel 80c emit light of different colors. The different colors here can be, for example, red (R), green (G), and blue (B). Thus, the subpixel 80a, the subpixel 80b, and the subpixel 80c can be subpixels for red (R), green (G), and blue (B), respectively, as illustrated in FIG. 22B.

Note that in FIG. 22B, the colors of light emitted by the subpixel 80a, the subpixel 80b, and the subpixel 80c can be cyan (C), magenta (M), yellow (Y), or white (W) in addition to red (R), green (G), and blue (B).

The number of subpixels included in the pixel 80 illustrated in FIG. 22A is three, but the number of subpixels included in the pixel 80 illustrated in FIG. 22A may be one, two, or four or more. For example, as illustrated in FIG. 22C, the pixel 80 includes four subpixels: the subpixel 80a, the subpixel 80b, the subpixel 80c, and the subpixel 80d. The subpixel 80a, the subpixel 80b, and the subpixel 80c in the pixel 80 in FIG. 22C can be configured to emit light of different colors in a manner similar to that of the pixel 80 in FIG. 22A. The different colors here can be, for example, red (R), green (G), blue (B), and white (W). Accordingly, the subpixel 80a, the subpixel 80b, the subpixel 80c, and the subpixel 80d can be subpixels for red (R), green (G), blue (B), and white (W), respectively, as illustrated in FIG. 22D.

Note that in FIG. 22D, the colors of light emitted by the subpixel 80a, the subpixel 80b, the subpixel 80c, and the subpixel 80d can be cyan (C), magenta (M), or yellow (Y) in addition to red (R), green (G), blue (B), and white (W).

Although FIG. 22A and FIG. 22C illustrate examples where the subpixels in the pixel 80 are arranged such that the long sides are adjacent to one another as an example, the subpixels in the pixel 80 may be arranged such that the short sides are adjacent to one another.

FIG. 22E illustrates an example where each subpixel has a square top surface and an electrode is formed.

The pixel 80 illustrated in FIG. 22E includes a conductor 81 serving as an electrode and three subpixels: the subpixel 80a, the subpixel 80b, and the subpixel 80c.

As an example, the subpixel 80a, the subpixel 80b, and the subpixel 80c emit light of different colors. The different colors here can be, for example, red (R), green (G), and blue (B). Thus, the subpixel 80a, the subpixel 80b, and the subpixel 80c can be subpixels for red (R), green (G), and blue (B), respectively, as illustrated in FIG. 22F.

Note that in FIG. 22F, the colors of light emitted by the subpixel 80a, the subpixel 80b, and the subpixel 80c can be cyan (C), magenta (M), yellow (Y), or white (W) in addition to red (R), green (G), and blue (B).

The conductor 81 has a function of a common electrode of light-emitting diodes provided in the subpixel 80a, the subpixel 80b, and the subpixel 80c, for example. In particular, the common electrode preferably serves as a cathode electrode of the light-emitting diode included in each of the subpixel 80a, the subpixel 80b, and the subpixel 80c.

The conductor 81 corresponds to the electrode 172 or the electrode 173 in the LED package 170 in FIG. 11A, for example. Thus, a material usable for the electrode 172 or the electrode 173 can be used as a material for the conductor 81, for example.

Note that the conductor 81 may be provided such that the subpixel 80a, the subpixel 80b, and the subpixel 80c are positioned above the conductor 81 as illustrated in FIG. 22G. That is, the subpixel 80a, the subpixel 80b, and the subpixel 80c are provided over the conductor 81. The conductor 81 of the pixel 80 in FIG. 22G corresponds the electrode 172 of the LED package 170A1 in FIG. 11B.

Although a conductor corresponding to the electrode 173 of the LED package 170A1 in FIG. 11B is not illustrated in the pixel 80 in FIG. 22G, the pixel 80 in FIG. 22G may include the conductor corresponding to the electrode 173.

The number of electrodes of the pixel 80 illustrated in FIG. 22E and FIG. 22G is one, but the number of electrodes of the pixel 80 illustrated in FIG. 22E may be two or more. For example, the number of electrodes of the pixel 80 may be determined in accordance with the number of subpixels. For example, in the case where an anode electrode and a cathode electrode are provided in each of three subpixels in the pixel 80 in FIG. 22E, the number of electrodes provided in the pixel 80 can be six. For another example, in the case where an anode electrode and a common electrode serving as a cathode electrode are provided in each of three subpixels in the pixel 80 in FIG. 22E, the number of electrodes provided in the pixel 80 can be four.

The top surface of the conductor 81 of the pixel 80 has a square shape in FIG. 22E, but the top surface of the conductor 81 may have a variety of shapes such as a rough trapezoid shape with rounded corners, a rough square shape with rounded corners, a rough hexagonal shape with rounded corners, a shape formed by combining a half circle and a rectangle, a circular shape, or an elliptical shape.

One of the plurality of subpixels included in the pixel 80 illustrated in each of FIG. 18A to FIG. 18G, FIG. 20A to FIG. 20H, FIG. 22A, and FIG. 22B may be replaced with the conductor 81.

Note that the insulators, the conductors, the semiconductors, and the like disclosed in this specification and the like can be formed by a PVD (Physical Vapor Deposition) method or a CVD method. Examples of a PVD method include a sputtering method, a resistance-heating evaporation method, an electron beam evaporation method, and a PLD (Pulsed Laser Deposition) method. Examples of a CVD method include a plasma CVD method and a thermal CVD method. Specifically, examples of a thermal CVD method include an MOCVD (Metal Organic Chemical Vapor Deposition) method and an ALD (Atomic Layer Deposition) method.

A thermal CVD method is a deposition method not using plasma, and thus has an advantage that no defect due to plasma damage is generated.

Deposition by a thermal CVD method may be performed in such a manner that a source gas and an oxidizer are supplied into a chamber at a time, the pressure in the chamber is set to an atmospheric pressure or a reduced pressure, and they are made to react with each other in the vicinity of the substrate or over the substrate to be deposited over the substrate.

Deposition by an ALD method may be performed in such a manner that pressure in a chamber is set to an atmospheric pressure or a reduced pressure, source gases for reaction are sequentially introduced into the chamber, and then the sequence of the gas introduction is repeated. For example, two or more kinds of source gases are sequentially supplied to the chamber by switching respective switching valves (also referred to as high-speed valves); in order to avoid mixing of the plurality of kinds of source gases, an inert gas (e.g., argon or nitrogen) or the like is introduced at the same time as or after introduction of a first source gas and then a second source gas is introduced. Note that in the case where the first source gas and the inert gas are introduced at a time, the inert gas serves as a carrier gas, and the inert gas may also be introduced at the same time as the introduction of the second source gas. Alternatively, the second source gas may be introduced after the first source gas is exhausted by vacuum evacuation instead of the introduction of the inert gas. The first source gas is adsorbed on the surface of the substrate to deposit a first thin layer; then the second source gas is introduced to react with the first thin layer; as a result, a second thin layer is stacked over the first thin layer, so that a thin film is formed. The sequence of the gas introduction is controlled and repeated a plurality of times until a desired thickness is obtained, so that a thin film with excellent step coverage can be formed. The thickness of the thin film can be adjusted by the number of repetition times of the sequence of the gas introduction; therefore, an ALD method makes it possible to accurately adjust the thickness and is thus suitable for manufacturing a minute FET.

A variety of films such as the metal film, the semiconductor film, and the inorganic insulating film disclosed in the above-described embodiments can be formed by a thermal CVD method such as an MOCVD method and an ALD method; for example, in the case of depositing an In—Ga—Zn—O film, trimethylindium (In(CH₃)₃), trimethylgallium (Ga(CH₃)₃), and dimethylzinc (Zn(CH₃)₂) are used. Without limitation to the above combination, triethylgallium (Ga(C₂H₅)₃) can also be used instead of trimethylgallium, and diethylzinc (Zn(C₂H₅)₂) can also be used instead of dimethylzinc.

For example, in the case where a hafnium oxide film is formed with a deposition apparatus using an ALD method, two kinds of gases, ozone (O₃) as an oxidizer and a source gas which is obtained by vaporizing liquid containing a solvent and a hafnium precursor compound (e.g., hafnium alkoxide and hafnium amide such as tetrakis(dimethylamide)hafnium (TDMAH, Hf[N(CH₃)₂]₄)), are used. Examples of another material include tetrakis(ethylmethylamide)hafnium.

For example, in the case where an aluminum oxide film is formed with a deposition apparatus using an ALD method, two kinds of gases, H₂O as an oxidizer and a source gas which is obtained by vaporizing liquid containing a solvent and an aluminum precursor compound (e.g., trimethylaluminum (TMA, Al(CH₃)₃)) are used. Examples of another material include tris(dimethylamide)aluminum, triisobutylaluminum, and aluminum tris(2,2,6,6-tetramethyl-3,5-heptanedionate).

For example, in the case where a silicon oxide film is formed by a deposition apparatus using an ALD method, hexachlorodisilane is adsorbed on a surface on which a film is to be formed, and radicals of an oxidizing gas (e.g., O₂ or dinitrogen monoxide) are supplied to react with the adsorbate.

For example, in the case where a tungsten film is deposited by a deposition apparatus using an ALD method, a WF₆ gas and a B₂H₆ gas are sequentially and repeatedly introduced to form an initial tungsten film, and then a WF₆ gas and an H₂ gas are sequentially and repeatedly introduced to form a tungsten film. Note that an SiH₄ gas may be used instead of a B₂H₆ gas.

In the case where an In—Ga—Zn—O film is deposited as an oxide semiconductor film with a deposition apparatus using an ALD method, a precursor (generally referred to as a metal precursor or the like in some cases) and an oxidizer (generally referred to as a reactant, a non-metal precursor, or the like in some cases) are sequentially and repetitively introduced. Specifically, for example, an In(CH₃)₃ gas as a precursor and an O₃ gas) as an oxidizer are introduced to form an In—O layer; a Ga(CH₃)₃ gas as a precursor and an O₃ gas) as an oxidizer are introduced to form a GaO layer; and then, a Zn(CH₃)₂ gas as a precursor and an O₃ gas) as an oxidizer are introduced to form a ZnO layer. Note that the order of these layers is not limited to this example. A mixed oxide layer such as an In—Ga—O layer, an In—Zn—O layer, or a Ga—Zn—O layer may be formed with the use of these gases. Note that although an H₂O gas which is obtained by bubbling water with an inert gas such as Ar may be used instead of an O₃ gas), it is preferable to use an O₃ gas) which does not contain H. Furthermore, instead of an In(CH₃)₃ gas, an In(C₂H₅)₃ gas may be used. Furthermore, instead of a Ga(CH₃)₃ gas, a Ga(C₂H₅)₃ gas may be used. Furthermore, instead of a Zn(CH₃)₂ gas, a Zn(C₂H₅)₂ gas may be used.

There is no particular limitation on the screen ratio (aspect ratio) of the display portion of the electronic device of one embodiment of the present invention. For example, the display portion is compatible with a variety of screen ratios such as 1:1 (a square), 4:3, 16:9, 16:10, 21:9, and 32:9.

There is no particular limitation on the shape of the display portion of the electronic device of one embodiment of the present invention. The display portion can have any of various shapes such as a rectangular shape, a polygonal shape (e.g., an octagonal shape), a circular shape, and an elliptical shape.

Note that this embodiment can be combined with any of the other embodiments in this specification as appropriate.

### Embodiment 4

Described in this embodiment is a metal oxide (hereinafter, also referred to as an oxide semiconductor) that can be used in the OS transistor described in the above embodiment.

The metal oxide used in the OS transistor preferably contains at least indium or zinc, and further preferably contains indium and zinc. The metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and M is further preferably gallium.

The metal oxide can be formed by a sputtering method, a chemical vapor deposition (CVD) method such as a metal organic chemical vapor deposition (MOCVD) method, or an atomic layer deposition (ALD) method and the like.

Hereinafter, an oxide containing indium (In), gallium (Ga), and zinc (Zn) is described as an example of the metal oxide. Note that an oxide containing indium (In), gallium (Ga), and zinc (Zn) may be referred to as an In—Ga—Zn oxide.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) can be given as examples of a crystal structure of an oxide semiconductor.

Note that a crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of the In—Ga—Zn oxide film having a crystal structure has a bilaterally asymmetrical shape. The asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of a quartz glass substrate, which indicates that the quartz glass substrate is in an amorphous state. Furthermore, not a halo pattern but a spot-like pattern is observed in the diffraction pattern of an In—Ga—Zn oxide film formed at room temperature. This suggests that the In—Ga—Zn oxide film formed at room temperature is in an intermediate state, which is neither a single crystal nor polycrystal nor an amorphous state, and it cannot be concluded that the In—Ga—Zn oxide film is in an amorphous state.

### [Structure of Oxide Semiconductor]

Note that oxide semiconductors may be classified in a manner different from the above when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the CAAC-OS, the nc-OS, and the a-like OS will be described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one minute crystal, the maximum diameter of the crystal region is less than 10 nm. In the case where the crystal region is formed of a large number of fine crystals, the maximum diameter of the crystal region may be approximately several tens of nanometers.

In the case of an In—Ga—Zn oxide, the CAAC-OS tends to have a layered crystal structure (also referred to as a layered structure) in which a layer containing indium (In) and oxygen (hereinafter, an In layer) and a layer containing gallium (Ga), zinc (Zn), and oxygen (hereinafter, a (Ga,Zn) layer) are stacked. Indium and gallium can be replaced with each other. Therefore, indium may be contained in the (Ga,Zn) layer. In addition, gallium may be contained in the In layer. Note that zinc may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 2θ=31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (also referred to as grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor is sometimes decreased by one or both of entry of impurities and formation of defects, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### [Structure of Oxide Semiconductor]

Next, the above-described CAC-OS will be described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic proportions of In, Ga, and Zn in the metal elements contained in the CAC-OS in an In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. For example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region containing indium oxide, indium zinc oxide, or the like as its main component. The second region is a region containing gallium oxide, gallium zinc oxide, or the like as its main component. That is, the first region can be replaced with a region containing In as its main component. The second region can be replaced with a region containing Ga as its main component.

Note that a clear boundary between the first region and the second region cannot be observed in some cases.

In addition, in a material composition of a CAC-OS in an In—Ga—Zn oxide that contains In, Ga, Zn, and O, there are regions containing Ga as a main component in part of the CAC-OS and regions containing In as a main component in another part of the CAC-OS. These regions each form a mosaic pattern and are randomly present. Thus, it is suggested that the CAC-OS has a structure where metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region containing In as its main component (the first region) and the region containing Ga as its main component (the second region) are unevenly distributed and mixed.

Here, the first region is a region having higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region is a region having a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

A transistor using the CAC-OS has high reliability. Thus, the CAC-OS is most suitable for a variety of semiconductor devices such as a display apparatus.

An oxide semiconductor has various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor with high reliability can be achieved.

It is particularly preferable to use an oxide containing indium (In), gallium (Ga), and zinc (Zn) (also referred to as “IGZO”) for a semiconductor layer where a channel is formed. Alternatively, an oxide containing indium (In), aluminum (Al), and zinc (Zn) (also referred to as “IAZO”) may be used for the semiconductor layer. Alternatively, an oxide containing indium (In), aluminum (Al), gallium (Ga), and zinc (Zn) (also referred to as “IAGZO”) may be used for the semiconductor layer.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charges trapped by the trap states in an oxide semiconductor take a long time to be released and may behave like fixed charges. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, nitrogen, an alkali metal, an alkaline earth metal, iron, nickel, and silicon. Note that an impurity in an oxide semiconductor refers to, for example, elements other than the main components of the oxide semiconductor. For example, an element with a concentration lower than 0.1 atomic % can be regarded as an impurity.

### <Impurity>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon (the concentration obtained by secondary ion mass spectrometry (SIMS)) in the semiconductor layer is set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

An oxide semiconductor containing nitrogen easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in an oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the oxide semiconductor is preferably reduced as much as possible. Specifically, the concentration of hydrogen in the oxide semiconductor, which is measured by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

The structure described in this embodiment can be used in an appropriate combination with any of the structures described in the other embodiments.

### Embodiment 5

In this embodiment, a display module that can be used for the electronic device of one embodiment of the present invention will be described.

### <Structure Example of Display Module>

First, a display module including the display apparatus that can be used for the electronic device of one embodiment of the present invention will be described.

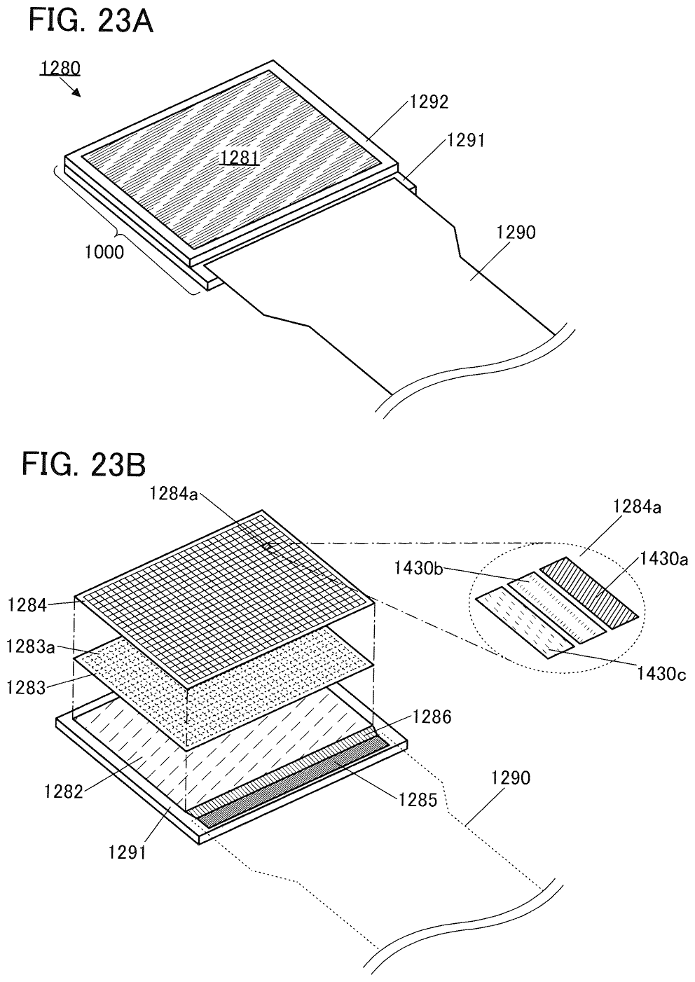

FIG. 23A is a perspective view of a display module 1280. The display module 1280 includes the display apparatus 1000 and an FPC 1290. The display apparatus 1001 illustrated in FIG. 13 may be used for the display module 1280 instead of the display apparatus 1000, for example.

The display module 1280 includes a substrate 1291 and a substrate 1292. The display module 1280 includes a display portion 1281. The display portion 1281 is a region of the display module 1280 where an image is displayed, and is a region where light emitted from pixels provided in a pixel portion 1284 described later can be seen.

FIG. 23B is a perspective view schematically illustrating a structure on the substrate 1291 side. A circuit portion 1282, a pixel circuit portion 1283 over the circuit portion 1282, and the pixel portion 1284 over the pixel circuit portion 1283 are stacked over the substrate 1291. In addition, a terminal portion 1285 for connection to the FPC 1290 is provided in a portion not overlapping with the pixel portion 1284 over the substrate 1291. The terminal portion 1285 and the circuit portion 1282 are electrically connected to each other through a wiring portion 1286 formed of a plurality of wirings.

Note that the pixel portion 1284 and the pixel circuit portion 1283 correspond to the pixel layer PXAL described above, for example. The circuit portion 1282 corresponds to the circuit layer SICL described above, for example.

The pixel portion 1284 includes a plurality of pixels 1284a arranged periodically. An enlarged view of one pixel 1284a is illustrated on the right side in FIG. 23B. The pixel 1284a includes a light-emitting diode 1430a, a light-emitting diode 1430b, and a light-emitting diode 1430c that emit light of different colors. Note that the light-emitting diode 1430a, the light-emitting diode 1430b, and the light-emitting diode 1430c correspond to the light-emitting diodes included in the above-described LED packages or the light-emitting diode 420R, the light-emitting diode 420G, and the light-emitting diode 420B, for example. The above-described light-emitting diodes may be arranged in a stripe pattern as illustrated in FIG. 23B. Alternatively, a variety of arrangement methods, such as delta arrangement and pentile arrangement, can be employed.

The pixel circuit portion 1283 includes a plurality of pixel circuits 1283a arranged periodically.

One pixel circuit 1283a is a circuit that controls light emission from three light-emitting diodes included in one pixel 1284a. One pixel circuit 1283a may be provided with three circuits each of which controls light emission from one light-emitting diode. For example, the pixel circuit 1283a can include at least one selection transistor, one current control transistor (driving transistor), and a capacitor for one light-emitting diode. In that case, a gate signal is input to a gate of the selection transistor, and a source signal is input to one of a source and a drain of the selection transistor. Thus, an active-matrix display apparatus is achieved.

The circuit portion 1282 includes a circuit for driving the pixel circuits 1283a in the pixel circuit portion 1283. For example, one or both of a gate line driver circuit and a source line driver circuit are preferably included. In addition, at least one of an arithmetic circuit, a memory circuit, a power supply circuit, and the like may be included.

The FPC 1290 functions as a wiring for supplying a video signal, a power supply potential, or the like to the circuit portion 1282 from the outside. In addition, an IC may be mounted on the FPC 1290.

The display module 1280 can have a structure in which one or both of the pixel circuit portion 1283 and the circuit portion 1282 are stacked below the pixel portion 1284; thus, the aperture ratio (the effective display area ratio) of the display portion 1281 can be significantly high.

Note that this embodiment can be combined with any of the other embodiments in this specification as appropriate.

### Embodiment 6

In this embodiment, electronic devices each including a display apparatus will be described as examples of an electronic device of one embodiment of the present invention.

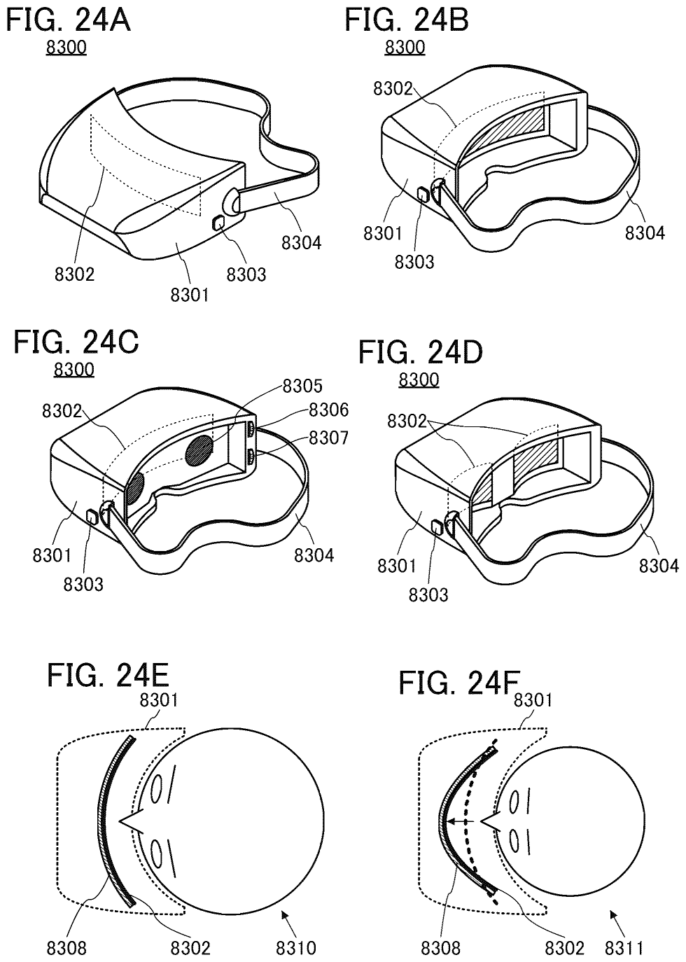

FIG. 24A and FIG. 24B each illustrate an appearance of an electronic device 8300 that is a head-mounted display.

The electronic device 8300 includes a housing 8301, a display portion 8302, an operation button 8303, and a band-shaped fixing unit 8304.

The operation button 8303 has a function of a power button or the like. The electronic device 8300 may include a button other than the operation button 8303.

As illustrated in FIG. 24C, lenses 8305 may be included between the display portion 8302 and the positions of the user's eyes. The user can see magnified images on the display portion 8302 through the lenses 8305, leading to a higher realistic sensation. In that case, as illustrated in FIG. 24C, a dial 8306 for changing the positions of the lenses to adjust visibility may be included.

For the display portion 8302, an extremely high-definition display apparatus is preferably used, for example. When a high-definition display apparatus is used for the display portion 8302, it is possible to display a more realistic image that does not allow the user to perceive pixels even when the image is magnified using the lenses 8305 as illustrated in FIG. 24C.

FIG. 24A to FIG. 24C illustrate an example in which one display portion 8302 is provided. Such a structure can reduce the number of components.

The display portion 8302 can display an image for the right eye and an image for the left eye side by side on a right region and a left region, respectively. Thus, a three-dimensional image using binocular disparity can be displayed.

One image that can be seen by both eyes may be displayed on the entire display portion 8302. A panorama image can thus be displayed from end to end of the field of view, which can provide a stronger sense of reality.

Here, the display portion 8302 of the electronic device 8300 preferably has a mechanism for changing the curvature of the display portion 8302 to an optimal value in accordance with the size of the user's head, the positions of the user's eyes, or the like. For example, the user himself or herself may adjust the curvature of the display portion 8302 by operating a dial 8307 for adjusting the curvature of the display portion 8302. Alternatively, a sensor portion for detecting the size of the user's head, the positions of the user's eyes, or the like (e.g., a camera, a contact sensor, or a noncontact sensor) may be provided on the housing 8301, and a mechanism for adjusting the curvature of the display portion 8302 on the basis of detection data obtained by the sensor portion may be provided.

In the case where the lenses 8305 are used, a mechanism for adjusting the positions and angle of the lenses 8305 in synchronization with the curvature of the display portion 8302 is preferably provided. Alternatively, the dial 8306 may have a function of adjusting the angle of the lenses.

FIG. 24E and FIG. 24F illustrate an example in which a driver portion 8308 controlling the curvature of the display portion 8302 is provided. The driver portion 8308 is fixed to at least part of the display portion 8302. The driver portion 8308 has a function of changing the shape of the display portion 8302 when the part that is fixed to the display portion 8302 changes in shape or moves.

FIG. 24E is a schematic view illustrating the case where a user 8310 having a relatively large head wears the housing 8301. In that case, the driver portion 8308 adjusts the shape of the display portion 8302 such that the curvature is relatively small (the radius of curvature is large).

By contrast, FIG. 24F illustrates the case where a user 8311 having a smaller head than the user 8310 wears the housing 8301. The user 8311 has a shorter distance between the eyes than the user 8310. In that case, the driver portion 8308 adjusts the shape of the display portion 8302 such that the curvature of the display portion 8302 is large (the radius of curvature is small). In FIG. 24F, the position and shape of the display portion 8302 in FIG. 24E are denoted by a dashed line.

When the electronic device 8300 has such a mechanism for adjusting the curvature of the display portion 8302, an optimal display can be offered to a variety of users of all ages and genders.

When the curvature of the display portion 8302 is changed in accordance with contents displayed on the display portion 8302, the user can have a more realistic sensation. For example, shaking can be expressed by fluctuating the curvature of the display portion 8302. In this way, it is possible to produce various effects depending on the scene in contents, and provide the user with new experiences. A further realistic display can be provided when the display portion 8302 operates in conjunction with a vibration module provided in the housing 8301.

Note that the electronic device 8300 may include two display portions 8302 as illustrated in FIG. 24D.

Since the two display portions 8302 are included, the user's eyes can see their respective display portions. This allows a high screen resolution image to be displayed even when three-dimensional display using parallax or the like is performed. In addition, the display portion 8302 is curved around an arc with the user's eye as an approximate center. This allows a uniform distance between the user's eye and the display surface of the display portion; thus, the user can see a more natural image. Even when the luminance or chromaticity of light from the display portion is changed depending on the angle at which the user sees it, since the user's eye is positioned in a normal direction of the display surface of the display portion, the influence of the change can be substantially ignorable and thus a more realistic image can be displayed.

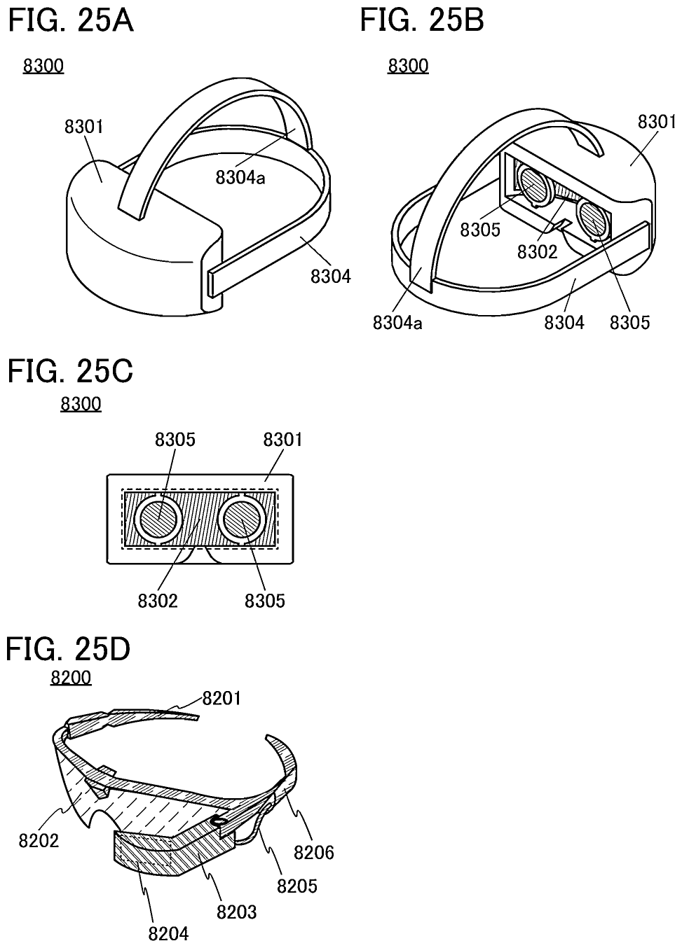

FIG. 25A to FIG. 25C are diagrams illustrating an appearance of another the electronic device 8300, which is different from the electronic device 8300 illustrated in FIG. 24A to FIG. 24D. Specifically, FIG. 25A to FIG. 25C are different from FIG. 24A to FIG. 24D in including a fixing unit 8304a worn on a head and a pair of the lenses 8305, for example.

A user can see display on the display portion 8302 through the lenses 8305. The display portion 8302 is preferably curved so that the user can feel high realistic sensation. Another image displayed on another region of the display portion 8302 is seen through the lenses 8305, so that three-dimensional display using parallax or the like can be performed. Note that the structure is not limited to the structure in which one display portion 8302 is provided; the two display portions 8302 may be provided and one display portion may be provided per eye of the user.

For the display portion 8302, an extremely high-definition display apparatus is preferably used, for example. When a high-definition display apparatus is used for the display portion 8302, it is possible to display a more realistic image that does not allow the user to perceive pixels even when the image is magnified using the lenses 8305 as illustrated in FIG. 25C.

The head-mounted display, which is an electronic device of one embodiment of the present invention, may be an electronic device 8200 illustrated in FIG. 25D, which is a glasses-type head-mounted display.

The electronic device 8200 includes a mounting portion 8201, a lens 8202, a main body 8203, a display portion 8204, and a cable 8205. A battery 8206 is incorporated in the mounting portion 8201.

The cable 8205 supplies power from the battery 8206 to the main body 8203. The main body 8203 includes a wireless receiver or the like and can display received image information on the display portion 8204. The main body 8203 includes a camera, and information on the movement of the eyeballs or the eyelids of the user can be used as an input means.

The mounting portion 8201 may include a plurality of electrodes capable of sensing current flowing accompanying with the movement of the user's eyeballs at a position in contact with the user to have a function of recognizing the user's sight line. The mounting portion 8201 may also have a function of monitoring the user's pulse with use of current flowing through the electrodes. The mounting portion 8201 may include a variety of sensors such as a temperature sensor, a pressure sensor, or an acceleration sensor to have a function of displaying the user's biological information on the display portion 8204, a function of changing an image displayed on the display portion 8204 in accordance with the movement of the user's head, and the like.

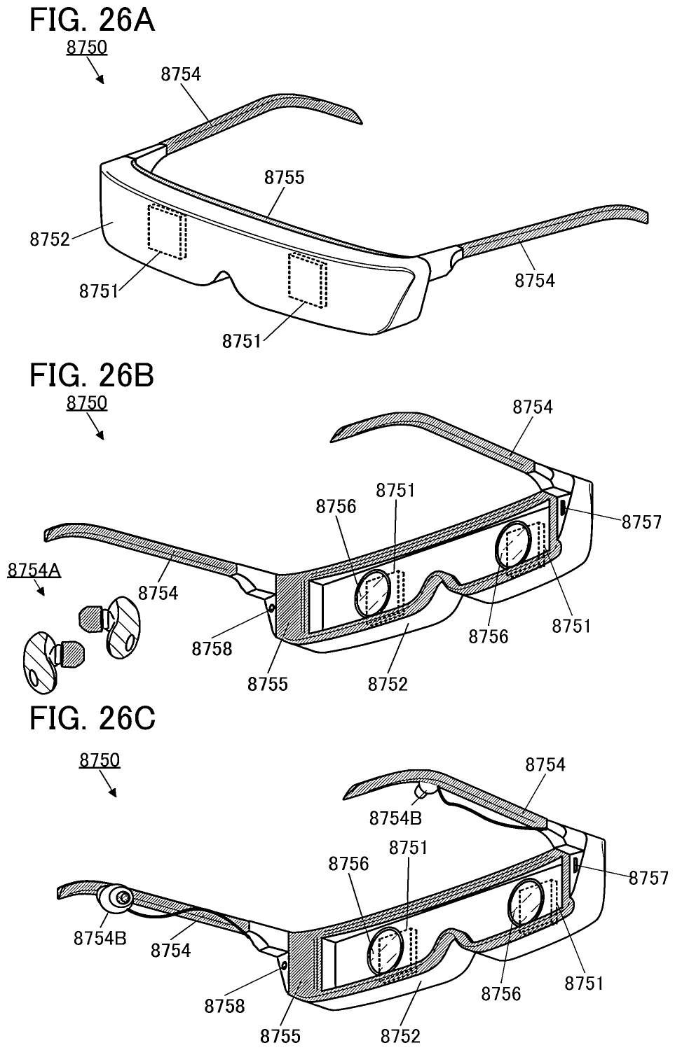

FIG. 26A to FIG. 26C are diagrams illustrating an appearance of an electronic device 8750, which is different from the electronic devices 8300 illustrated in FIG. 24A to FIG. 24D and FIG. 25A to FIG. 25C and the electronic device 8200 illustrated in FIG. 25D.

FIG. 26A is a perspective view illustrating the front surface, the top surface, and the left side surface of the electronic device 8750, and FIG. 26B and FIG. 26C are each a perspective view illustrating the back surface, the bottom surface, and the right side surface of the electronic device 8750.

The electronic device 8750 includes a pair of display apparatuses 8751, a housing 8752, a pair of mounting portions 8754, a cushion 8755, a pair of lenses 8756, and the like. The pair of display apparatuses 8751 is positioned to be seen through the lenses 8756 inside the housing 8752.

Here, one of the pair of display apparatuses 8751 corresponds to the display apparatus DSP described in Embodiment 1, for example. Although not illustrated, the electronic device 8750 illustrated in FIG. 26A to FIG. 26C includes an electronic component including the processing unit described in the above embodiment (e.g., the circuits included in the control circuit PRPH illustrated in FIG. 5). Although not illustrated, the electronic device 8750 illustrated in FIG. 26A to FIG. 26C includes a camera. The camera can take an image of the user's eye and its periphery. Although not illustrated, in the housing 8752 of the electronic device 8750 illustrated in FIG. 26A to FIG. 26C, a motion detection portion, an audio, a control portion, a communication portion, and a battery are provided.

The electronic device 8750 is an electronic device for VR. A user wearing the electronic device 8750 can see an image displayed on the display apparatus 8751 through the lens 8756. Furthermore, the pair of display apparatuses 8751 may display different images, whereby three-dimensional display using parallax can be performed.

An input terminal 8757 and an output terminal 8758 are provided on the back side of the housing 8752. To the input terminal 8757, a cable for supplying an image signal or the like from an image output device or power or the like for charging a battery provided in the housing 8752 can be connected. The output terminal 8758 can function as, for example, an audio output terminal to which earphones or headphones can be connected.

The housing 8752 preferably includes a mechanism for enabling adjustment of the left and right positions of the lens 8756 and the display apparatus 8751 to the optimal positions in accordance with the position of the user's eye. In addition, the housing 8752 preferably includes a mechanism for adjusting focus by changing the distance between the lens 8756 and the display apparatus 8751.

With use of the above-described camera, the display apparatus 8751, and the above-described electronic component, the electronic device 8750 can estimate the state of a user of the electronic device 8750 and can display information on the estimated user's state on the display apparatus 8751. Alternatively, information on a state of a user of an electronic device connected to the electronic device 8750 through a network can be displayed on the display apparatus 8751.

The cushion 8755 is a portion that comes in contact with the user's face (e.g., forehead or one or both cheeks). The cushion 8755 is in close contact with the user's face, so that light leakage can be prevented, which increases the sense of immersion. A soft material is preferably used for the cushion 8755 so that the cushion 8755 is in close contact with the face of the user wearing the electronic device 8750. For example, any of materials such as rubber, silicone rubber, urethane, and sponge can be used. Furthermore, when a sponge or the like whose surface is covered with cloth or leather (for example, natural leather or synthetic leather) is used, a gap is unlikely to be generated between the user's face and the cushion 8755, whereby light leakage can be suitably prevented. Furthermore, using such a material is preferable because it has a soft texture and the user does not feel cold when wearing the device in a cold season, for example. The member in contact with user's skin, such as the cushion 8755 or the mounting portion 8754, is preferably detachable because cleaning or replacement can be easily performed.

The electronic device in this embodiment may further include earphones 8754A. The earphones 8754A include a communication portion (not illustrated) and have a wireless communication function. The earphones 8754A can output audio data with the wireless communication function. Note that the earphones 8754A may include a vibration mechanism to function as bone-conduction earphones.

Like earphones 8754B illustrated in FIG. 26C, the earphones 8754A can be connected to the mounting portion 8754 directly or by wiring. The earphones 8754B and the mounting portion 8754 may each have a magnet. This is preferable because the earphones 8754B can be fixed to the mounting portion 8754 with magnetic force and thus can be easily housed.

The earphones 8754A may include a sensor portion. With use of the sensor portion, the state of the user of the electronic device can be estimated.

The electronic device of one embodiment of the present invention may include one or more selected from an antenna, a battery, a camera, a speaker, a microphone, a touch sensor, and an operation button, in addition to any one of the above components.

The electronic device of one embodiment of the present invention may include a secondary battery, and it is preferable that the secondary battery be capable of being charged by contactless power transmission.

Examples of the secondary battery include a lithium ion secondary battery (e.g., a lithium polymer battery using a gel electrolyte (lithium ion polymer battery)), a nickel-hydride battery, a nickel-cadmium battery, an organic radical battery, a lead-acid battery, an air secondary battery, a nickel-zinc battery, or a silver-zinc battery.

The electronic device of one embodiment of the present invention may include an antenna. When a signal is received by the antenna, the electronic device can display an image, information, or the like on a display portion. When the electronic device includes an antenna and a secondary battery, the antenna may be used for contactless power transmission.

A display portion in an electronic device of one embodiment of the present invention can display an image with a screen resolution of, for example, full high definition, 4K2K, 8K4K, 16K8K, or higher.

Note that this embodiment can be combined with any of the other embodiments in this specification as appropriate.

### Embodiment 7

In this embodiment, electronic devices each including a display apparatus fabricated in accordance with one embodiment of the present invention will be described.

Electronic devices described below as examples each include the display apparatus of one embodiment of the present invention in a display portion. Thus, the electronic devices achieve high screen resolution.

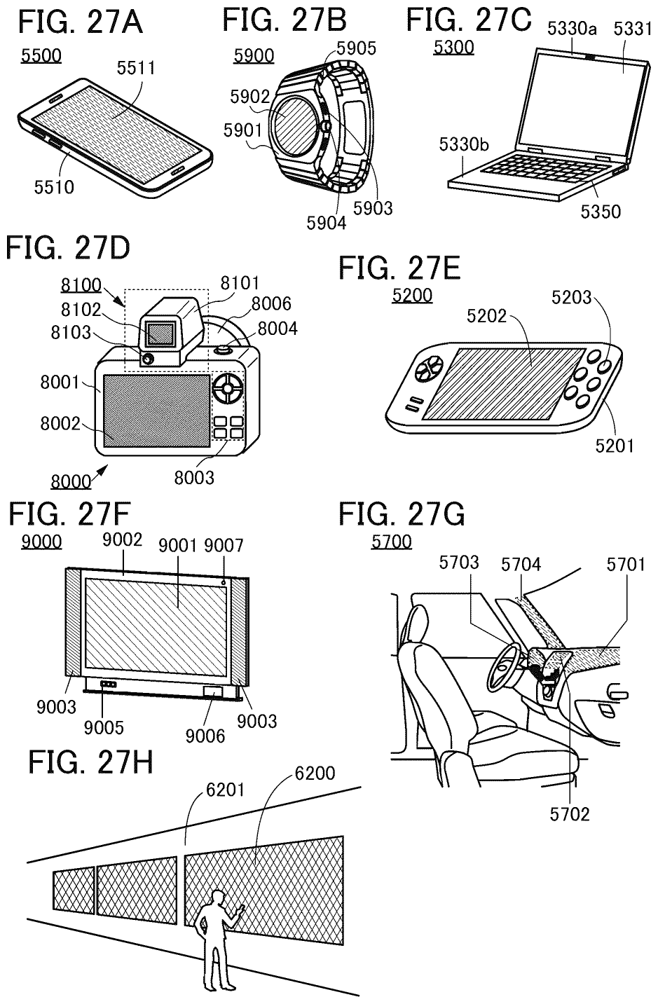

For example, the display apparatus described in any of the above embodiments is used in electronic devices illustrated in FIG. 27A to FIG. 27H described later in some cases. In addition, these electronic devices can each achieve both high screen resolution and a large screen.

One embodiment of the present invention includes the display apparatus and one or more selected from an antenna, a battery, a housing, a camera, a speaker, a microphone, a touch sensor, and an operation button.

The electronic device of one embodiment of the present invention may include a secondary battery, and it is preferable that the secondary battery be capable of being charged by contactless power transmission.

For the secondary battery, the description of the secondary battery described in Embodiment 6 can be referred to, for example.

The electronic device of one embodiment of the present invention may include an antenna. For the antenna, the description of the antenna described in Embodiment 6 can be referred to, for example.

A display portion in an electronic device of one embodiment of the present invention can display an image with a screen resolution of, for example, full high definition, 4K2K, 8K4K, 16K8K, or higher.

Examples of electronic devices include a digital camera, a digital video camera, a digital photo frame, a mobile phone, a portable game machine, a portable information terminal, and an audio reproducing device in addition to electronic devices with a relatively large screen, such as a television device, a laptop personal computer, a monitor device, digital signage, a pachinko machine, and a game machine.

The electronic device using one embodiment of the present invention can be incorporated along a flat surface or a curved surface of an inside wall or an outside wall of a construction such as a house or a building or an interior or an exterior of a car or the like.

### [Mobile Phone]

An information terminal 5500 illustrated in FIG. 27A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

### [Wearable Terminal]

FIG. 27B is an external view of an information terminal 5900 that is an example of a wearable terminal. The information terminal 5900 includes a housing 5901, a display portion 5902, an operation button 5903, a crown 5904, and a band 5905.

### [Information Terminal]

FIG. 27C illustrates a laptop information terminal 5300. The laptop information terminal 5300 illustrated in FIG. 27C includes, for example, a display portion 5331 in a housing 5330a and a keyboard portion 5350 in a housing 5330b.

Although the smartphone, the wearable terminal, and the laptop information terminal are respectively illustrated in FIG. 27A to FIG. 27C as examples of the electronic devices, one embodiment of the present invention can be used for information terminals other than a smartphone, a wearable terminal, and a laptop information terminal. Examples of information terminals other than a smartphone, a wearable terminal, and a laptop information terminal include a PDA (Personal Digital Assistant), a desktop information terminal, and a workstation.

### [Camera]

FIG. 27D is an external view of a camera 8000 to which a finder 8100 is attached.

The camera 8000 includes a housing 8001, a display portion 8002, operation buttons 8003, a shutter button 8004, and the like. In addition, a detachable lens 8006 is attached to the camera 8000.

Note that the lens 8006 and the housing may be integrated with each other in the camera 8000.

The camera 8000 can take images by the press of the shutter button 8004 or touch on the display portion 8002 functioning as a touch panel.

The housing 8001 includes a mount including an electrode, so that, in addition to the finder 8100, a stroboscope or the like can be connected to the housing.

The finder 8100 includes a housing 8101, a display portion 8102, and a button 8103.

The housing 8101 is attached to the camera 8000 by a mount for engagement with a mount of the camera 8000. In the finder 8100, an image or the like received from the camera 8000 can be displayed on the display portion 8102.

The button 8103 has a function of a power button.

The display apparatus of one embodiment of the present invention can be used for the display portion 8002 of the camera 8000 and the display portion 8102 of the finder 8100. Note that a finder may be incorporated in the camera 8000.

### [Game Machine]

FIG. 27E is an external view of a portable game machine 5200 which is an example of a game machine. The portable game machine 5200 includes a housing 5201, a display portion 5202, and a button 5203.

Images displayed on the portable game machine 5200 can be output with a display apparatus such as a television device, a personal computer display, a game display, or a head-mounted display, for example.

The portable game machine 5200 with low power consumption can be provided by including the display apparatus described in the above embodiment. Moreover, heat generation from a circuit can be reduced owing to low power consumption; thus, the influence of heat generation on the circuit itself, a peripheral circuit, and a module can be reduced.

Although FIG. 27E illustrates the portable game machine as an example of a game machine, the electronic device of one embodiment of the present invention is not limited thereto. Examples of the electronic device of one embodiment of the present invention include a stationary game machine, an arcade game machine installed in entertainment facilities (e.g., a game center or an amusement park), and a throwing machine for batting practice installed in sports facilities.

### [Television Device]

FIG. 27F is a perspective view illustrating a television device. A television device 9000 includes a housing 9002, a display portion 9001, speakers 9003, an operation key 9005 (including a power switch or an operation switch), a connection terminal 9006, a sensor 9007 (e.g., a sensor having a function of measuring or sensing force, displacement, a position, speed, acceleration, angular velocity, rotational frequency, distance, light, liquid, magnetism, temperature, a chemical substance, sound, time, hardness, an electric field, current, voltage, power, radiation, a flow rate, humidity, gradient, oscillation, an odor, or infrared rays), and the like. The memory device of one embodiment of the present invention can be provided in the television device. The television device can include the display portion 9001 of, for example, 50 inches or more or 100 inches or more.

The television device 9000 with low power consumption can be provided by including the display apparatus described in the above embodiment. Moreover, heat generation from a circuit can be reduced owing to low power consumption; thus, the influence of heat generation on the circuit itself, a peripheral circuit, and a module can be reduced.

### [Moving Vehicle]

The display apparatus of one embodiment of the present invention can be used around a driver's seat in a car, which is a moving vehicle.

FIG. 27G is a diagram illustrating an area around a windshield inside a car 5700. FIG. 27G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying navigation information, a speedometer, a tachometer, a mileage, a fuel meter, a gearshift indicator, and air-condition settings, for example. The content and layout of the display on the display panels can be changed appropriately to suit the user's preferences, so that the design can be improved. The display panel 5701 to the display panel 5703 can also be used as lighting devices.

The display panel 5704 can compensate for the view obstructed by the pillar (blind areas) by showing an image taken by an imaging unit provided for the car body. That is, showing an image taken by an imaging unit provided on the outside of the car 5700 leads to elimination of blind areas and enhancement of safety. Display of an image that complements for a portion that cannot be seen makes it possible to confirm safety more naturally and comfortably. The display panel 5704 can also be used as a lighting device.

The display apparatus of one embodiment of the present invention can be used for the display panel 5701 to the display panel 5704, for example.

Although a car is described above as an example of a moving vehicle, the moving vehicle is not limited to a car. Examples of moving vehicles include a train, a monorail train, a ship, and a flying object (e.g., a helicopter, an unmanned aircraft (a drone), an airplane, or a rocket), and these moving vehicles can include the display apparatus of one embodiment of the present invention.

### [Digital Signage]

FIG. 27H illustrates an example of digital signage that can be attached to a wall. FIG. 27H illustrates a state where a digital signage 6200 is attached to a wall 6201. The display apparatus of one embodiment of the present invention can be used in a display portion of the digital signage 6200, for example. An interface such as a touch panel may be provided in the digital signage 6200, for example.

Although the electronic device attachable to a wall is described above as an example of digital signage, the kind of digital signage is not limited thereto. Examples of the digital signage include digital signage attached to a pillar, freestanding digital signage placed on the ground, and digital signage mounted on a rooftop or a side wall of an architecture such as a building.

Note that this embodiment can be combined with any of the other embodiments in this specification as appropriate.

### Embodiment 8

In this embodiment, a system including the above-described electronic device and a server (referred to as a computer in some cases) functioning on a network will be described.

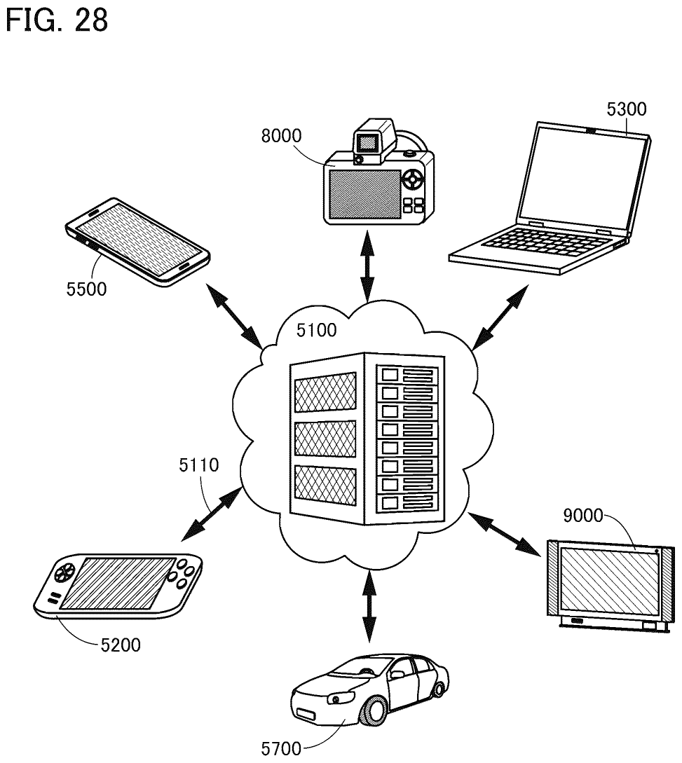

FIG. 28A schematically illustrates a state where communication is performed between the electronic device using the display apparatus of one embodiment of the present invention and a server 5100, for example. Note that in FIG. 28A, communication 5110 is shown as the manner of communication. FIG. 28A illustrates the information terminal 5500, the camera 8000, the laptop information terminal 5300, the portable game machine 5200, the automobile 5700, and the television device 9000 as examples of the electronic device.

In such a mode, when each of the electronic devices performs arithmetic processing with a large scale, the electronic device transmits a signal including an instruction relating to the arithmetic processing to the server 5100, and the server 5100 can perform the arithmetic processing instead of the electronic device. Specifically, the electronic device does not need to have data needed for arithmetic processing and application software in such a mode; thus, the capacity of the memory device in the electronic device can be saved. Alternatively, since the electronic device does not need to perform the arithmetic processing, load of the circuit included in the electronic device can be reduced.

Note that in this specification and the like, the above-described system is referred to as a thin client system in some cases. The electronic device is referred to as a thin client terminal and the server 5100 is referred to as a thin client server in some cases.

Examples of processing performed by the server 5100 instead of the electronic device include image processing for displaying an image on the display portion of the display apparatus (e.g., processing for adjusting the gray level or luminance adjustment for each color), processing of setting the image resolution in each divided region in the display portion of the display apparatus, processing of setting the frame frequency in each divided portion in the display portion of the display apparatus, and processing related to eye tracking function which are described in the above embodiment.

The structure described in this embodiment can be used in an appropriate combination with any of the structures described in the other embodiments.

### REFERENCE NUMERALS

DSP: display apparatus, PXAL: pixel layer, EML: layer, OSL: layer, SICL: circuit layer, BS: substrate, SST: stack, TP: touch sensor layer, DRV: driver circuit region, LIA: region, DIS: display portion, ARA[1,1]: display region, ARA[2,1]: display region, ARA[m−1,1]: display region, ARA[m,1]: display region, ARA[1,2]: display region, ARA[2,2]: display region, ARA[m−1,2]: display region, ARA[m,2]: display region, ARA[1,n−1]: display region, ARA[2,n−1]: display region, ARA[m−1,n−1]: display region, ARA[m,n−1]: display region, ARA[1,n]: display region, ARA[2,n]: display region, ARA[m−1,n]: display region, ARA[m,n]: display region, ARD[1,1]: circuit region, ARD[2,1]: circuit region, ARD[m−1,1]: circuit region, ARD[m,1]: circuit region, ARD[1,2]: circuit region, ARD[2,2]: circuit region, ARD[m−1,2]: circuit region, ARD[m,2]: circuit region, ARD[1,n−1]: circuit region, ARD[2,n−1]: circuit region, ARD[m−1,n−1]: circuit region, ARD[m,n−1]: circuit region, ARD[1,n]: circuit region, ARD[2,n]: circuit region, ARD[m−1,n]: circuit region, ARD[m,n]: circuit region, PRPH: control circuit, SD: driver circuit, SDS: circuit, GD: driver circuit, GDS: circuit, DMG: distribution circuit, DMS: distribution circuit, CTR: control unit, MD: memory device, PG: voltage generation circuit, TMC: timing controller, CKS: clock signal generation circuit, GPS: image processing portion, INT: interface, BW: bus wiring, PX: pixel, GL: wiring, GL1: wiring, GL2: wiring, SL: wiring, ANO: wiring, CAT: wiring, VCOM: wiring, ASU: region, ASU_AF: region, ALPa: region, ALPb: region, ALPc: region, ALPd: region, ALPe: region, 30: driver circuit, 70A: pixel, 70B: pixel, 80: pixel, 80a: subpixel, 80b: subpixel, 80c: subpixel, 80d: subpixel, 81: conductor, 103: insulator, 104: conductor, 105: insulator, 106: conductor, 107: adhesive layer, 108: adhesive layer, 110: substrate, 111a: conductor, 111b: conductor, 111c: conductor, 112a: conductor, 112b: conductor, 112c: conductor, 116: protective layer, 117: conductor, 118: conductor, 148: resin layer, 149: resin layer, 166R: coloring layer, 166G: coloring layer, 166B: coloring layer, 167R: coloring layer, 167G: coloring layer, 170: LED package, 170R: LED package, 170G: LED package, 170B: LED package, 170A1: LED package, 170A2: LED package, 170A3: LED package, 170S: LED package, 171: substrate, 172: electrode, 173: electrode, 175: adhesive layer, 178: sealing layer, 180: LED chip, 180A: LED chip, 180R: LED chip, 180G: LED chip, 180B: LED chip, 181: substrate, 181R: substrate, 181G: substrate, 181B: substrate, 182: semiconductor layer, 182a: semiconductor layer, 182b: semiconductor layer, 182c: semiconductor layer, 183: electrode, 183A: electrode, 183a: electrode, 183b: electrode, 183c: electrode, 184: light-emitting layer, 184a: light-emitting layer, 184b: light-emitting layer, 184c: light-emitting layer, 185: semiconductor layer, 185a: semiconductor layer, 185b: semiconductor layer, 185c: semiconductor layer, 186: electrode, 186a: electrode, 186b: electrode, 186c: electrode, 187: electrode, 190: color conversion layer, 190a: color conversion layer, 190b: color conversion layer, 191: conductor, 192: conductor, 193a: conductor, 193b: conductor, 193c: conductor, 194a: conductor, 194b: conductor, 194c: conductor, 200: transistor, 200A: transistor, 200B: transistor, 200C: transistor, 211: insulator, 213: insulator, 214: insulator, 215: insulator, 218: insulator, 221: conductor, 222a: conductor, 222b: conductor, 223: conductor, 225: insulator, 231: semiconductor layer, 231n: low-resistance region, 231i: channel formation region, 300: transistor, 310: substrate, 311: insulator, 312: insulator, 313: insulator, 314: insulator, 316: conductor, 317: conductor, 318: semiconductor layer, 318i: semiconductor region, 318p: low-resistance region, 319: conductor, 320: insulator, 322: insulator, 410: substrate, 411: protective layer, 420: light-emitting diode, 420R: light-emitting diode, 420G: light-emitting diode, 420B: light-emitting diode, 500: pixel circuit, 600: capacitor, 1000: display apparatus, 1000A: display apparatus, 1000C: display apparatus, 1001: display apparatus, 1001A: display apparatus, 1280: display module, 1281: display portion, 1290: FPC, 1282: circuit portion, 1283: pixel circuit portion, 1283a: pixel circuit, 1284: pixel portion, 1284a: pixel, 1285: terminal portion, 1286: wiring portion, 1291: substrate, 1292: substrate, 1430a: light-emitting diode, 1430b: light-emitting diode, 1430c: light-emitting diode, 5200: portable game machine, 5201: housing, 5202: display portion, 5203: button, 5300: laptop information terminal, 5330a: housing, 5330b: housing, 5331: display portion, 5350: keyboard portion, 5500: information terminal, 5510: housing, 5511: display portion, 5701: display panel, 5702: display panel, 5703: display panel, 5704: display panel, 5900: information terminal, 5901: housing, 5902: display portion, 5903: operation button, 5904: crown, 5905: band, 6200: digital signage, 6201: wall, 8000: camera, 8001: housing, 8002: display portion, 8003: operation button, 8004: shutter button, 8006: lens, 8100: finder, 8101: housing, 8102: display portion, 8103: button, 8200: electronic device, 8201: mounting portion, 8202: lens, 8203: main body, 8204: display portion, 8205: cable, 8206: battery, 8300: electronic device, 8301: housing, 8302: display portion, 8303: operation button, 8304: fixing unit, 8304a: fixing unit, 8305: lens, 8310: user, 8311: user, 8750: electronic device, 8751: display apparatus, 8752: housing, 8754: mounting portion, 8754A: earphone, 8754B: earphone, 8755: cushion, 8756: lens, 8757: input terminal, 8758: output terminal, 9000: television device, 9001: display portion, 9002: housing, 9003: speaker, 9005: operation key, 9006: connection terminal, 9007: sensor

1.-8. (canceled)

9. A display apparatus comprising:
a first layer over a substrate, the first layer comprising a first driver circuit and a second driver circuit; and
a second layer over the first layer, the second layer comprising a first display region and a second display region,
wherein the first display region comprises a first pixel,
wherein the second display region comprises a second pixel,
wherein the first pixel comprises a first light-emitting diode,
wherein the second pixel comprises a second light-emitting diode,
wherein each of the first driver circuit and the second driver circuit comprises a first transistor comprising silicon in a channel formation region,
wherein each of the first pixel and the second pixel comprises a transistor comprising a metal oxide in a channel formation region,
wherein the first display region is configured to display an image with a first frame frequency,
wherein the second display region is configured to display an image with a second frame frequency, and
wherein the first frame frequency is different from the second frame frequency.

10. The display apparatus according to claim 9,
wherein the first display region further comprises a first sensor portion,
wherein the second display region further comprises a second sensor portion,
wherein the first sensor portion is positioned over the first light-emitting diode, and
wherein the second sensor portion is positioned over the second light-emitting diode.

11. The display apparatus according to claim 9,
wherein the substrate comprises a glass substrate.

12. The display apparatus according to claim 9,
wherein the first transistor comprises polysilicon in the channel formation region.

13. The display apparatus according to claim 9,
wherein the first driver circuit and the first pixel overlap each other, and
wherein the second driver circuit and the second pixel overlap each other.

14. The display apparatus according to claim 9, further comprising a wiring between the first layer and the second layer,
wherein the wiring is electrically connected to the first pixel and the first driver circuit, and
wherein the wiring extends in a direction perpendicular to or a direction substantially perpendicular to the substrate.
